(19) United States
(12) Patent Application Publication
(10) Pub. No.: US 2025/0164883 A1
(43) Pub. Date: May 22, 2025

(54) RADIATION-SENSITIVE COMPOSITION AND PATTERN FORMING METHOD

(71) Applicant: JSR CORPORATION, Tokyo (JP)

(72) Inventors: Motohiro SHIRATANI, Tokyo (JP); Fumiko YONEZAWA, Tokyo (JP); Takehiro NAKAYAMA, Tokyo (JP); Masahiro ARAKI, Sunnyvale, CA (US); Hirofumi SASAKI, Tokyo (JP)

(73) Assignee: JSR CORPORATION, Tokyo (JP)

(21) Appl. No.: 18/951,824

(22) Filed: Nov. 19, 2024

(30) Foreign Application Priority Data
Nov. 22, 2023 (JP) 2023-197974

(51) Int. Cl. G03F 7/039; C08L 25/18; C08L 33/06; C08L 33/16; G03F 7/00; G03F 7/004; G03F 7/20

(52) U.S. Cl. CPC G03F 7/0395; C08L 25/18; C08L 33/066; C08L 33/16; G03F 7/0046; G03F 7/2004; G03F 7/70033; C08L 2203/20

(57) ABSTRACT

A radiation-sensitive composition includes: a first polymer comprising a structural unit (I) having an acid-dissociable group; a second polymer comprising a structural unit (i) represented by formula (f1); and a solvent. The acid-dissociable group has an iodo group. R^{K1} is a hydrogen atom, a fluorine atom, or the like; L^{Y1} is a divalent hydrocarbon group having 1 to 10 carbon atoms; L^{Y2} is —COO—* or —OCO—*, *is a bond on an R^{f1} side; R^{f1} is a monovalent hydrocarbon group having 1 to 10 carbon atoms or a monovalent fluorinated hydrocarbon group having 1 to 10 carbon atoms; R^{f2} and R^{f3} are each independently a fluorine atom or a monovalent fluorinated hydrocarbon group having 1 to 10 carbon atoms; s is an integer of 0 to 3, and when R^{f1} is the monovalent hydrocarbon group having 1 to 10 carbon atoms, s is an integer of 1 to 3.

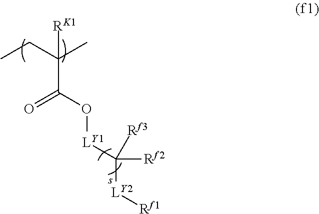

### CROSS-REFERENCE TO RELATED APPLICATIONS

The present application claims priority to Japanese Patent Application No. 2023-197974 filed Nov. 22, 2023, the contents of which are incorporated herein by reference in their entirety.

### BACKGROUND OF THE DISCLOSURE

### Technical Field

The present disclosure relates to a radiation-sensitive composition and a pattern forming method.

### Background Art

A photolithography technique performed using a resist composition has been utilized for formation of a fine circuit on a semiconductor device. As the representative procedure, for example, a resist pattern is formed on a substrate by generating an acid by irradiating the coating of the resist composition with radioactive ray through a mask pattern, and then generate a difference in solubility of polymer into an alkaline or organic developer between an exposed part and a non-exposed part through a reaction in the presence of the acid as a catalyst.

In the photolithography technique, pattern miniaturization is promoted by using short-wavelength radiation such as ArF excimer laser, or by combining such radiation with an immersion exposure method (liquid immersion lithography). As a next generation technique, the use of further shorter-wavelength radiation such as an electron beam, X-ray, and extreme ultraviolet (EUV) is being sought.

While pattern miniaturization is progressing, a technique of adding a fluorine-containing polymer to a resist composition for the purpose of controlling the film quality of a resist film has been proposed (JP-B-5712247).

### SUMMARY

According to an aspect of the present disclosure, a radiation-sensitive composition includes: a first polymer comprising a structural unit (I) having an acid-dissociable group; a second polymer comprising a structural unit (i) represented by formula (f1); and a solvent. The acid-dissociable group has an iodo group. R^{K1} is a hydrogen atom, a fluorine atom, an alkyl group having 1 to 6 carbon atoms, a halogenated alkyl group having 1 to 6 carbon atoms, or a group represented by —R^{K2}—X—R^{K3}, in which R^{K2} is a single bond, an alkanediyl group having 1 to 6 carbon atoms, or a halogenated alkanediyl group having 1 to 6 carbon atoms, X is a divalent linking group having a hetero atom, and R^{K3} is an alkyl group having 1 to 6 carbon atoms or a halogenated alkyl group having 1 to 6 carbon atoms; L^{Y1} is a divalent hydrocarbon group having 1 to 10 carbon atoms; L^{Y2} is —COO—* or —OCO—*, *is a bond on an R^{f1} side; R^{f1} is a monovalent hydrocarbon group having 1 to 10 carbon atoms or a monovalent fluorinated hydrocarbon group having 1 to 10 carbon atoms; R^{f2} and R^{f3} are each independently a fluorine atom or a monovalent fluorinated hydrocarbon group having 1 to 10 carbon atoms; s is an integer of 0 to 3, and when R^{f1} is the monovalent hydrocarbon group having 1 to 10 carbon atoms, s is an integer of 1 to 3.

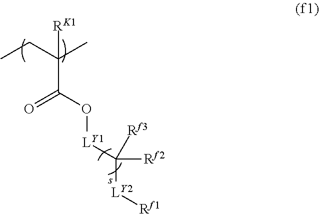

According to another aspect of the present disclosure, a pattern forming method includes: directly or indirectly applying the above-described radiation-sensitive composition onto a substrate to form a resist film; exposing the resist film to light; and developing the exposed resist film with a developer.

### DESCRIPTION OF THE EMBODIMENTS

In developing the next generation technique, various resist performances equal to or higher than conventional performances are required in terms of sensitivity, line width roughness (LWR) performance indicating variation in line width of a resist pattern, an over exposure margin (Max CD) indicating tolerance of a space dimension at the time of over exposure, and the like.

According to the embodiments of the radiation-sensitive composition, it is possible to achieve superior sensitivity when forming a resist pattern, as well as LWR performance and over-exposure margins that are equivalent to or better than those of conventional products. Although the reason for this is not clear, the following is a possible explanation.

The absorption of radiation such as EUV with a wavelength of 13.5 nm by iodine groups (iodine atoms) is significant, and as a result, the secondary electron generation efficiency increases, making the resulting resist film more sensitive. This also improves the acid generation efficiency, and a good dissolution contrast is obtained between the exposed and unexposed areas.

On the other hand, components containing iodine atoms have low solubility, and pattern collapse may occur during development. According to the photosensitive radiation-sensitive composition, a dissociation reaction occurs in the structural unit (i) of the second polymer present near the surface of the resist film during alkaline development, and the solubility of the resist film surface layer in the developer can be improved. As a result, even if over-exposure occurs, the resist film can still show good solubility in the developer, and this can suppress pattern collapse, etc. It is thought that these combined effects can demonstrate the above resist performance.

Further, in the pattern formation method of the present embodiments, the above photosensitive radiation-sensitive composition, which exhibits excellent sensitivity as well as LWR performance and over-exposure margins equivalent to or better than conventional products, is used in resist pattern formation, so high-quality resist patterns can be formed efficiently.

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4 -7.2 as does the following list of values: 1, 4, 6, 10.

Hereinafter, embodiments of the present invention will be described in detail, but the present invention is not limited to these embodiments. Combinations of preferred embodiments are also preferable.

### <<Radiation-Sensitive Composition>>

A radiation-sensitive composition (hereinafter, also simply referred to as a “composition”) according to the present embodiment contains a first polymer (hereinafter, also referred to as a “base polymer”), a second polymer, and a solvent. The composition may contain another optional component as long as the effects of the present invention are not impaired.

### <First Polymer>

The first polymer (that is, the base polymer) is an aggregate of polymerized chains containing a structural unit (I) having an acid-dissociable group. The acid-dissociable group has an iodo group (hereinafter, the acid-dissociable group having an iodo group is also referred to as an “iodo group-containing acid-dissociable group”). When the iodo group is contained in the base polymer, the radiation absorption efficiency is increased, and the secondary electron-generating efficiency is increased, so that the sensitivity can be improved. In addition to the structural unit (I), the base polymer may contain a structural unit having an acid-dissociable group having no iodo group (hereinafter, also referred to as a “structural unit (II)”), a structural unit having a phenolic hydroxyl group (hereinafter, also referred to as a “structural unit (III)”), and the like.

### (Structural Unit (I))

The structural unit (I) is a structural unit having an iodo group-containing acid-dissociable group (provided that, among structures corresponding to the structural unit (III), a structure having an iodo group-containing acid-dissociable group is treated as the structural unit (I)). The “acid-dissociable group” refers to a group that substitutes for a hydrogen atom of a carboxy group, a phenolic hydroxy group, an alcoholic hydroxy group, a sulfo group, or the like, and is dissociated by the action of an acid. An acid generated from the radiation-sensitive acid generator or the structural unit (IV) described later through exposure to light dissociates the acid-dissociable group in the structural unit (I) to generate a carboxy group or the like. As a result, a difference in solubility into a developer arises between the exposed portion and the unexposed portion of a resist film, making it possible to achieve pattern formation.

The acid-dissociable group preferably contains an iodo group in the form of an iodo group-containing aromatic ring structure. The iodo group-containing aromatic ring structure is a structure in which some or all of hydrogen atoms of the aromatic ring are substituted with an iodo group. Another structural unit composing the base polymer may contain the iodo group-containing aromatic ring structure.

The aromatic ring in the iodo group-containing aromatic ring structure is not particularly limited as long as the ring forms a ring structure having aromaticity. Examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine group, a carbazole ring, and a dibenzofuran ring, or combinations thereof. Among them, a benzene ring is preferable as the aromatic ring.

The number of iodine atoms in the iodo group-containing aromatic ring structure is not particularly limited, but is preferably 1 to 4, more preferably 1, 2, or 3, still more preferably 1 or 2.

The structural unit (I) is not particularly limited as long as the structural unit (I) contains an iodo group-containing acid-dissociable group, and examples thereof include a structural unit having a tertiary alkyl ester moiety, a structural unit having a structure in which a hydrogen atom of a phenolic hydroxyl group is substituted with a tertiary alkyl group, a structural unit having an acetal bond, and a structural unit having a primary or secondary alkyl ester moiety substituted with an aromatic ring (including an aromatic heterocyclic ring).

The structural unit (I) is preferably a structural unit represented by the following formula (1) (hereinafter, also referred to as a “structural unit (I-1)”).

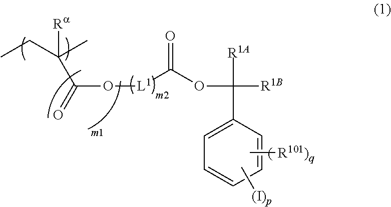

(In the formula (1),
R^{α} is a hydrogen atom, a fluorine atom, a methyl group, or a trifluoromethyl group.
L¹ is a divalent linking group.
R^{1A} and R^{1B} are each independently a hydrogen atom, a monovalent chain hydrocarbon group having 1 to 10 carbon atoms or a monovalent alicyclic hydrocarbon group having 3 to 20 carbon atoms, or represent a divalent alicyclic group having 3 to 20 carbon atoms composed of R^{1A} and R^{1B} combined with each other together with a carbon atom to which R^{1A} and R^{1B} are bonded, provided that both R^{1A} and R^{1B} are not hydrogen atoms.
R¹⁰¹ is a nitro group, a cyano group, a hydroxy group, an alkoxy group, or an amino group. When there are a plurality of R¹⁰¹s, the plurality of R¹⁰¹s are the same as or different from each other.
m1 and m2 are each independently 0 or 1, provided that when m1 is 1, m2 is 1.
p is an integer of 1 to 3, and q is an integer of 0 to 3, provided that p+q is 5 or less.)

Examples of the divalent linking group represented by L¹ include an alkanediyl group, a cycloalkanediyl group, an alkenediyl group, an arenediyl group, a group containing, between carbon-carbon bonds of these groups, —CO—, —CS—, —O—, —S—, —SO₂—, —NR′—, or a combination of two or more thereof, or a group obtained by combining these groups. R′ is a hydrogen atom or a monovalent hydrocarbon group having 1 to 10 carbon atoms. Some or all of hydrogen atoms of these groups may be substituted with, for example, a halogen atom such as a fluorine atom, a chlorine atom, a bromine atom, or an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group, or a group obtained by substituting a hydrogen atom of such a group with a halogen atom.

The alkanediyl group is preferably an alkanediyl group having 1 to 8 carbon atoms such as a methanediyl group, an ethanediyl group, a 1,3-propanediyl group, or a 2,2-propanediyl group.

Examples of the cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The cycloalkanediyl group is preferably a cycloalkanediyl group having 5 to 12 carbon atoms.

Examples of the alkenediyl group include an ethenediyl group, a propenediyl group, and a butenediyl group. The alkenediyl group is preferably an alkenediyl group having 2 to 6 carbon atoms.

Examples of the arenediyl group include a phenylene group, a tolylene group, and a naphthylene group. The arenediyl group is preferably an arenediyl group having 6 to 15 carbon atoms.

The divalent linking group represented by L¹ is preferably an alkanediyl group or an arenediyl group, more preferably an alkanediyl group having 1 to 4 carbon atoms or an arenediyl group having 6 to 10 carbon atoms, still more preferably a methanediyl group or a benzenediyl group.

Examples of the monovalent chain hydrocarbon group having 1 to 10 carbon atoms represented by R^{1A} and R^{1B} include a monovalent linear or branched saturated hydrocarbon group having 1 to 10 carbon atoms and a monovalent linear or branched unsaturated hydrocarbon group having 1 to 10 carbon atoms. Examples of the monovalent linear or branched saturated hydrocarbon group having 1 to 10 carbon atoms include alkyl groups such as a methyl group, an ethyl group, an n-propyl group, an i-propyl group, an n-butyl group, a 2-methylpropyl group, a 1-methylpropyl group, a t-butyl group, an n-pentyl group, an isopentyl group, and a neopentyl group. Examples of the monovalent linear chain or branched chain unsaturated hydrocarbon group having 2 to 10 carbon atoms include alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms represented by R^{1A} and R^{1B} include monocyclic or polycyclic saturated hydrocarbon groups and monocyclic or polycyclic unsaturated hydrocarbon groups. As the monocyclic saturated hydrocarbon group, a cyclopentyl group, a cyclohexyl group, a cycloheptyl group, and a cyclooctyl group are preferable. As the polycyclic cycloalkyl group, bridged alicyclic hydrocarbon groups such as a norbornyl group, an adamantyl group, a tricyclodecyl group, and a tetracyclododecyl group are preferable. Examples of the monocyclic unsaturated hydrocarbon group include monocyclic cycloalkenyl groups such as a cyclopropenyl group, a cyclobutenyl group, a cyclopentenyl group, and a cyclohexenyl group. Examples of the polycyclic unsaturated hydrocarbon group include polycyclic cycloalkenyl groups such as a norbornenyl group, a tricyclodecenyl group, and a tetracyclododecenyl group. It is to be noted that the bridged alicyclic hydrocarbon group refers to a polycyclic alicyclic hydrocarbon group in which two carbon atoms that compose an alicyclic ring and are not adjacent to each other are bonded by a linking group containing one or more carbon atoms.

As the divalent alicyclic group having 3 to 20 carbon atoms composed of R^{1A} and R^{1B} combined with each other together with a carbon atom to which R^{1A} and R^{1B} are bonded, groups obtained by removing one hydrogen atom from the monovalent alicyclic hydrocarbon group having 3 to 20 carbon atoms can be suitably employed.

As R^{1A} and R^{1B}, a monovalent chain hydrocarbon group having 1 to 10 carbon atoms or a divalent alicyclic group having 3 to 20 carbon atoms composed of R^{1A} and R^{1B} combined with each other together with a carbon atom to which R^{1A} and R^{1B} are bonded is preferable, a monovalent linear hydrocarbon group having 1 to 10 carbon atoms or a divalent alicyclic group having 5 to 10 carbon atoms is more preferable, and a methyl group, an ethyl group, a cyclopentanediyl group, or a cyclohexanediyl group is still more preferable.

Examples of the alkoxy group represented by R¹⁰¹ include alkoxy groups having 1 to 5 carbon atoms such as a methoxy group, an ethoxy group, and a propoxy group.

p is preferably 1 or 2.

Specific examples of the structural unit (I) include, but are not particularly limited to, structures represented by the following formulas (1-1) to (1-29). The structural units represented by the following formulas (1-1) to (1-18) also correspond to the structural unit (I-1).

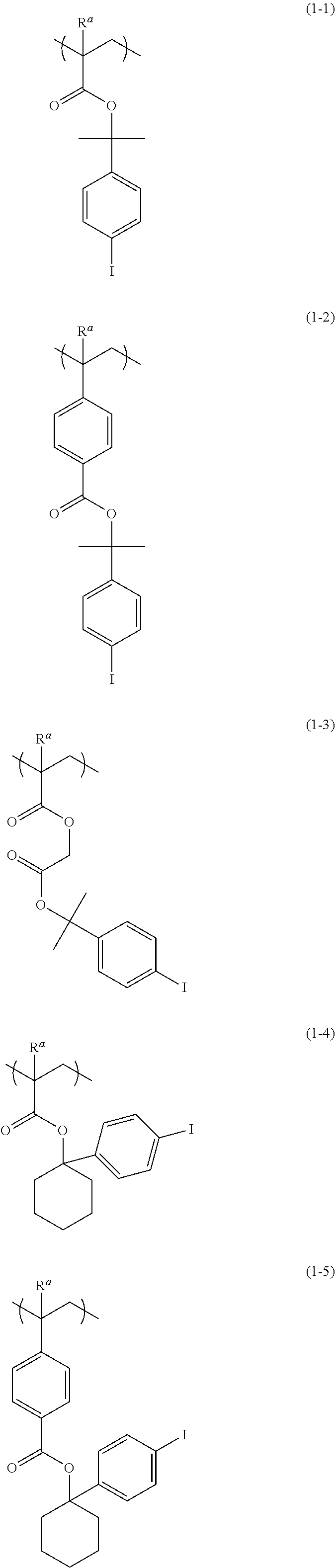

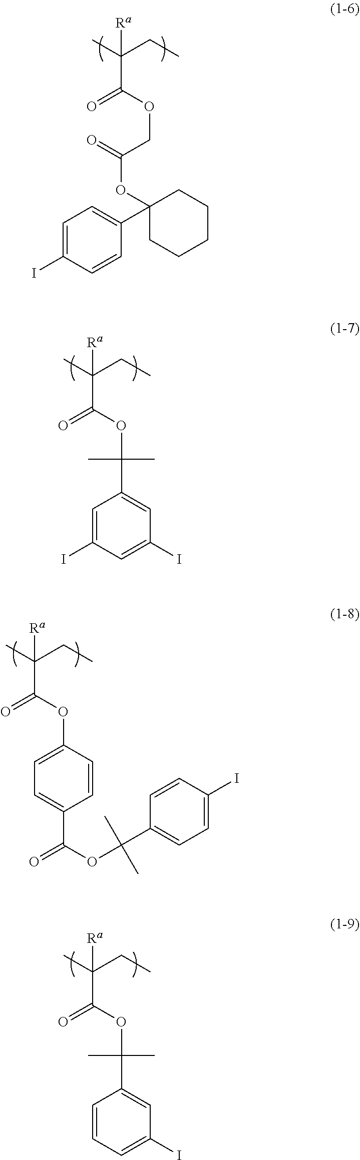

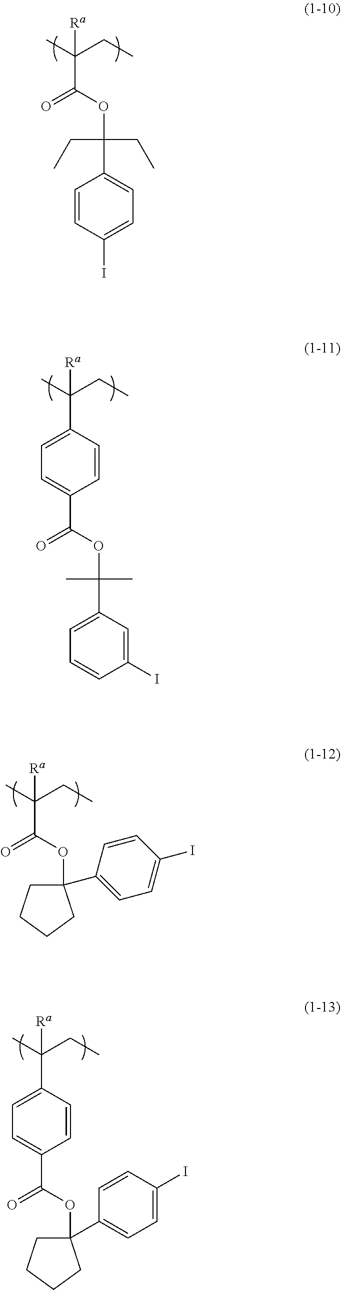

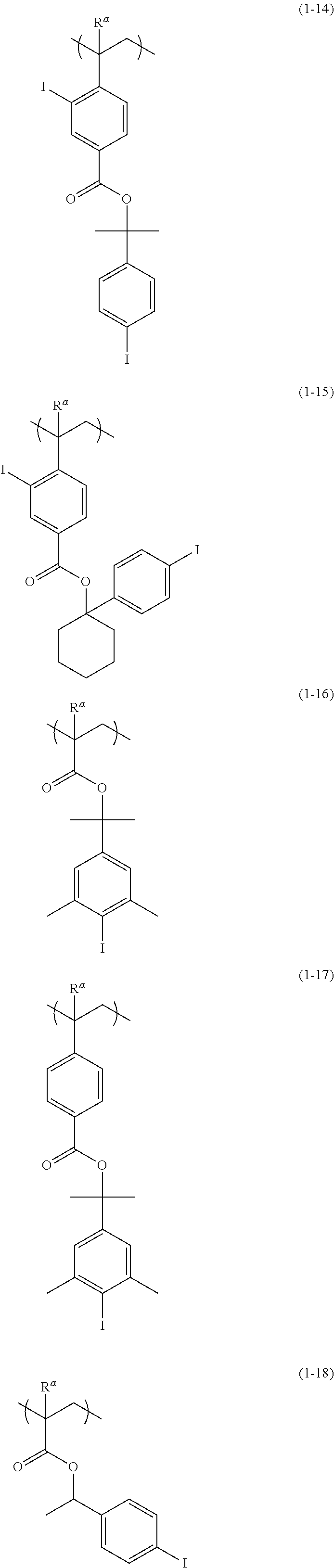

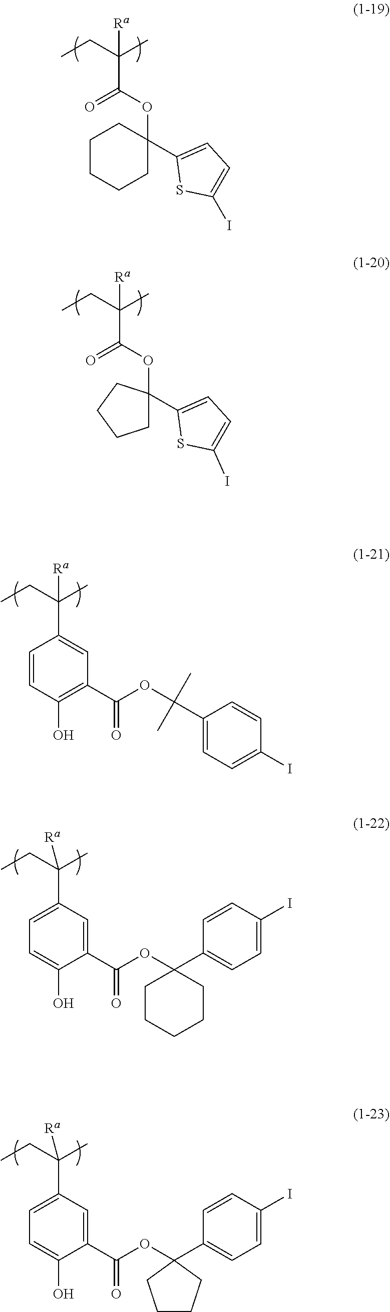

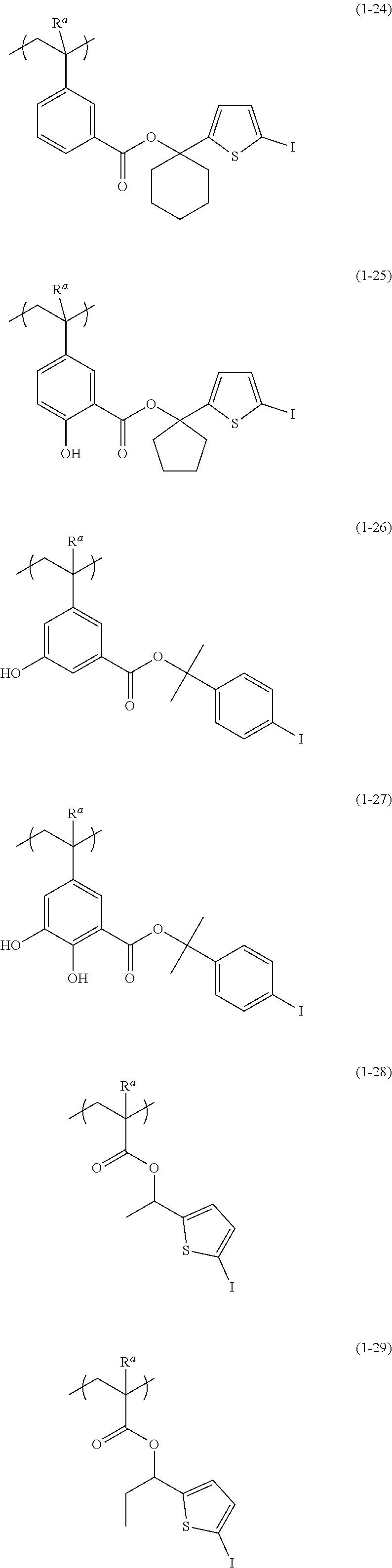

In the formulas, R^{α} has the same meaning as in the formula (1).

The lower limit of the content of the structural unit (I) (the total content when a plurality of structural units (I) are contained) is preferably 20 mol %, more preferably 30 mol %, still more preferably 35 mol % based on all structural units composing the base polymer. The upper limit of the content is preferably 85 mol %, more preferably 80 mol %, still more preferably 75 mol %, particularly preferably 70 mol %. When the content of the structural unit (I) is adjusted to within the above range, the sensitivity of the radiation-sensitive composition can be further improved.

### (Structural Unit (II))

The structural unit (II) is a structural unit having an acid-dissociable group having no iodo group (hereinafter, also referred to as an “iodo group-free acid-dissociable group”). As the structural unit (II), a structure obtained by removing an iodo group from the structural unit (I) can be suitably employed, provided that a structural unit having both an iodo group-free acid-dissociable group and a phenolic hydroxyl group is treated as a structural unit (III) described later. The base polymer may contain one structural unit (II) or two or more structural units (II) in combination.

Examples of the structural unit (II) include structural units represented by the following formulas (3-1) to (3-4) (hereinafter, also referred to as “structural units (II-1) to (II-4)”).

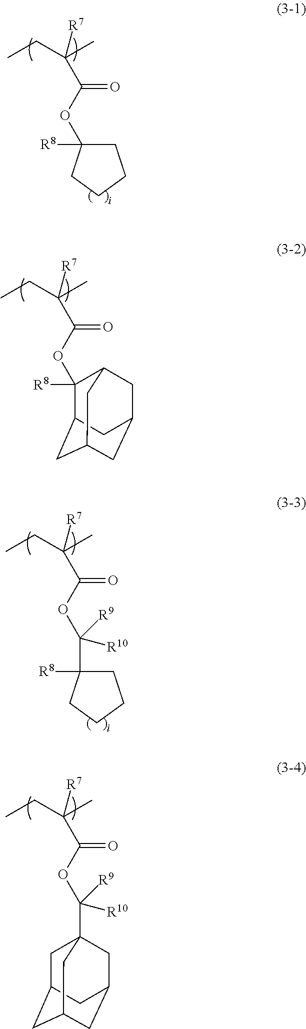

In the formulas (3-1) and (3-4),
R⁷ is a hydrogen atom, a fluorine atom, a methyl group, or a trifluoromethyl group. R⁸ is a monovalent hydrocarbon group having 1 to 20 carbon atoms. R⁹ and R¹⁰ are each independently a monovalent chain hydrocarbon group having 1 to 10 carbon atoms or a monovalent alicyclic hydrocarbon group having 3 to 20 carbon atoms, or represent a divalent alicyclic group having 3 to 20 carbon atoms composed of R⁹ and R¹⁰ combined with each other together with a carbon atom to which R⁹ and R¹⁰ are bonded.
i and j are each independently an integer of 1 to 4.

Examples of the monovalent hydrocarbon group having 1 to 20 carbon atoms represented by R⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

As the chain hydrocarbon group having 1 to 10 carbon atoms represented by R⁸ to R¹⁰, monovalent chain hydrocarbon groups having 1 to 10 carbon atoms represented by R^{1A} and R^{1B} of the formula (1) can be suitably employed.

As the alicyclic hydrocarbon group having 3 to 20 carbon atoms represented by R⁸ to R¹⁰, monovalent alicyclic hydrocarbon groups having 3 to 20 carbon atoms represented by R^{1A} and R^{1B} of the formula (1) can be suitably employed.

Examples of the monovalent aromatic hydrocarbon group having 6 to 20 carbon atoms represented by R⁸ include aryl groups such as a phenyl group, a tolyl group, a xylyl group, a naphthyl group, and an anthryl group; and aralkyl groups such as a benzyl group, a phenethyl group, and a naphthylmethyl group.

As the divalent alicyclic group having 3 to 20 carbon atoms composed of R⁹ and R¹⁰ combined with each other together with a carbon atom to which R⁹ and R¹⁰ are bonded, groups obtained by removing one hydrogen atom from the monovalent alicyclic hydrocarbon group having 3 to 20 carbon atoms can be suitably employed.

As R⁸ to R¹⁰, a methyl group, an ethyl group, an isopropyl group, an ethyl group, or a phenyl group is preferable.

i and j are preferably 1, 2, or 4.

Furthermore, the base polymer may contain structural units represented by the following formulas (1f) to (2f) as structural units (II) other than the above.

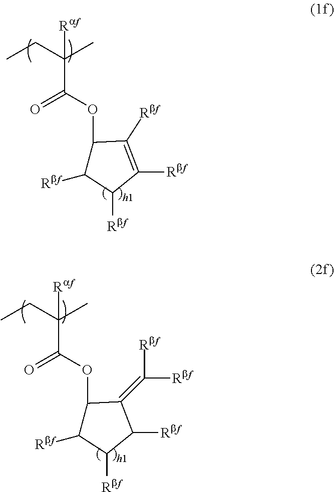

In the formulas (1f) to (2f), R^{αf}s are each independently a hydrogen atom, a fluorine atom, a methyl group, or a trifluoromethyl group. R^{βf}s are each independently a hydrogen atom or a chain alkyl group having 1 to 5 carbon atoms. h₁ is an integer of 1 to 4.

As the R^{βf}, a hydrogen atom, a methyl group, or an ethyl group is preferable. h₁ is preferably 1 or 2.

When the base polymer contains the structural unit (II), the lower limit of the content of the structural unit (II) (the total content when a plurality of structural units (II) are contained) is preferably 10 mol %, more preferably 15 mol %, still more preferably 20 mol % based on all structural units composing the base polymer. The upper limit of the content is preferably 50 mol %, more preferably 40 mol %, still more preferably 35 mol %. When the content of the structural unit (II) is adjusted to within the above range, the patternability of the radiation-sensitive composition can be further improved.

### (Structural Unit (III))

The base polymer preferably contains a structural unit (III) having a phenolic hydroxyl group. When the polymer contains the structural unit (III), the solubility into a developer can be more appropriately adjusted, and as a result, the sensitivity and the like of the radiation-sensitive composition can be further improved. When KrF excimer laser light, EUV, an electron beam, or the like is used as radiation to be applied in an exposure step in a resist pattern forming method, the structural unit (III) contributes to improvement in etching resistance and improvement in difference in solubility into a developer (dissolution contrast) between an exposed area and an unexposed area. In particular, the polymer containing the structural unit (III) can be suitably applied for pattern formation using exposure with radiation having a wavelength of 50 nm or less, such as an electron beam or EUV. The structural unit (III) is preferably represented by the following formula (2).

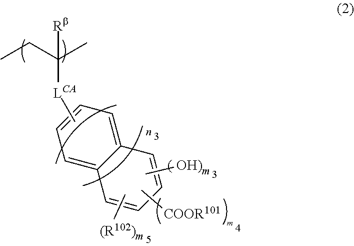

(In the formula (2),

R^{β} is a hydrogen atom, a fluorine atom, a methyl group, or a trifluoromethyl group.

L^{CA} is a single bond, —COO—*, or —O—*. * is a bond on the aromatic ring side.

R¹⁰¹ is an acid-dissociable group.

R¹⁰² is a halogen atom, a cyano group, a nitro group, an alkyl group, an alkoxycarbonyl group, an acyl group, or an acyloxy group. When there are a plurality of R¹⁰²s, the plurality of R¹⁰²s are the same as or different from each other.

n₃ is an integer of 0 to 2, m₃ is an integer of 1 to 8, and m₄ and m₅ are each independently an integer of 0 to 8, provided that 1≤m₃+m₄+m₅≤2n₃+5 is satisfied.)

R^{β} is preferably a hydrogen atom or a methyl group from the viewpoint of the copolymerizability of a monomer that affords the structural unit (III).

L^{CA} is preferably a single bond or —COO—*.

The acid-dissociable group represented by R¹⁰¹ is not particularly limited, and examples thereof include a structure in which R¹⁰¹ is bonded to —COO— to form a tertiary alkyl ester moiety, a structure in which R¹⁰¹ is bonded to —COO— to form a secondary unsaturated alkyl ester moiety having a double bond between the β-position carbon and the γ-position carbon of the terminal oxygen atom of —COO—, and a structure in which R¹⁰¹ is bonded to —COO— to form an acetal bond.

The halogen atom in R¹⁰² is preferably an iodine atom.

The n₃ is more preferably 0 or 1, still more preferably 0.

m₃ is preferably an integer of 1 to 3, more preferably 1 or 2.

m₄ is preferably an integer of 0 to 3, more preferably an integer of 0 to 2.

m₅ is preferably an integer of 0 to 3, more preferably an integer of 0 to 2.

As the structural unit (III), structural units represented by the following formulas (2-1) to (2-26) (hereinafter, also referred to as “structural units (III-1) to (III-26)”) and the like are preferable.

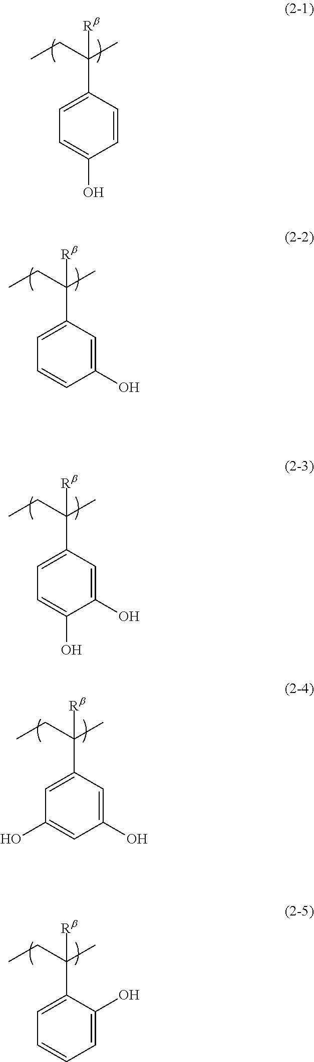

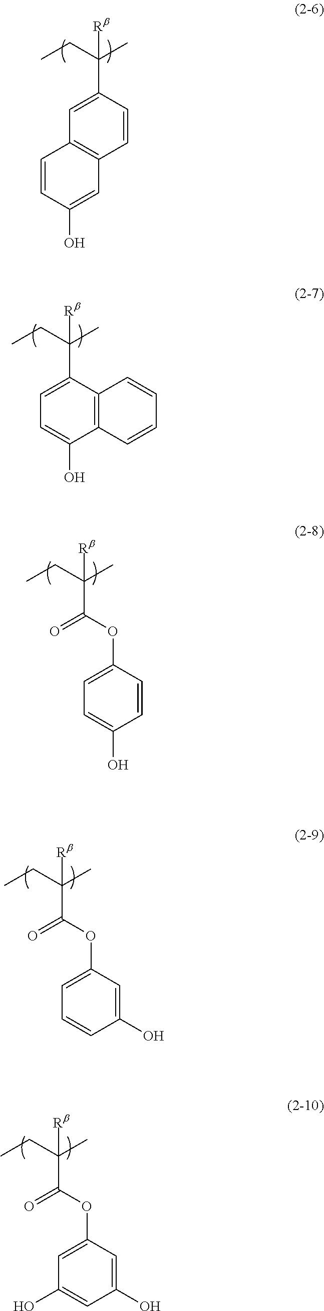

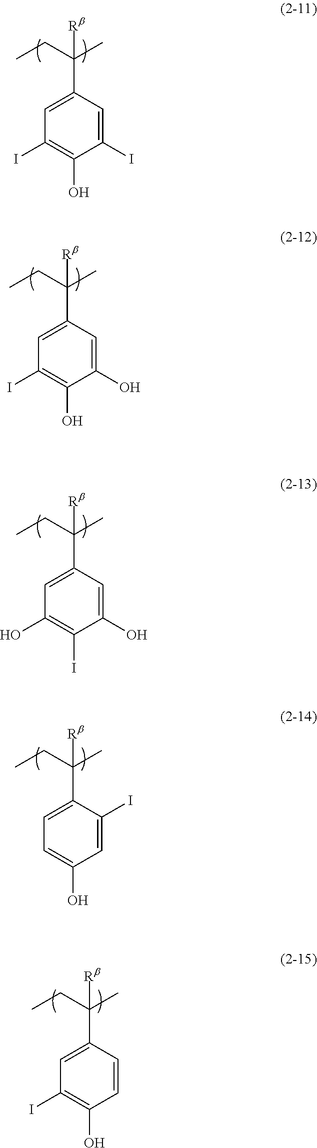

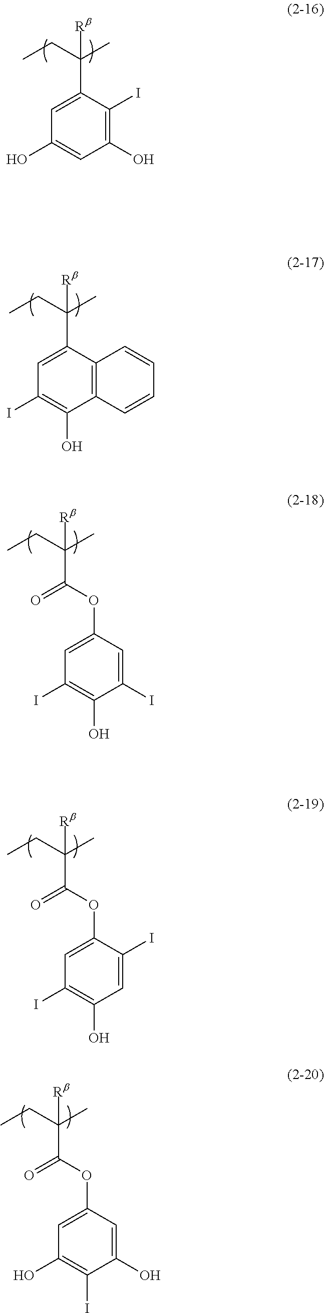

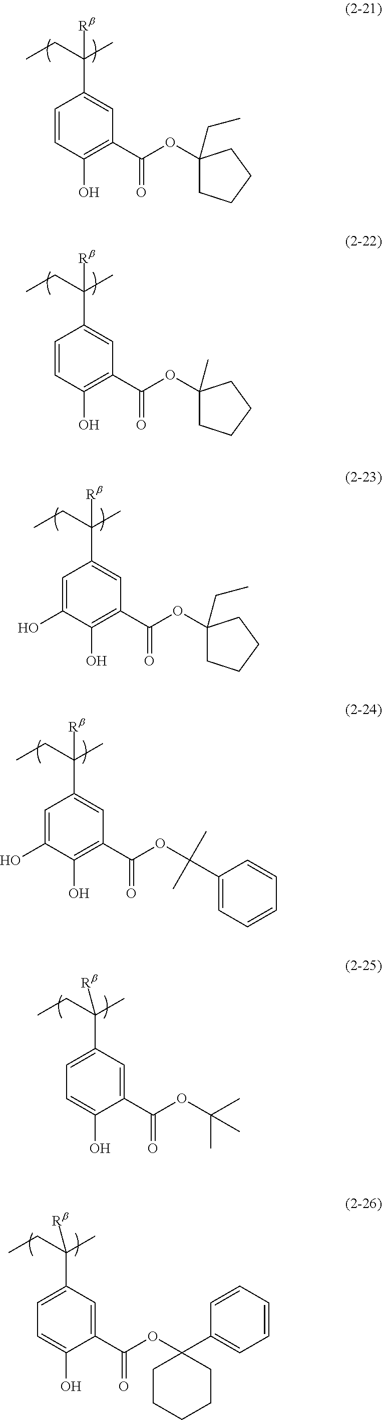

In the formulas (2-1) to (2-26), R is the same as in the formula (2).

The lower limit of the content of the structural unit (III) (the total when a plurality of structural units (III) are present) is preferably 10 mol %, more preferably 20 mol %, and still more preferably 30 mol % based on all structural units composing the polymer. The upper limit of the content is preferably 80 mol %, more preferably 70 mol %, still more preferably 65 mol %. When the content of the structural unit (III) is adjusted to within the above range, the sensitivity and the development contrast of the radiation-sensitive composition can be further improved.

### (Structural Unit (IV))

The base polymer may contain a structural unit (IV) having a first organic acid anion and a first onium cation and having a first acid generating structure that generates an acid that dissociates the acid-dissociable group through exposure to light. An onium salt structure formed of the first organic acid anion and the first onium cation (that is, the first acid generating structure) functions as a so-called radiation-sensitive acid generation structure.

In the specification, the “dissociation” of the acid-dissociable group refers to dissociation that occurs when post-exposure baking is performed at 110° C. for 60 seconds.

When the base polymer contains the radiation-sensitive acid generating structure, the polarity of the base polymer of the exposed portion increases, and therefore when the developer is an aqueous alkaline solution, the base polymer is soluble, and on the other hand, when the developer is an organic solvent, the base polymer is hardly soluble in the developer.

The form of the first organic acid anion and the first onium cation contained in the structural unit (IV) of the base polymer is not particularly limited, and the base polymer may have the first organic acid anion as a side chain portion or may have the first onium cation as a side chain portion. Having as a side chain portion means that the corresponding first organic acid anion or first onium cation is bonded (covalently bonded) to the main chain as a side chain structure of the base polymer. When the first organic acid anion is bonded to the main chain as a side chain structure of the base polymer, the first onium cation is ionically bonded to the first organic acid anion as a counter ion of the first organic acid anion. On the other hand, when the first onium cation is bonded to the main chain as a side chain structure of the base polymer, the first organic acid anion is ionically bonded to the first onium cation as a counter ion of the first onium cation. From the viewpoint of controlling the acid diffusion length, the base polymer preferably has the first organic acid anion as a side chain portion.

The first organic acid anion preferably has at least one anion selected from the group consisting of a sulfonate anion, a carboxylate anion, and a sulfonimide anion as an acid anion moiety. Examples of the acid generated through exposure to light may include a sulfonic acid, a carboxylic acid, and a sulfonimide corresponding to the acid anion moiety.

The first organic acid anion preferably includes —O—, —CO—, a cyclic structure, or a combination thereof as a structure other than the acid anion moiety. The combination also includes a structure (heterocyclic structure) in which —O—or —CO— is incorporated as a moiety forming a ring in a cyclic structure.

The cyclic structure may be any of a monocyclic ring, a polycyclic ring, or a combination thereof. The cyclic structure may be any of an alicyclic structure, an aromatic ring structure, a heterocyclic structure, or a combination thereof. In the case of the combination, the ring structure may be a structure in which ring structures are bonded through a chain structure, or two or more ring structures may form a fused ring structure, a bridged ring structure, or a spiro ring structure. A divalent heteroatom-containing group may be present between carbons forming the skeleton of the cyclic structure or the chain structure, and some or all of hydrogen atoms on carbon atoms of the cyclic structure or the chain structure may be substituted with another substituent.

Examples of the divalent heteroatom-containing group include —CO—, —CS—, —NR′—, —O—, —S—, —SO₂—, or a divalent group obtained by combining them. R′ is a hydrogen atom or a hydrocarbon group having 1 to 10 carbon atoms.

As the substituent with which some or all of hydrogen atoms on carbon atoms of the cyclic structure or the chain structure are substituted, a substituent that can be possessed by the divalent linking group represented by L¹ of the formula (1) can be suitably employed.

In the first acid generating structure, it is preferable that the first organic acid anion have a sulfonate anion as an acid anion moiety, and an electron attractive group be bonded to a carbon atom adjacent to a sulfur atom in the sulfonate anion. As a result, the first acid generating structure can efficiently exhibit the above function. Examples of the electron attractive group include a fluorine atom, a fluorinated hydrocarbon group, a nitro group, and a cyano group. As the fluorinated hydrocarbon group, a perfluoroalkyl group having 1 to 5 carbon atoms is preferable.

The first organic acid anion preferably has an iodo group. The first organic acid anion preferably contains the iodo group-containing aromatic ring structure as an aspect of containing an iodo group.

Examples of the first onium cation include radiolytic onium cations. Examples of the radiolytic onium cation include a sulfonium cation, a tetrahydrothiophenium cation, and an iodonium cation. Among them, a sulfonium cation or an iodonium cation is preferable, and a sulfonium cation is more preferable.

The first onium cation preferably has an iodo group. The first onium cation preferably contains the iodo group-containing aromatic ring structure as an aspect of containing an iodo group.

The first onium cation in the structural unit (IV) is preferably a fluoro group-containing onium cation having a fluoro group. The fluoro group-containing onium cation preferably has a fluoro group-containing aromatic ring structure. The fluoro group-containing aromatic ring structure is a structure in which some or all of hydrogen atoms of the aromatic ring are substituted with a fluoro group. As the aromatic ring in the fluoro group-containing aromatic ring structure, an aromatic ring in the iodo group-containing aromatic ring structure can be suitably employed. As a result, the radiation absorption efficiency is increased, so that the sensitivity can be improved.

When the structural unit (IV) has the above structures in combination, the above functions can be efficiently exhibited.

The structural unit (IV) is preferably a structural unit represented by the following formula (a1) (hereinafter, also referred to as a “structural unit (IV-1)”) or a structural unit represented by the following formula (a2) (hereinafter, also referred to as a “structural unit (IV-2)”).

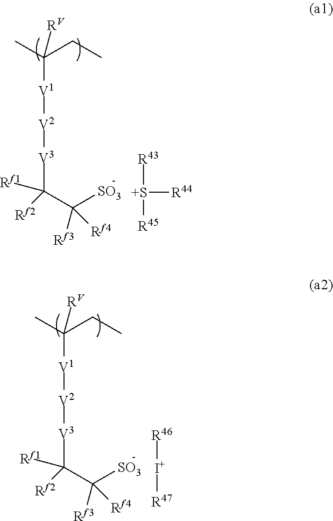

In the formulas, R^{V} is a hydrogen atom or a methyl group. V¹ is a single bond or an ester group. V² is a linear, branched or cyclic alkylene group having 1 to 12 carbon atoms, a cycloalkylene group having 3 to 12 carbon atoms, an arylene group having 6 to 10 carbon atoms, a combination thereof, or an amide bond, and a part of a methylene group composing the alkylene group, the cycloalkylene group, or the arylene group may be substituted with an ether group, an ester group, or a lactone ring-containing group. V³ is a single bond, an ether group, an ester group, a linear or branched alkylene group having 1 to 12 carbon atoms, or a cyclic cycloalkylene group having 3 to 12 carbon atoms, and a part of a methylene group composing the alkylene group may be substituted with an ether group or an ester group. Some or all of hydrogen atoms of V² and V³ may be substituted with a heteroatom or a monovalent hydrocarbon group having 1 to 20 carbon atoms optionally containing a heteroatom. R^{f1} to R^{f4} are each independently a hydrogen atom, a fluorine atom, or a trifluoromethyl group, and at least one of R^{f1} to R^{f4} is a fluorine atom or a fluorinated hydrocarbon group. R⁴³ to R⁴⁷ are each independently a monovalent hydrocarbon group having 1 to 20 carbon atoms and optionally containing a heteroatom, and R⁴³ and R⁴⁴ may be bonded to each other to form a ring together with a sulfur atom to which R⁴³ and R⁴⁴ are bonded. It is preferable that at least one of R⁴³ to R⁴⁵ and at least one of R⁴⁶ to R⁴⁷ each contain the iodo group-containing aromatic ring structure or the fluoro group-containing aromatic ring structure.

As the monovalent hydrocarbon group having 1 to 20 carbon atoms in V², V³, and R⁴³ to R⁴⁷, an alkyl group having 1 to 12 carbon atoms, a cycloalkyl group having 3 to 12 carbon atoms, or an aryl group having 6 to 20 carbon atoms is preferable, and some or all of hydrogen atoms of these groups may be substituted with a heteroatom-containing group such as a hydroxy group, a carboxy group, a halogen atom, an oxo group, a cyano group, an amide group, a nitro group, a sultone group, a sulfone group or a sulfonium salt-containing group, an alkoxy group, or an alkoxycarbonyl group, and a part of a methylene group composing these groups may be substituted with an ether group, an ester group, a carbonyl group, a carbonate group, or a sulfonate ester group.

The structural units (IV-1) to (IV-2) are preferably represented by the following formulas (a1-1) and (a2-1), respectively.

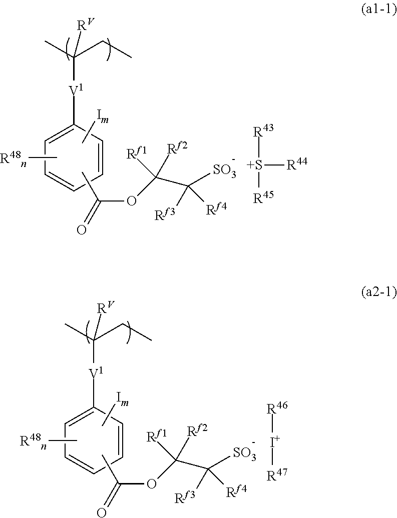

In the formulas, R^{V}, R⁴³ to R⁴⁷, R^{f1} to R^{f4}, and V¹ have the same meanings as in the formula (a1) or (a2). R⁴⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to 5 carbon atoms. m is an integer of 0 to 4. n is an integer of 0 to 3.

Examples of the first organic acid anion of the monomer that affords the structural unit (IV) (including the structural unit (IV-1) and the structural unit (IV-2)) include, but are not limited to, those shown below. In the following, all of the first organic acid anions having an aromatic ring structure have the iodo group-containing aromatic ring structure, but the structural unit (IV) does not necessarily have the iodo group-containing aromatic ring structure. As the first organic acid anion having no iodo group-containing aromatic ring structure, a structure in which an iodine atom in the following formula is substituted with a hydrogen atom, another substituent, or the like can be suitably employed. In the following formula, R^{V} has the same meaning as described above.

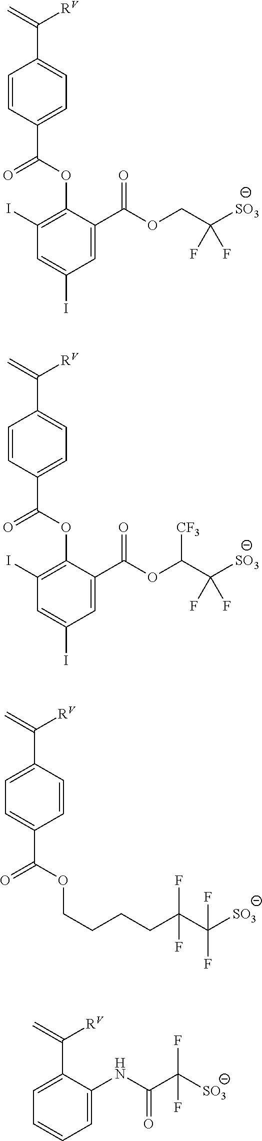

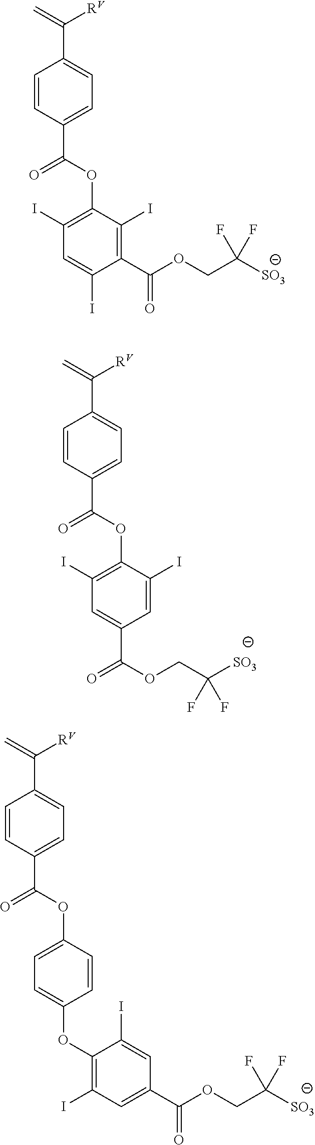

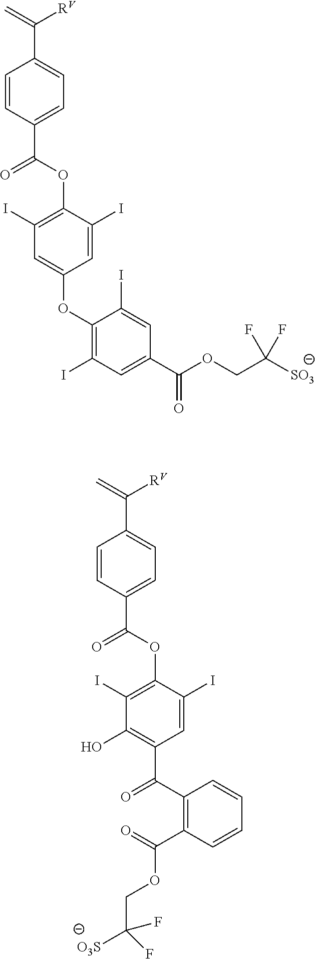

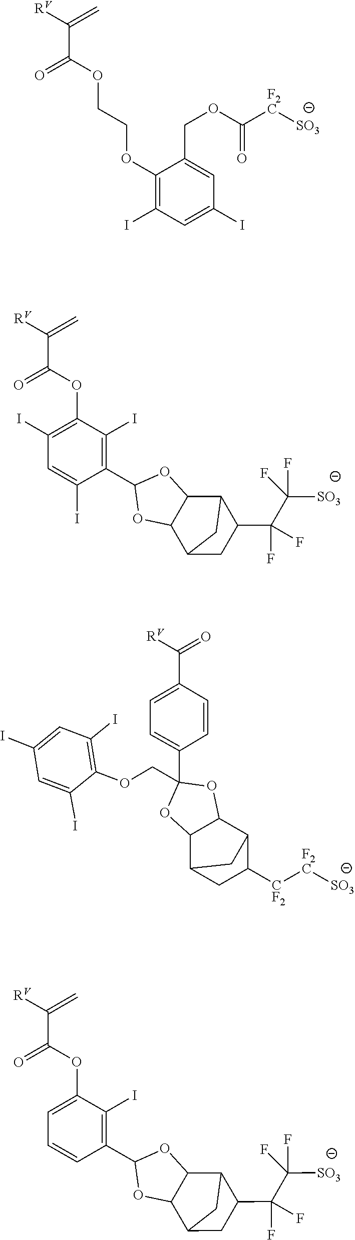

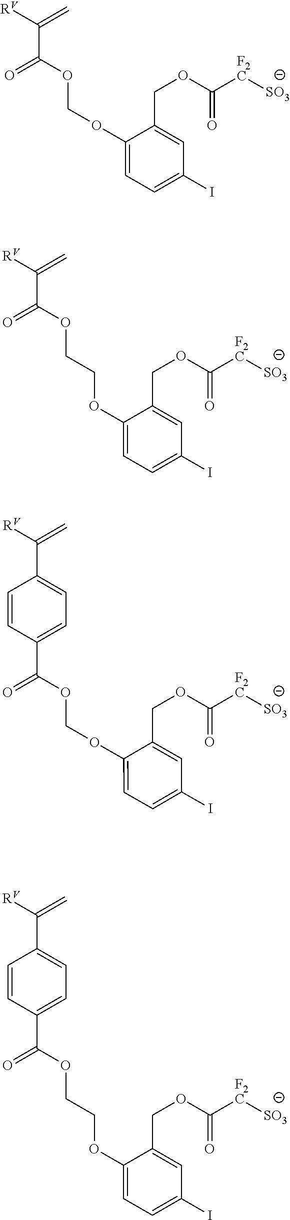

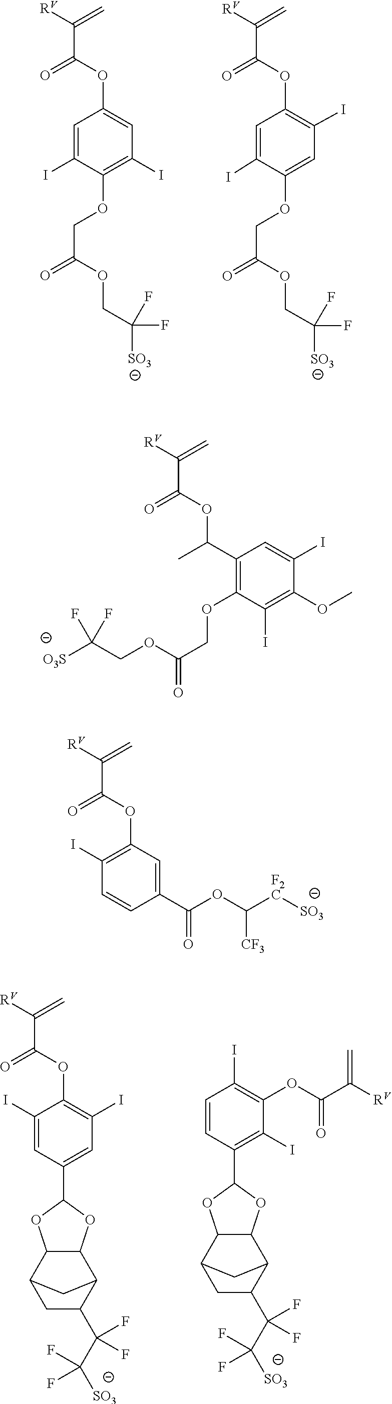

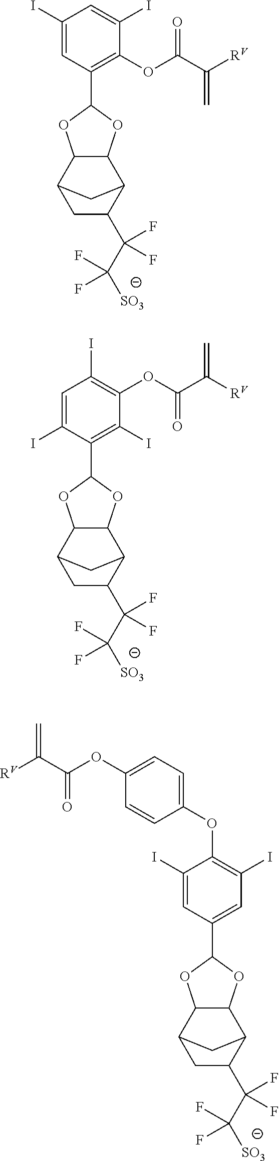

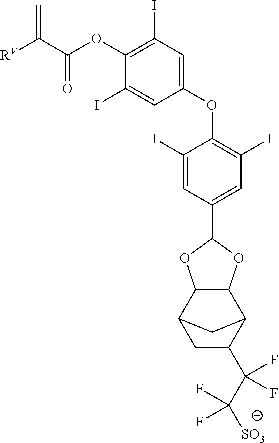

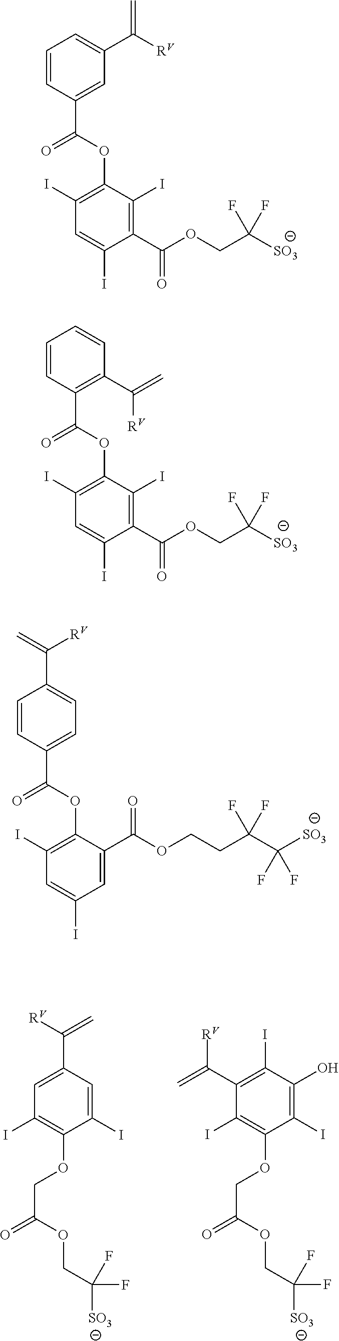

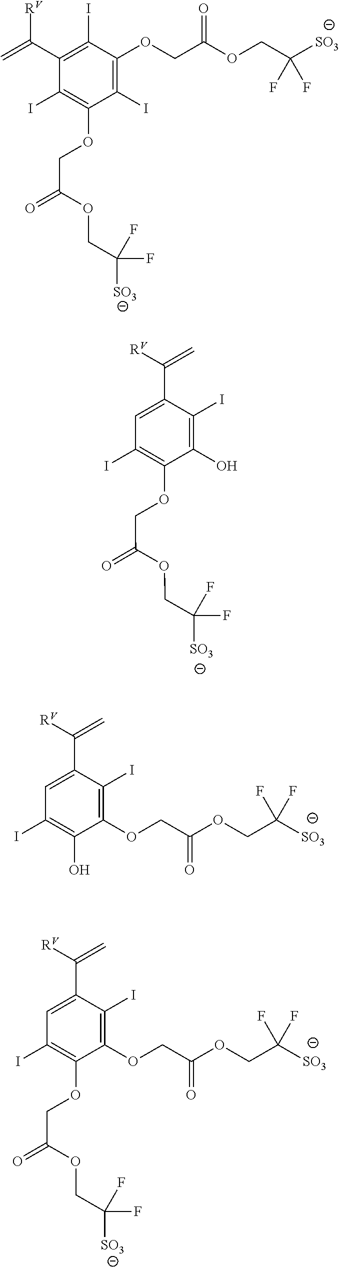

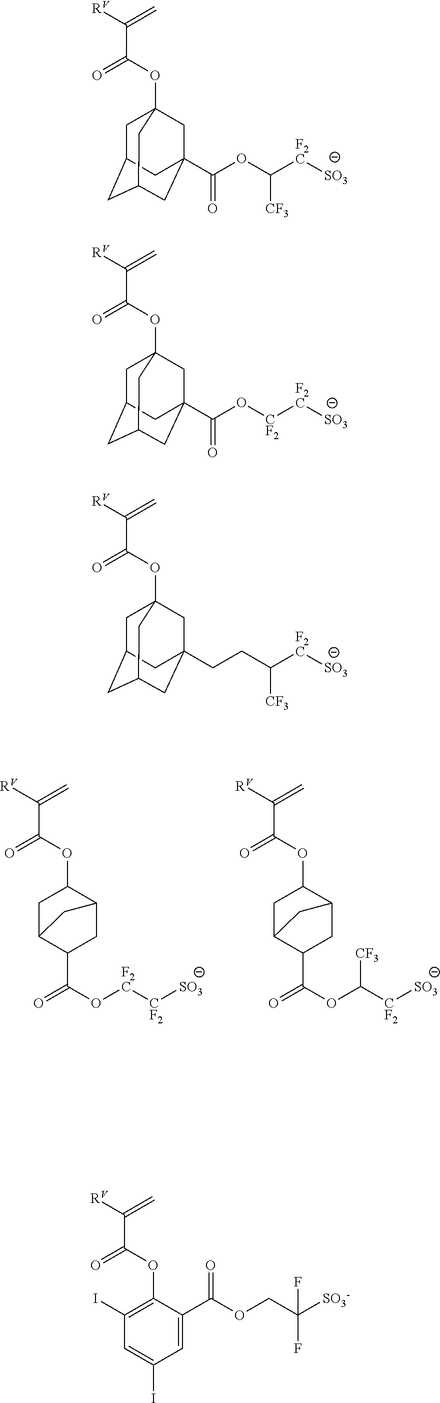

In the above formulas, R^{V} has the same meaning as in the above formula (a1).

The first onium cation of the structural unit (IV-1) is preferably represented by the following formula (Q-1).

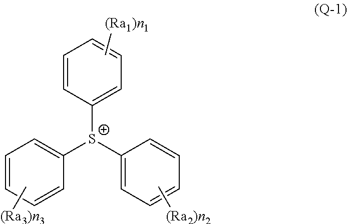

In the formula (Q-1), Ra1 and Ra2 each independently represent a substituent. n1 represents an integer of 0 to 5, and when n1 is 2 or more, the plurality of Ra1s may be the same as or different from each other. n2 represents an integer of 0 to 5, and when n2 is 2 or more, the plurality of Ra2s may be the same as or different from each other. n3 represents an integer of 0 to 5, and when n3 is 2 or more, the plurality of Ra3s may be the same as or different from each other. Ra3 represents a substituent. Ra1 and Ra2 may be linked to each other to form a ring. When n1 is 2 or more, the plurality of Ra1s may be linked to each other to form a ring. When n2 is 2 or more, the plurality of Ra2s may be linked to each other to form a ring.

The substituent represented by Ra1, Ra2 and Ra3 is preferably an alkyl group, a cycloalkyl group, an alkoxy group, a cycloalkyloxy group, an alkoxycarbonyl group, an alkylsulfonyl group, a hydroxy group, a halogen atom, or a halogenated hydrocarbon group.

The alkyl group as Ra1 and Ra2 may be either a linear alkyl group or a branched alkyl group. The alkyl group is preferably one having 1 to 10 carbon atoms, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among them, a methyl group, an ethyl group, an n-butyl group, and a t-butyl group are particularly preferable.

Examples of the cycloalkyl group as Ra1 and Ra2 include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among them, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra1 and Ra2 include those listed above as the alkyl group as Ra1 and Ra2. As the alkoxy group, a methoxy group, an ethoxy group, an n-propoxy group, and an n-butoxy group are particularly preferable.

Examples of the cycloalkyl group moiety of the cycloalkyloxy group as Ra1 and Ra2 include those listed above as the cycloalkyl group as Ra1 and Ra2. As the cycloalkyloxy group, a cyclopentyloxy group and a cyclohexyloxy group are particularly preferable.

Examples of the alkoxy group moiety of the alkoxycarbonyl group as Ra1 and Ra2 include those listed above as the alkoxy group as Ra1 and Ra2. As the alkoxycarbonyl group, a methoxycarbonyl group, an ethoxycarbonyl group, and an n-butoxycarbonyl group are particularly preferable.

Examples of the alkyl group moiety of the alkylsulfonyl group as Ra1 and Ra2 include those listed above as the alkyl group as Ra1 and Ra2. Examples of the cycloalkyl group moiety of the cycloalkylsulfonyl group as Ra1 and Ra2 include those listed above as the cycloalkyl group as Ra1 and Ra2. As the alkylsulfonyl group or the cycloalkylsulfonyl group, a methanesulfonyl group, an ethanesulfonyl group, an n-propanesulfonyl group, an n-butanesulfonyl group, a cyclopentanesulfonyl group, and a cyclohexanesulfonyl group are particularly preferable.

Each of the groups Ra1 and Ra2 may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra1 and Ra2 include a fluorine atom, a chlorine atom, a bromine atom, and an iodine atom, and a fluorine atom and an iodine atom are preferable.

As the halogenated hydrocarbon group as Ra1 and Ra2, a halogenated alkyl group is preferable. Examples of the alkyl group and the halogen atom composing the halogenated alkyl group include those described above. Among them, a fluorinated alkyl group is preferable, and CF₃ is more preferable.

As described above, Ra1 and Ra2 may be linked to each other to form a ring (namely, a heterocyclic ring containing a sulfur atom). In this case, it is preferable that Ra1 and Ra2 be bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having 20 or less carbon atoms in total are preferable. When Ra1 and Ra2 are linked to each other to form a ring, it is preferable that Ra1 and Ra2 be bonded to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When n1 is 2 or more, the plurality of Ra1s may be linked to each other to form a ring, and when n2 is 2 or more, the plurality of Ra2s may be linked to each other to form a ring. Examples thereof include an aspect in which two Ra1s are linked to each other to form a naphthalene ring together with a benzene ring to which two Ra1s are bonded.

Ra3 is preferably a fluorine atom, an iodine atom, or a group having one or more fluorine atoms. Examples of the group having a fluorine atom may include groups in which a halogen atom of the alkyl group, cycloalkyl group, alkoxy group, cycloalkyloxy group, alkoxycarbonyl group, and alkylsulfonyl group as Ra1 and Ra2 is substituted with a fluorine atom. Among them, fluorinated alkyl groups are suitable, CF₃, C₂F₅, C₃F₇, C₄F₉, C₅F₁₁, C₆F₁₃, C₇F₁₅, CBF₁, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra3 is preferably a fluorine atom, an iodine atom, or CF₃, more preferably a fluorine atom or an iodine atom.

n1 and n2 are each independently preferably an integer of 0 to 3, preferably an integer of 0 to 2.

n3 is preferably an integer of 1 to 3, more preferably 1 or 2.

(n1+n2+n3) is preferably an integer of 1 to 15, more preferably an integer of 1 to 9, still more preferably an integer of 2 to 6, particularly preferably an integer of 3 to 6. When (n1+n2+n3) is 1, it is preferable that n3=1, and Ra3 be a fluorine atom, an iodine atom, or CF₃. When (n1+n2+n3) is 2, a combination in which n1=n3=1, and Ra1 and Ra3 are each independently a fluorine atom, an iodine atom, or CF₃, and a combination in which n3=2, and Ra3 is a fluorine atom, an iodine atom, or CF₃ are preferable. When (n1+n2+n3) is 3, a combination in which n1=n2=n3=1, and Ra1 to Ra3 are each independently a fluorine atom, an iodine atom, or CF₃ is preferable. When (n1+n2+n3) is 4, a combination in which n1=n3=2, and Ra1 and Ra3 are each independently a fluorine atom, an iodine atom, or CF₃ is preferable. When (n1+n2+n3) is 5, a combination in which n1=n2=1 and n3=3, and Ra1 to Ra3 are each independently a fluorine atom, an iodine atom, or CF₃, a combination in which n1=n2=2 and n3=1, and Ra1 to Ra3 are each independently a fluorine atom, an iodine atom, or CF₃, and a combination in which n3=5, and Ra3s are each independently a fluorine atom, an iodine atom, or CF₃ are preferable. When (n1+n2+n3) is 6, a combination in which n1=n2=n3=2, and Ra1 to Ra3 are each independently a fluorine atom, an iodine atom, or CF₃ is preferable.

Specific examples of such an onium cation represented by the formula (Q-1) include those shown below. A fluorine atom or an iodine atom in the following onium cation may be substituted with a hydrogen atom or another substituent.

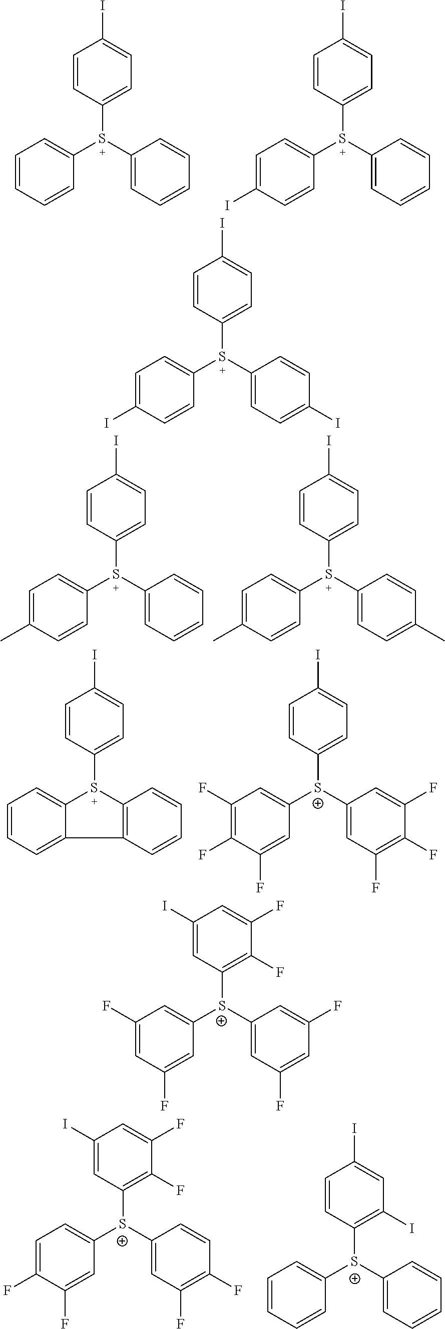

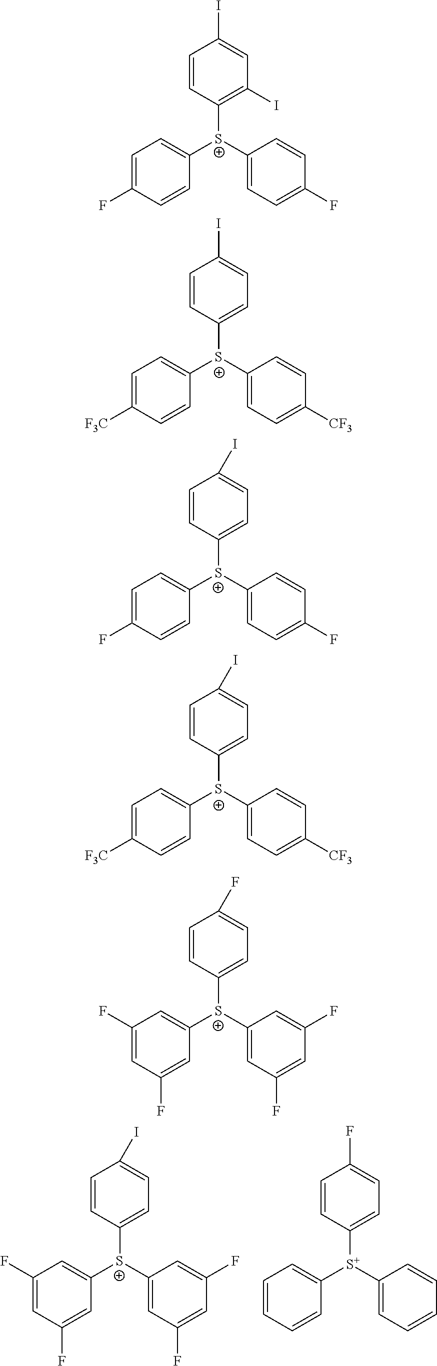

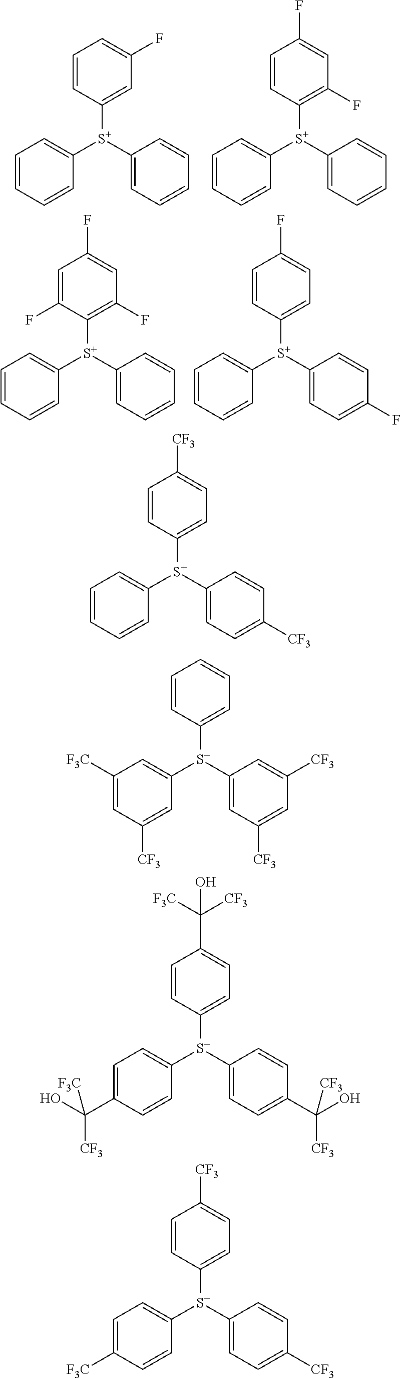

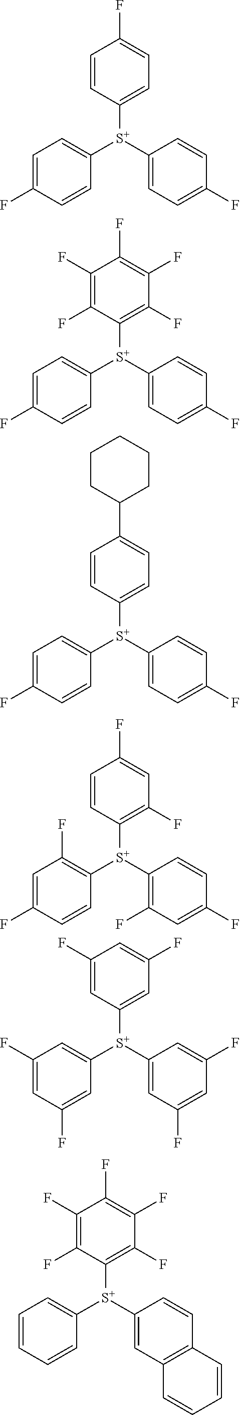 [SMILES: Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1 ; Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F]

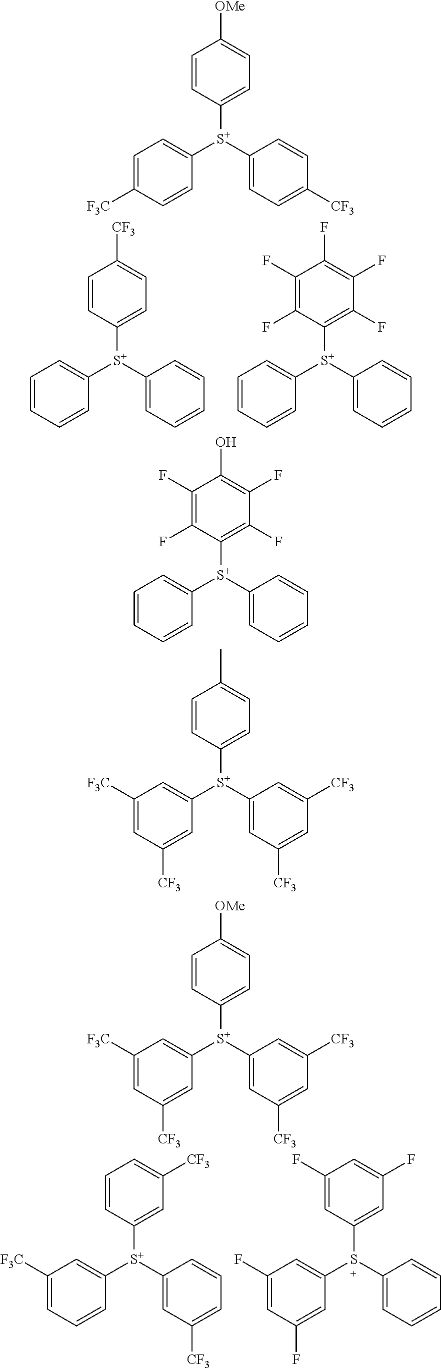

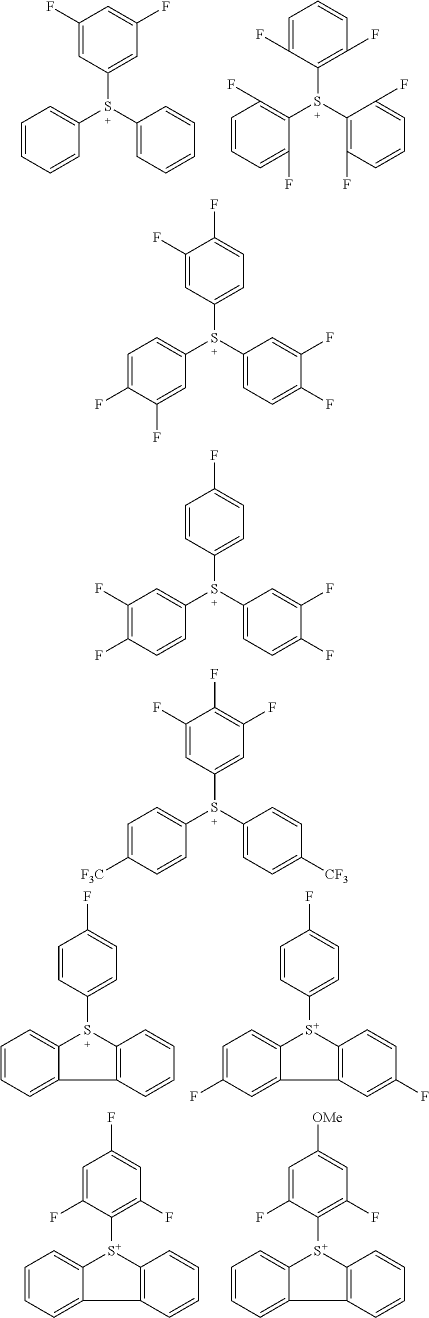

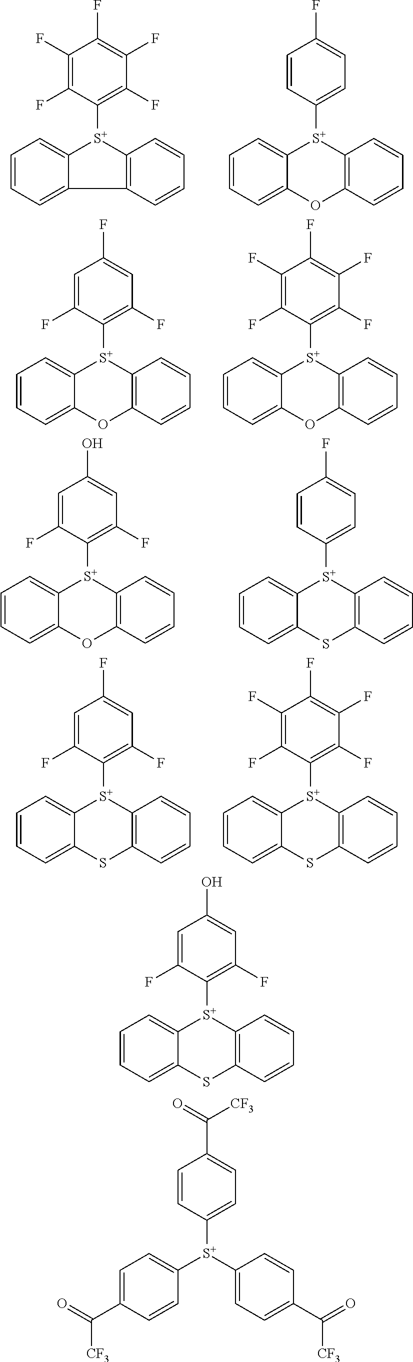

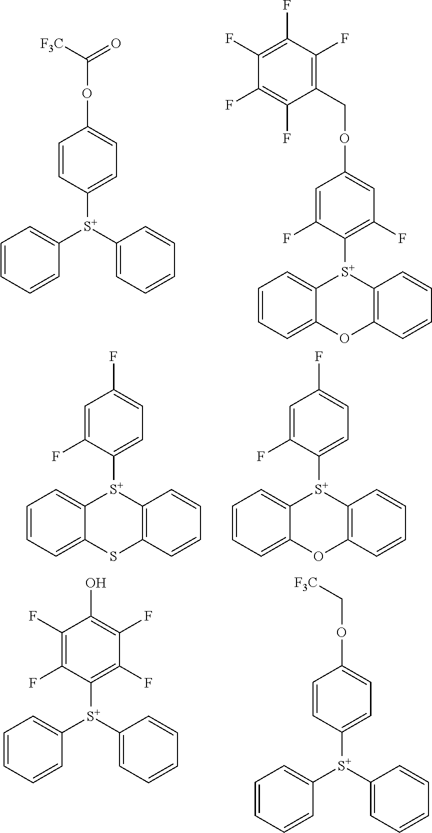 [SMILES: O=C(Oc1ccc([S+](c2ccccc2)c2ccccc2)cc1)C(F)(F)F ; Fc1cc(OCc2c(F)c(F)c(F)c(F)c2F)cc(F)c1[S+]1c2ccccc2Oc2ccccc21 ; Fc1ccc([S+]2c3ccccc3Sc3ccccc32)c(F)c1 ; Fc1ccc([S+]2c3ccccc3Oc3ccccc32)c(F)c1 ; Oc1c(F)c(F)c([S+](c2ccccc2)c2ccccc2)c(F)c1F ; FC(F)(F)COc1ccc([S+](c2ccccc2)c2ccccc2)cc1]

The onium cation of the structural unit (IV-2) is preferably a diaryliodonium cation having one or more fluorine atoms or iodine atoms. It is preferable that at least one of aryl groups of the onium cation of the structural unit (IV-2) have the fluoro group-containing aromatic ring structure or the iodo group-containing aromatic ring structure.

As a side chain structure of the base polymer, an aspect can also be suitably employed in which the first onium cation is bonded to the main chain, and the first organic acid anion is ionically bonded to the first onium cation as a counter ion of the first onium cation. In this case, it is preferable that the first onium cation be bonded to the main chain via a divalent linking group or a single bond, and a structure from V² to SO₃⁻ in the formula (a1) or (a2) be ionically bonded to the first onium cation as a counter ion. As the divalent linking group, a divalent linking group represented by L¹ of the formula (1) can be suitably employed.

When the base polymer contains the structural unit (IV), the lower limit of the content of the structural unit (IV) (the total content when a plurality of structural units (IV) are contained) is preferably 2 mol %, more preferably 3 mol %, still more preferably 5 mol % based on all structural units composing the base polymer. The upper limit of the content is preferably 30 mol %, more preferably 25 mol %, still more preferably 20 mol %. When the content of the structural unit (IV) is adjusted to within the above range, the function as an acid generating structure can be sufficiently exhibited, and the various resist properties can be exhibited.

The monomer that affords the structural units (IV-1) to (IV-2) can be synthesized, for example, by the same method as that for a sulfonium salt having a polymerizable anion described in JP-B-5201363.

### (Structural Unit (V))

The base polymer may contain a structural unit (V) having a second organic acid anion and a second onium cation and having a second acid generating structure that generates an acid that does not dissociate the acid-dissociable group through exposure to light. An onium salt structure formed of the second organic acid anion and the second onium cation (that is, the second acid generating structure) functions as an acid diffusion controlling structure. Specifically, the second acid generating structure has a function of suppressing, by salt exchange, the diffusion of an acid generated from the first acid generating structure in the unexposed portion without substantially dissociate the acid-dissociable group of the structural unit (I) under a pattern forming condition using the radiation-sensitive composition. The acid generated from the second acid generating structure can be said to be a relatively weaker acid (acid having a higher pKa) than the acid generated from the first acid generating structure. Whether the onium salt structure functions as a radiation-sensitive acid generating structure or an acid diffusion controlling structure depends on the energy required for dissociating the acid-dissociable group of the base polymer, and the acidity of the onium salt structure or the generated acid.

The form of the second organic acid anion and the second onium cation contained in the structural unit (V) of the base polymer is not particularly limited, but the base polymer may have the second organic acid anion as a side chain portion or may have the second onium cation as a side chain portion. Having as a side chain portion means that the corresponding second organic acid anion or second onium cation is bonded (covalently bonded) to the main chain as a side chain structure of the base polymer. When the second organic acid anion is bonded to the main chain as a side chain structure of the base polymer, the second onium cation is ionically bonded to the second organic acid anion as a counter ion of the second organic acid anion. On the other hand, when the second onium cation is bonded to the main chain as a side chain structure of the base polymer, the second organic acid anion is ionically bonded to the second onium cation as a counter ion of the second onium cation. From the viewpoint of development contrast, the base polymer preferably has the second organic acid anion as a side chain portion.

The second organic acid anion preferably has a sulfonate anion or a carboxylate anion as an acid anion moiety, more preferably has a carboxylate anion, provided that when the second organic acid anion has the sulfonate anion, an electron attractive group is not bonded to a carbon atom adjacent to a sulfur atom in the sulfonate anion. Examples of the electron attractive group include electron attractive groups that can be possessed by the first organic acid anion in the first acid generating structure. The acid generated through exposure to light is a carboxylic acid or a sulfonic acid corresponding to the acid anion moiety.

The second organic acid anion preferably includes —O—, —CO—, a cyclic structure, or a combination thereof as a structure in addition to the acid anion moiety. As such a structure, the structure represented by the first organic acid anion can be suitably employed.

The second organic acid anion preferably has an iodo group or a hydroxy group. The second organic acid anion preferably contains the iodo group-containing aromatic ring structure as an aspect of containing an iodo group.

Examples of the second onium cation include a radiolytic or non-radiolytic onium cation. Examples of the radiolytic or non-radiolytic onium cation include a sulfonium cation, a tetrahydrothiophenium cation, an iodonium cation, and an ammonium cation. Among them, a sulfonium cation or an iodonium cation is preferable, and a sulfonium cation is more preferable.

The second onium cation preferably has an iodo group. The non-radiolytic onium cation preferably contains the iodo group-containing aromatic ring structure as an aspect of containing an iodo group.

The second onium cation in the structural unit (V) preferably has the fluoro group-containing aromatic ring structure. As a result, the radiation absorption efficiency is increased, so that the sensitivity can be improved.

When the structural unit (V) has the above structures in combination, the above functions can be efficiently exhibited.

The structural unit (V) is preferably a structural unit represented by the following formula (p1) (hereinafter, also referred to as a “structural unit (V-1)”).

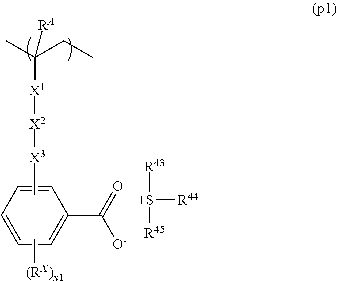

In the formula (p1), R^{A} is a hydrogen atom or a methyl group.

In the formula (p1), X¹ is a single bond, an ester bond, an ether bond, a phenylene group, or a naphthylene group.

In the formula (p1), X² is a single bond, a saturated hydrocarbylene group having 1 to 12 carbon atoms, or a phenylene group, and the saturated hydrocarbylene group may contain an ether bond, an ester bond, an amide bond, a lactone ring, or a sultone ring. The hydrocarbylene group represented by X² may be linear, branched, or cyclic, and specific examples thereof include a methylene group, an ethane-1,1-diyl group, an ethane-1,2-diyl group, a propane-1,2-diyl group, a propane-1,3-diyl group, a propane-2,2-diyl group, a butane-1,2-diyl group, a butane-1,3-diyl group, a butane-1,4-diyl group, a butane-2,2-diyl group, a butane-2,3-diyl group, a 2-methylpropane-1,3-diyl group, a pentane-1,5-diyl group, a hexane-1,6-diyl group, a heptane-1,7-diyl group, an octane-1,8-diyl group, a nonane-1,9-diyl group, alkanediyl groups having 1 to 12 carbon atoms such as a decane-1,10-diyl group; cyclic saturated hydrocarbylene groups having 3 to 12 carbon atoms such as a cyclopentanediyl group, a cyclohexanediyl group, a norbornanediyl group, or an adamantanediyl group; and groups obtained by combining them.

In the formula (p1), X³ is a single bond, an ester bond, or an ether bond.

In the formula (p1), R^{X} is a linear, branched or cyclic alkyl group having 1 to 5 carbon atoms, a halogen atom, a hydroxy group, a linear, branched or cyclic alkoxy group having 1 to 4 carbon atoms, or a linear, branched or cyclic alkoxycarbonyl group having 2 to 5 carbon atoms.

In the formula (p1), R⁴³ to R⁴⁵ have the same meaning as in the formula (a1).

In the formula (p1), x1 is an integer of 0 to 3. When x1 is 2 or more, the plurality of R_{X}s are the same as or different from each other.

Instead of the sulfonium cation in the formula (p1), an iodonium cation can also be used. As the iodonium cation, a diaryliodonium cation shown as the onium cation of the structural unit (II-2) can be suitably employed.

Examples of the second organic acid anion of the monomer that affords the structural unit (V) include, but are not limited to, those shown below. All of the second organic acid anions shown below have an iodo group or a hydroxy group, but the structural unit (V) does not necessarily have an iodo group or a hydroxy group. As the second organic acid anion having no iodo group or hydroxy group, a structure in which an iodo group or a hydroxy group in the following formula is substituted with a hydrogen atom, another substituent, or the like can be suitably employed. In the following formulas, R^{A} is the same as described above. The second organic acid anion preferably has a carboxylic acid anion and a hydroxy group. In this case, the carboxylic acid anion and the hydroxy group are preferably bonded to the same aromatic ring in the second organic acid anion, and in the same aromatic ring, a carbon atom to which the carboxylic acid anion is bonded and a carbon atom to which the hydroxy group is bonded are more preferably directly bonded to each other.

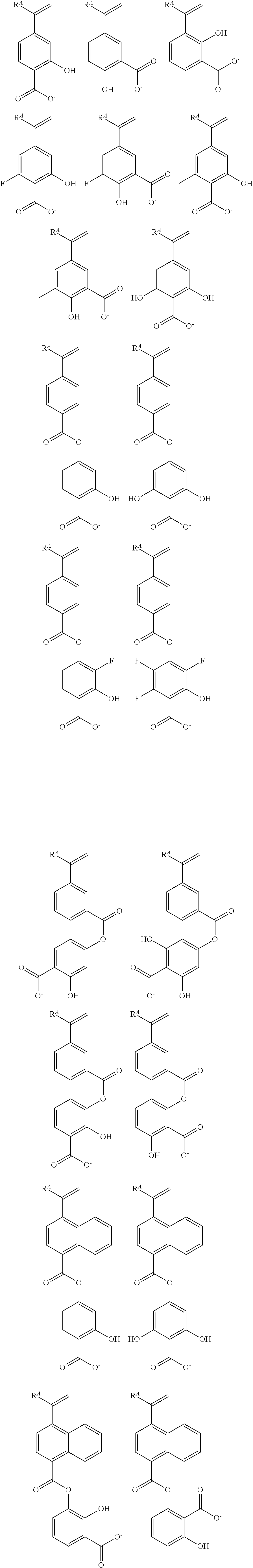

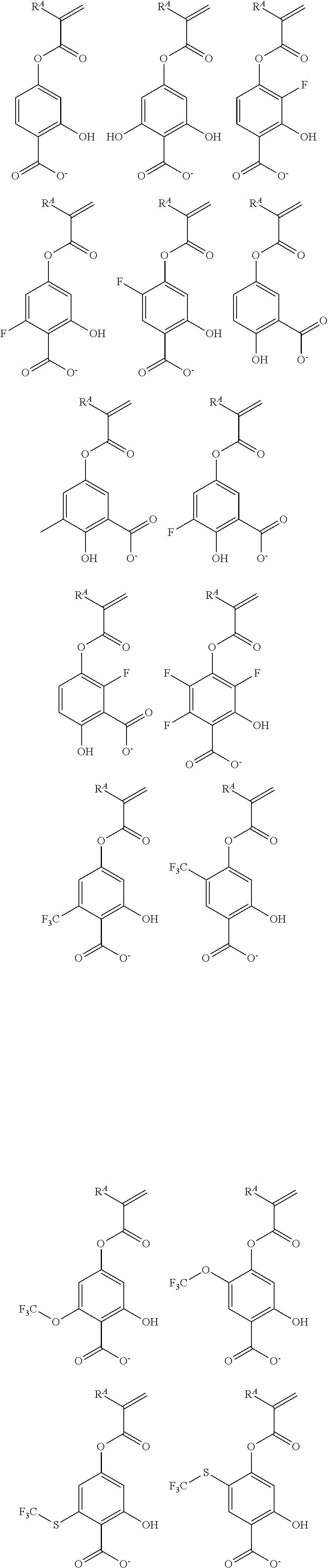

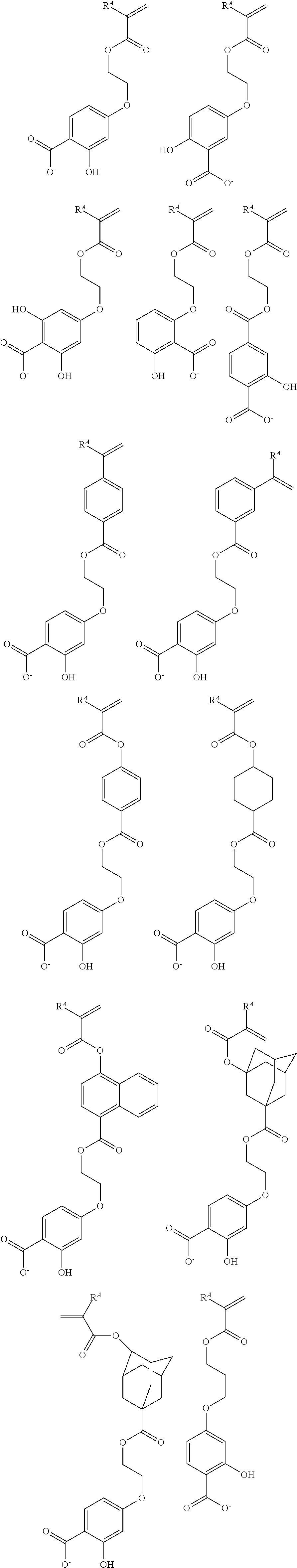

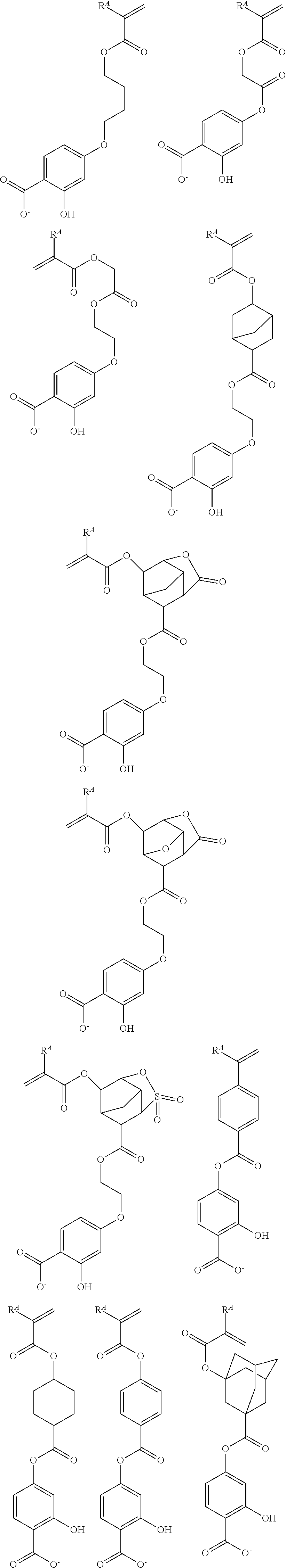

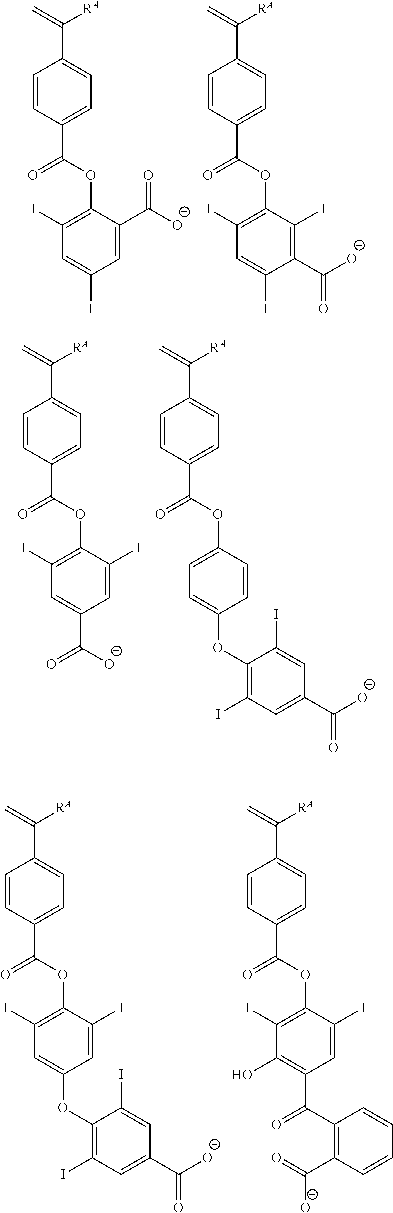

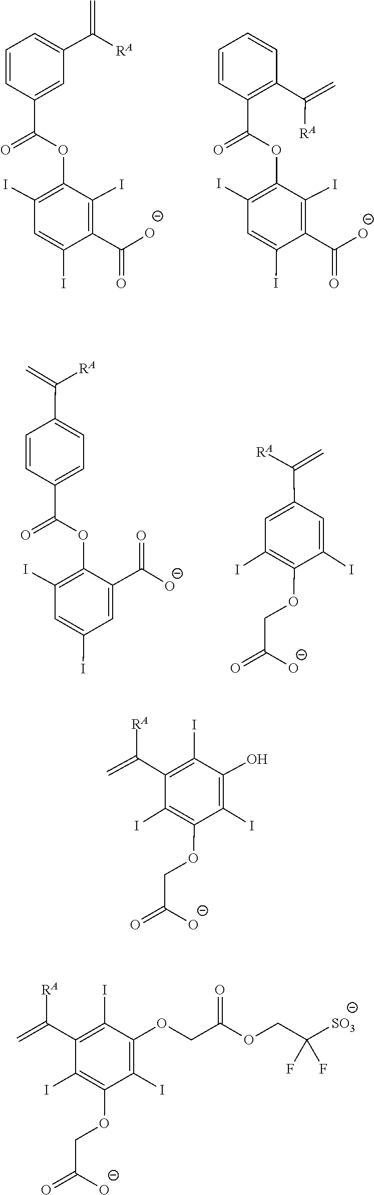

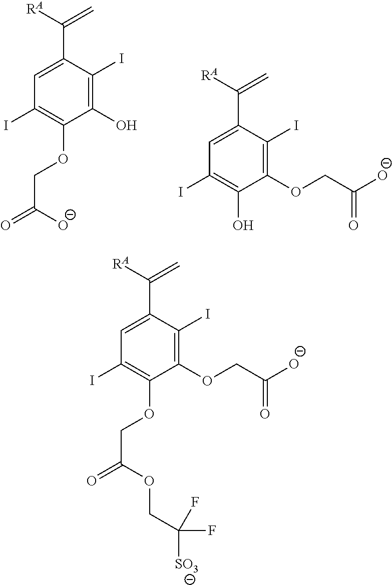

As the second onium cation of the structural unit (V), a sulfonium cation represented by the formula (Q-1) can be suitably employed.

As a side chain structure of the base polymer, an aspect can also be suitably employed in which the second onium cation is bonded to the main chain, and the second organic acid anion is ionically bonded to the second onium cation as a counter ion of the second onium cation. In this case, it is preferable that the second onium cation be bonded to the main chain via a divalent linking group or a single bond, and a structure from X¹ to COO— in the formula (p1) be ionically bonded to the second onium cation as a counter ion. As the divalent linking group, a divalent linking group represented by L¹ of the formula (1) can be suitably employed.

When the base polymer contains the structural unit (V), the lower limit of the content of the structural unit (V) (the total content when a plurality of structural units (V) are contained) is preferably 1 mol %, more preferably 2 mol %, still more preferably 3 mol % based on all structural units composing the base polymer. The upper limit of the content is preferably 15 mol %, more preferably 10 mol %, still more preferably 8 mol %. When the content of the structural unit (V) is adjusted to within the above range, the function as an acid diffusion controlling structure can be sufficiently exhibited.

### (Method for Synthesizing Base Polymer)

The base polymer can be synthesized by, for example, polymerizing monomers that will afford respective structural units in an appropriate solvent using a radical polymerization initiator or the like.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), and dimethyl 2,2′-azobisisobutyrate; and peroxide radical initiators, such as benzoyl peroxide, t-butyl hydroperoxide, and cumene hydroperoxide. Among them, AIBN and dimethyl 2,2′-azobisisobutyrate are preferable, and AIBN is more preferable. These radical initiators can be used singly or in mixture of two or more thereof.

As the solvents used in the polymerization, solvents described later can be suitably employed. The solvents to be used in the polymerization may be used singly, or two or more thereof may be used in combination.

The reaction temperature in the polymerization is usually 40° C. to 150° C., preferably 50° C. to 120° C. The reaction time is usually 1 hour to 48 hours, preferably 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 2,000, more preferably 3,000, still more preferably 4,000. The upper limit of the Mw is preferably 20,000, more preferably 16,000, still more preferably 14,000. When the Mw of the base polymer is adjusted to within the above range, the resulting resist film can exhibit good heat resistance and developability.

The ratio (Mw/Mn) of the Mw to the number average molecular weight (Mn) of the base polymer as determined by GPC relative to standard polystyrene is usually 1 or more and 5 or less, preferably 1 or more and 3 or less, more preferably 1 or more and 2 or less.

The method for measuring Mw and Mn of a polymer in the specification is as described in Examples.

The lower limit of the content of the base polymer is preferably 30% by mass, more preferably 40% by mass, still more preferably 50% by mass based on the total solid content of the radiation-sensitive composition. The upper limit of the content is preferably 80% by mass, more preferably 70% by mass.

### <Second Polymer>

The radiation-sensitive composition of the present embodiment contains a second polymer. Since the second polymer contains a structural unit (i) represented by the following formula (f1), the second polymer is said to be a polymer having a higher mass content of fluorine atoms than that of the base polymer. When the radiation-sensitive composition contains the second polymer, the radiation-sensitive composition can be localized on the surface layer of a resist film relative to the base polymer, and as a result, the surface modification of a resist film at the time of EUV exposure, and the control of distribution of a composition in the film can be achieved.

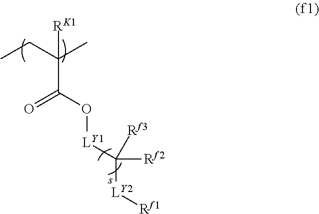

(In the formula (f1),

R^{K1} is a hydrogen atom, a fluorine atom, an alkyl group having 1 to 6 carbon atoms, a halogenated alkyl group having 1 to 6 carbon atoms, or a group represented by —R^{K2}—X—R^{K3} (wherein R^{K2} is a single bond, an alkanediyl group having 1 to 6 carbon atoms, or a halogenated alkanediyl group having 1 to 6 carbon atoms, X is a divalent linking group having a hetero atom, and R^{K3} is an alkyl group having 1 to 6 carbon atoms or a halogenated alkyl group having 1 to 6 carbon atoms). L^{Y1} is a divalent hydrocarbon group having 1 to 10 carbon atoms.

L^{Y2} is —COO—* or —OCO—*. * is a bond on the R^{f1} side. R^{f1} is a monovalent hydrocarbon group having 1 to 10 carbon atoms or a monovalent fluorinated hydrocarbon group having 1 to 10 carbon atoms.

R^{f2} and R^{f3} each independently represent a fluorine atom or a monovalent fluorinated hydrocarbon group having 1 to 10 carbon atoms, When there are a plurality of R^{f2} and R^{f3}, the plurality of R^{f2} and R^{f3} are the same as or different from each other.

s is an integer of 0 to 3. However, when R^{f1} is the monovalent hydrocarbon group having 1 to 10 carbon atoms, s is an integer of 1 to 3.)

As the alkyl group having 1 to 6 carbon atoms represented by R^{K1} and R^{K3}, among monovalent linear or branched saturated hydrocarbon groups having 1 to 10 carbon atoms in R^{1A} and R^{1B} of the formula (1), groups corresponding to those having 1 to 6 carbon atoms can be suitably employed.

Examples of the halogenated alkyl group having 1 to 6 carbon atoms represented by R^{K1} and R^{K3} include groups in which some or all of hydrogen atoms of the alkyl group having 1 to 6 carbon atoms are substituted with a halogen atom. The halogen atom is preferably a fluorine atom. Examples of the halogenated alkyl group having 1 to 6 carbon atoms include a trifluoromethyl group, a 2,2,2-trifluoroethyl group, a pentafluoroethyl group, a 2,2,3,3,3-pentafluoropropyl group, a 1,1,1,3,3,3-hexafluoropropyl group, a heptafluoro-n-propyl group, a heptafluoroisopropyl group, a nonafluoro-n-butyl group, a nonafluoroisobutyl group, a nonafluoro-t-butyl group, a 2,2,3,3,4,4,5,5-octafluoro-n-pentyl group, and a tridecafluoro-n-hexyl group.

Examples of the alkanediyl group having 1 to 6 carbon atoms represented by R^{K2} include groups obtained by removing one hydrogen atom from the alkyl group having 1 to 6 carbon atoms represented by R^{K1} and R^{K3}.

Examples of the halogenated alkanediyl group having 1 to 6 carbon atoms represented by R^{K2} include groups obtained by removing one hydrogen atom from the halogenated alkyl group having 1 to 6 carbon atoms represented by R^{K1} and R^{K3}.

Examples of the divalent hydrocarbon group having 1 to 10 carbon atoms represented by L^{Y1} include groups obtained by removing one hydrogen atom from, among monovalent hydrocarbon groups having 1 to 20 carbon atoms represented by R³ of the formula (3-1), groups corresponding to those having 1 to 10 carbon atoms. Among them, the divalent hydrocarbon group having 1 to 10 carbon atoms represented by L^{Y1} is preferably a methylene group, an ethanediyl group, or a propanediyl group.

L^{Y2} is preferably —COO—*.

Examples of the monovalent hydrocarbon group having 1 to 10 carbon atoms represented by R^{f1} include groups corresponding to 1 to 10 carbon atoms among monovalent hydrocarbon groups having 1 to 20 carbon atoms represented by R³ of the formula (3-1). Among them, the monovalent hydrocarbon group having 1 to 10 carbon atoms represented by R^{f1} is preferably a methyl group, an ethyl group, or a propyl group.

Examples of the monovalent fluorinated hydrocarbon group having 1 to 10 carbon atoms represented by R^{f1}, R^{f2}, and R^{f3} include a monovalent fluorinated chain hydrocarbon group having 1 to 10 carbon atoms and a monovalent fluorinated alicyclic hydrocarbon group having 3 to 10 carbon atoms.

Examples of the monovalent fluorinated chain hydrocarbon group having 1 to 10 carbon atoms include:
fluorinated alkyl groups in which the halogenated alkyl group having 1 to 6 carbon atoms represented by R^{K1} and R^{K3} is extended to those having 10 carbon atoms, and a halogen atom is a fluorine atom;
fluorinated alkenyl groups such as a trifluoroethenyl group and a pentafluoropropenyl group; and
fluorinated alkynyl groups such as a fluoroethynyl group and a trifluoropropynyl group.

Examples of the monovalent fluorinated alicyclic hydrocarbon group having 3 to 20 carbon atoms include: fluorinated cycloalkyl groups such as a
fluorocyclopentyl group, a difluorocyclopentyl group, a nonafluorocyclopentyl group, a fluorocyclohexyl group, a difluorocyclohexyl group, an undecafluorocyclohexylmethyl group, a fluoronorbornyl group, a fluoroadamantyl group, a fluorobornyl group, a fluoroisobornyl group, a fluorotricyclodecyl group, and a fluorotetracyclodecyl group; and
fluorinated cycloalkenyl groups such as a fluorocyclopentenyl group and a nonafluorocyclohexenyl group.

As the monovalent fluorinated hydrocarbon group having 1 to 10 carbon atoms represented by R^{f1}, R^{f2}, and R^{f3}, a monovalent fluorinated chain hydrocarbon group having 1 to 10 carbon atoms is preferable, a monovalent fluorinated chain hydrocarbon group having 1 to 6 carbon atoms is more preferable, and a monovalent fluorinated chain saturated hydrocarbon group having 1 to 4 carbon atoms is still more preferable.

s is preferably an integer of 0 to 2, more preferably 0 or 1.

In the formula (f1), R^{f1} is a monovalent fluorinated hydrocarbon group having 1 to 10 carbon atoms, and s is preferably 0.

The monomers that afford the structural unit (i) are each preferably represented by the following formulas (f1-1) to (f1-12).

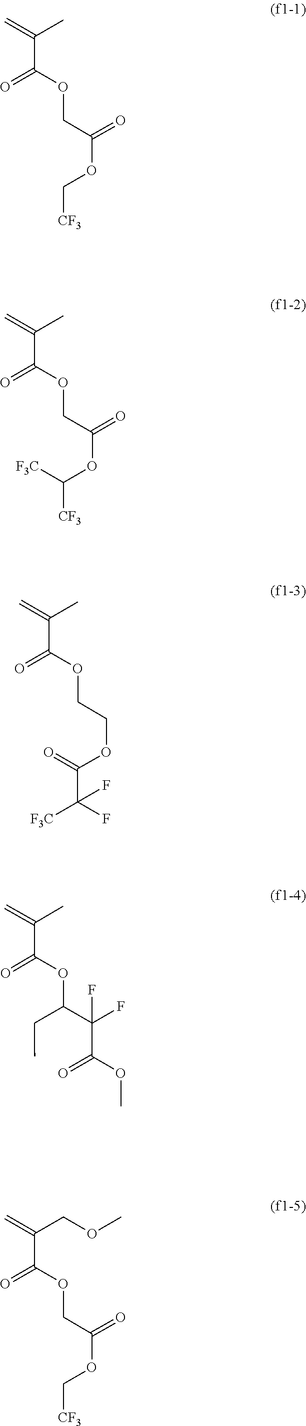

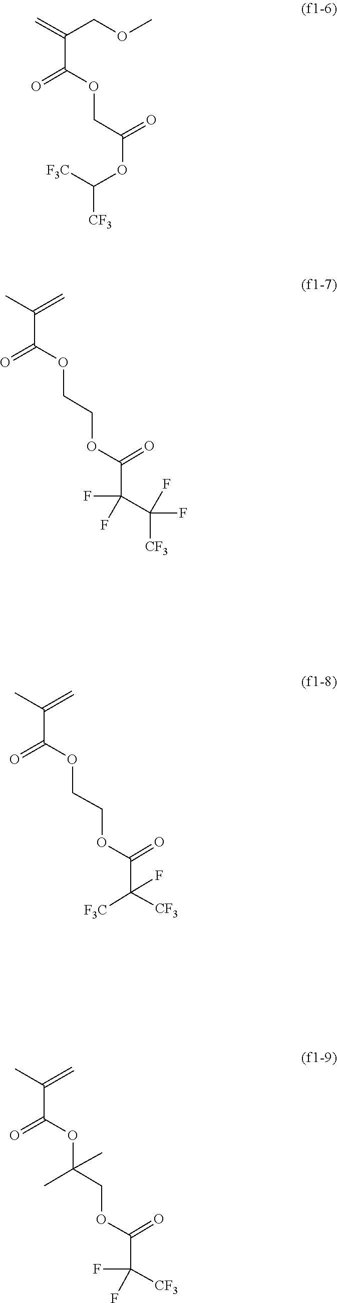

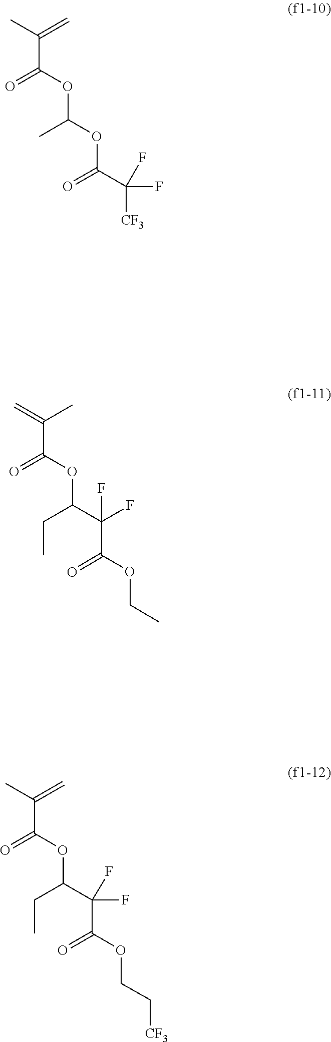

The lower limit of the content of the structural unit (i) (the total content when a plurality of structural units (i) are contained) is preferably 30 mol %, more preferably 40 mol %, still more preferably 45 mol % based on the all structural units composing the second polymer. The upper limit of the content is preferably 100 mol %, more preferably 90 mol %, still more preferably 80 mol %. When the content of the structural unit (V) is adjusted to within the above range, the solubility of the surface layer of a resist film due to the second polymer can be improved.

### (Other Structural Units)

The second polymer may contain the structural unit (II) in the base polymer as a structural unit in addition to the structural unit (i) Furthermore, the second polymer may contain the following structural units (ii) and (iii), and a structural unit derived from (meth)acrylic acid.

(Structural Unit (ii))

The structural unit (ii) is a structural unit containing at least one structure selected from the group consisting of a lactone structure, a cyclic carbonate structure, and a sultone structure. Since the second polymer further has the structural unit (ii), the solubility into a developer can be adjusted.

When the second polymer contains the structural unit (ii), the lower limit of the content of the structural unit (ii) is preferably 5 mol %, more preferably 10 mol %, still more preferably 15 mol % based on all structural units composing the second polymer. The upper limit of the content is preferably 40 mol %, more preferably 30 mol %, still more preferably 25 mol %. When the content of the structural unit (ii) is adjusted to within the above range, the solubility of the second polymer into a developer can be efficiently adjusted.

(Structural Unit (iii)) Examples of the structural unit (iii) include a structural unit containing a polar group (excluding those corresponding to the structural units (III) to (V) and the structural unit (ii)). Since the second polymer further has the structural unit (iii), the solubility into a developer can be adjusted. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (iii) include structural units represented by the following formulas.

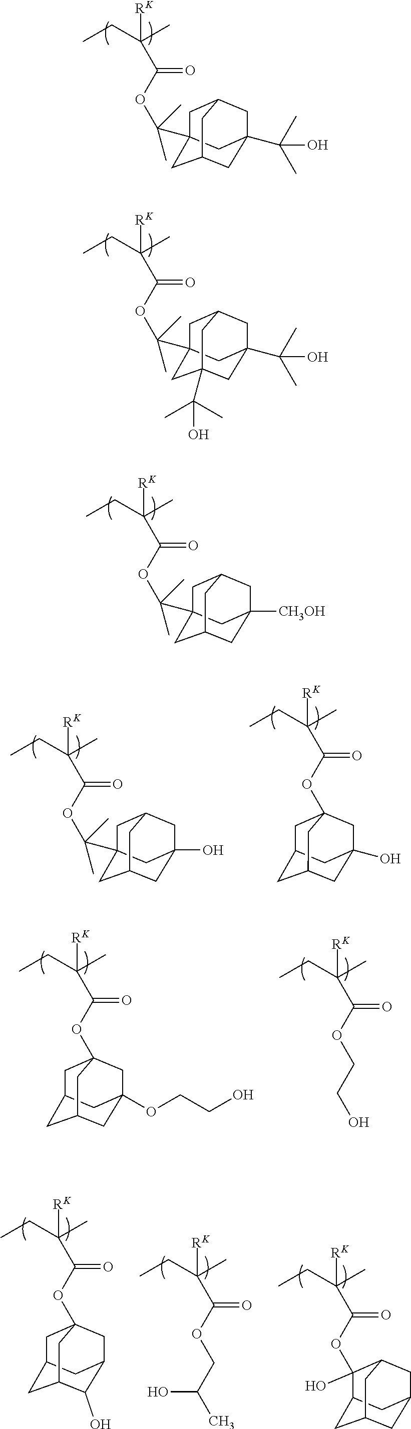

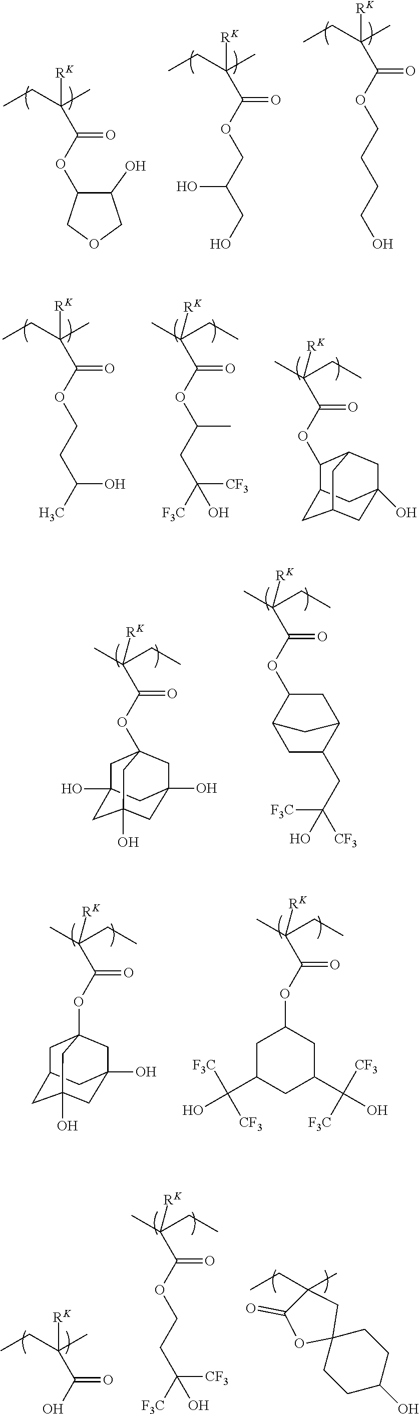

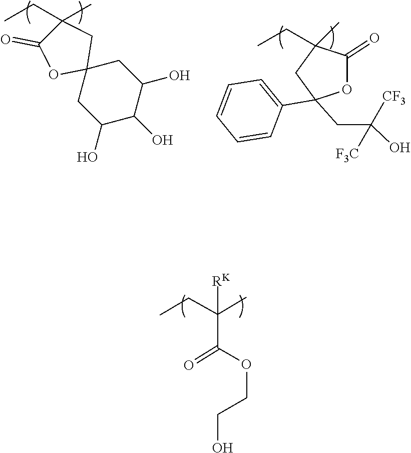

In the formulas, R^{K} is a hydrogen atom, a fluorine atom, a methyl group, or a trifluoromethyl group.

When the second polymer has the structural unit (iii) having a polar group, the lower limit of the content of the structural unit (iii) is preferably 5 mol %, more preferably 10 mol %, still more preferably 15 mol % based on all structural units composing the second polymer. The upper limit of the content is preferably 40 mol %, more preferably 30 mol %, still more preferably 25 mol %. When the content of the structural unit (ii) is adjusted to within the above range, the solubility of the second polymer into a developer can be efficiently adjusted.

When the second polymer has the structural unit derived from (meth)acrylic acid, the lower limit of the content of the structural unit is preferably 5 mol %, more preferably 10 mol %, still more preferably 15 mol % based on all structural units composing the second polymer. The upper limit of the content is preferably 50 mol %, more preferably 40 mol %, still more preferably 30 mol %.

The lower limit of the Mw of the second polymer is preferably 8,000, more preferably 12,000, still more preferably 16,000. The upper limit of the Mw is preferably 35,000, more preferably 30,000, still more preferably 25,000.

The lower limit of the Mw/Mn of the second polymer is usually 1, more preferably 1.1. The upper limit of the Mw/Mn is usually 5, preferably 3, more preferably 2.

The lower limit of the content of the second polymer is preferably 0.1 parts by mass, more preferably 1 part by mass, still more preferably 2 parts by mass, particularly preferably 3 parts by mass based on 100 parts by mass of the base polymer. The upper limit of the content is preferably 20 parts by mass, more preferably 15 parts by mass, still more preferably 10 parts by mass, particularly preferably 6 parts by mass.

When the content of the second polymer is adjusted to within the above range, the second polymer can be more effectively localized on the surface layer of a resist film, and as a result, the solubility of the surface layer of the resist film at the time of development can be improved, as well as the surface modification of the resist film at the time of EUV exposure and the control of distribution of a composition in the film can be achieved. The radiation-sensitive composition may contain one second polymer, or two or more second polymers.

### (Method for Synthesizing Second Polymer)

The second polymer can be synthesized by the same method as the method described above for synthesizing the base polymer.

### <Radiation-Sensitive Acid Generator>

The radiation-sensitive composition may contain a radiation-sensitive acid generator. The radiation-sensitive acid generator contains a third organic acid anion and a third onium cation, and forms the onium salt structure. The radiation-sensitive acid generator is a component that generates an acid through exposure to light. The acid generated through exposure to light has a function of dissociating the acid-dissociable group of the base polymer to generate a carboxy group or the like. The radiation-sensitive acid generator has a form (liberated from a polymer) in which the onium salt structure exists alone as a low molecular compound, and is different from a radiation-sensitive acid generating structure in which the first organic acid anion or the first onium cation is bonded (covalently bonded) to a main chain as a side chain structure of a base polymer as in the structural unit (IV) in the base polymer.

At least one selected from the group consisting of the third organic acid anion and the third onium cation preferably has an iodo group, more preferably has the iodo group-containing aromatic ring structure.

As the structure of the third organic acid anion of the radiation-sensitive acid generator, in addition to a structure from V² to SO₃ in the above formula (a1) or (a2) of the base polymer, a conventionally known structure can be suitably employed.

Examples of the third organic acid anion of the radiation-sensitive acid generator include, but are not limited to, those shown below. Instead of the first organic acid anion having the iodo group-containing aromatic ring structure, as the third organic acid anion having no iodo group-containing aromatic ring structure, a structure in which an iodo group in the following formula is substituted with a hydrogen atom, another substituent, or the like can be suitably employed.

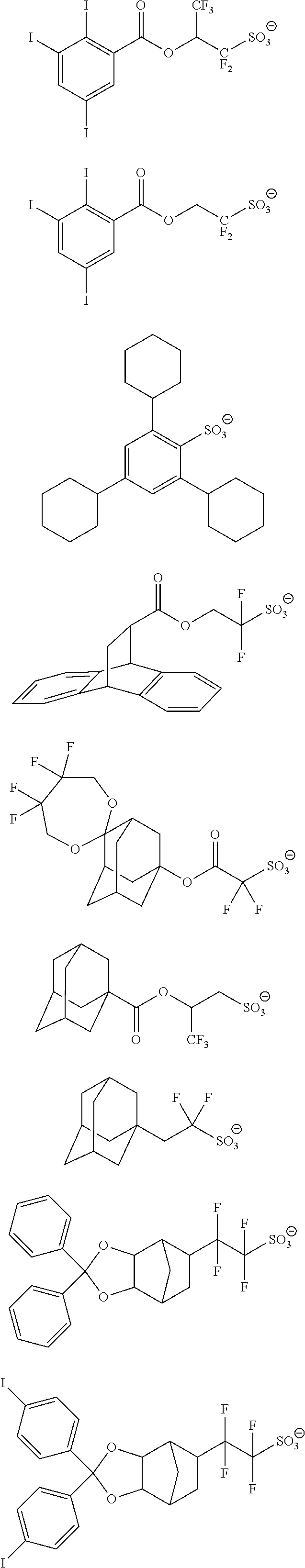

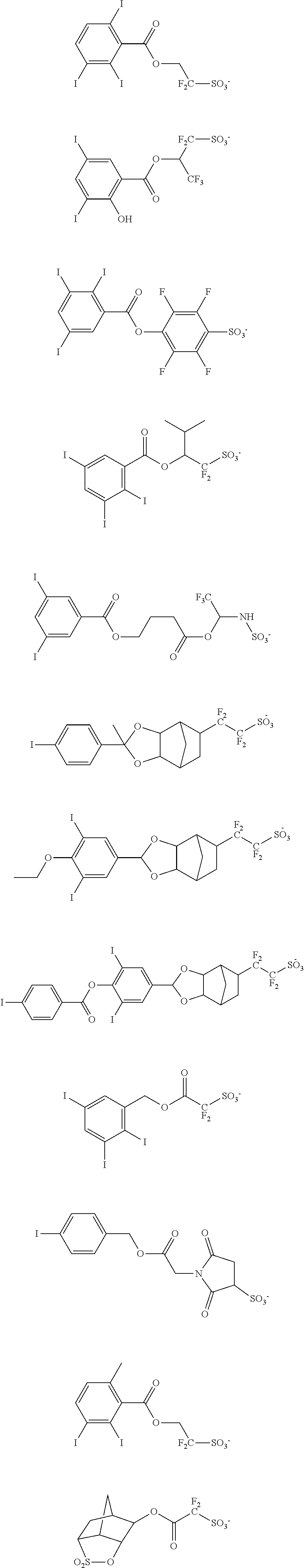

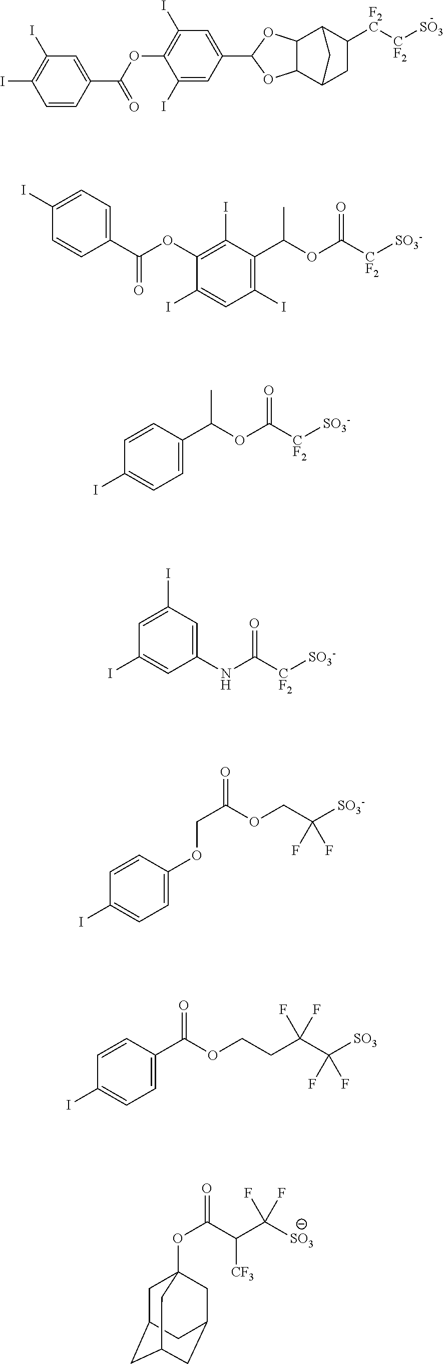

As the structure of the third onium cation of the radiation-sensitive acid generator, a structure of the first onium cation of the structural unit (IV) in the base polymer can be suitably employed.

The radiation-sensitive acid generator can also be synthesized by a known method, particularly by a salt exchange reaction. A known radiation-sensitive acid generator may also be used as long as the effect of the present invention is not impaired.

These radiation-sensitive acid generators may be used singly, or two or more thereof may be used in combination. When the radiation-sensitive composition contains the radiation-sensitive acid generator, the lower limit of the content of the radiation-sensitive acid generator (total content in the case of a plurality of radiation-sensitive acid generators) is preferably 5 parts by mass, more preferably 10 parts by mass, still more preferably 15 parts by mass based on 100 parts by mass of the base polymer. The upper limit of the content is preferably 100 parts by mass, more preferably 90 parts by mass, even more preferably 80 parts by mass. This makes it possible to exhibit superior sensitivity when forming a resist pattern.

### <Acid Diffusion Controlling Agent>

The radiation-sensitive composition may contain an acid diffusion controlling agent. The acid diffusion controlling agent contains a fourth organic acid anion and a fourth onium cation, and generates an acid having a higher pKa than that of an acid generated from the radiation-sensitive acid generator through irradiation with radiation. The acid diffusion controlling agent has a function of suppressing, by salt exchange, the diffusion of an acid generated from the radiation-sensitive acid generator in the unexposed portion without substantially dissociating the acid-dissociable group of the base polymer under a pattern forming condition using the radiation-sensitive composition.

When the radiation-sensitive composition contains the acid diffusion controlling agent, the diffusion of an acid in the unexposed portion can be suppressed, and a resist pattern excellent in LWR performance and development contrast can be formed.

At least one selected from the group consisting of the fourth organic acid anion and the fourth onium cation preferably has an iodo group, more preferably has the iodo group-containing aromatic ring structure.

Although the structure of the fourth organic acid anion is not specified, it is preferable to include —O—, —CO—, a cyclic structure, or a combination thereof. As the cyclic structure, a cyclic structure in the first organic acid anion of the structural unit (IV) of the base polymer can be suitably employed.

In the acid diffusion controlling agent, the fourth organic anion preferably has a sulfonate anion or a carboxylate anion as the acid anion moiety (provided that when the fourth organic acid anion has the sulfonate anion, neither a fluorine atom nor a fluorinated hydrocarbon group is bonded to a carbon atom adjacent to a sulfur atom of the sulfonate anion). As a result, the acid diffusion controlling agent can efficiently exhibit the above function.

Examples of the acid diffusion controlling agent include a sulfonium salt compound represented by the following formula (8-1) and an iodonium salt compound represented by the following formula (8-2). In addition, examples thereof include a compound containing a sulfonium cation and an anion in the same molecule represented by the following formula (8-3) and a compound containing an iodonium cation and an anion in the same molecule represented by the following formula (8-4).

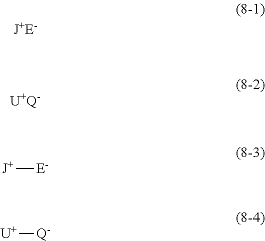

In the above formulas (8-1) to (8-4), J⁺ is a sulfonium cation, and U⁺ is an iodonium cation. E⁻ and Q⁻ are each independently the fourth organic acid anion represented by OH⁻, R^{α}—COO⁻, or R^{α}—SO₃⁻. In the formulas (8-1) to (8-2), R^{α} is a monovalent organic group having 1 to 30 carbon atoms. In the formulas (8-3) to (8-4), R^{α} is a single bond or a divalent organic group having 1 to 30 carbon atoms. Examples of the organic group include a monovalent hydrocarbon group having 1 to 20 carbon atoms, a group having a divalent hetero atom-containing group between carbon and carbon or at a carbon chain end of the hydrocarbon group, a group obtained by substituting some or all of hydrogen atoms of the hydrocarbon group with a monovalent hetero atom-containing group, or a combination thereof.

As the monovalent hydrocarbon group having 1 to 20 carbon atoms in the organic group, a monovalent hydrocarbon group having 1 to 20 carbon atoms represented by R⁸ of the formula (3-1) can be suitably employed. As the divalent heteroatom-containing group, a divalent heteroatom-containing group in the first organic acid anion of the structural unit (IV) of the base polymer can be suitably employed. Examples of the monovalent heteroatom-containing group include a hydroxy group, a carboxy group, a sulfanyl group, a cyano group, a nitro group, and halogen atoms.

Examples of the fourth organic acid anion of the acid diffusion controlling agent include, but are not limited to, those shown below. A compound containing an iodonium cation and an anion in the same molecule and a compound containing a sulfonium cation and an anion in the same molecule are also exemplified. As the organic acid anion having no iodo group-containing aromatic ring structure, a structure in which an iodo group in the following formula is substituted with an atom or a group other than the iodo group such as a hydrogen atom or another substituent can be suitably employed.

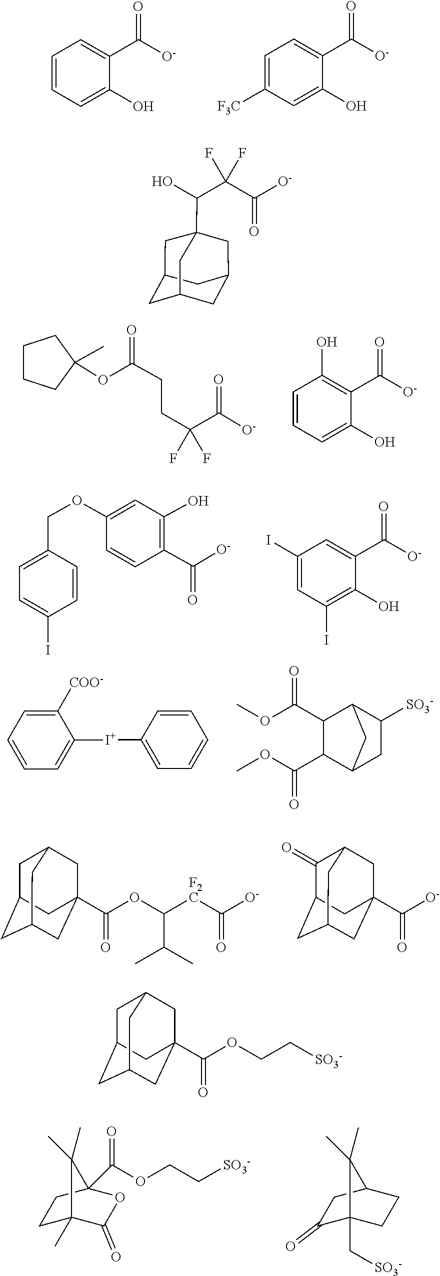

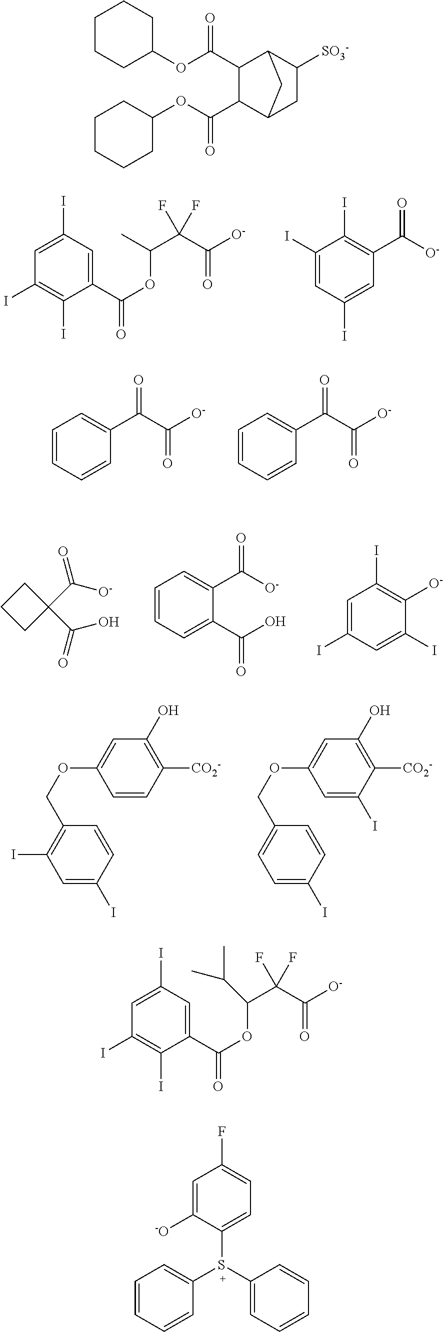

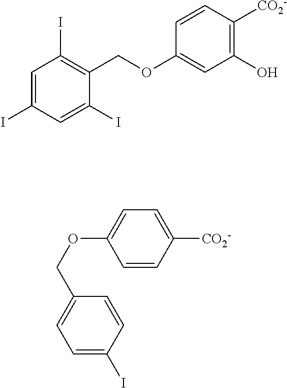

As the fourth onium cation in the acid diffusion controlling agent, a structure of the first onium cation of the structural unit (IV) in the base polymer can be suitably employed.

When the fourth onium cation is an iodonium cation, the cation is preferably a diaryliodonium cation. The diaryliodonium cation more preferably has one or more fluoro groups or iodo groups.

The acid diffusion controlling agent can also be synthesized by a known method, particularly by a salt exchange reaction.

These acid diffusion controlling agents may be used singly, or two or more thereof may be used in combination. When the radiation-sensitive composition contains an acid diffusion controlling agent, the lower limit of the content of the acid diffusion controlling agent (total content in the case of a plurality of acid diffusion controlling agents) is preferably 10 mol %, more preferably 15 mol %, still more preferably 20 mol % based on the total of the content of the structural unit (IV) of the base polymer and the content of the radiation-sensitive acid generator. The upper limit of the content is preferably 40 mol %, more preferably 35 mol %, still more preferably 30 mol %.

### <Solvent>

The radiation-sensitive composition according to the present embodiment contains a solvent. The solvent is not particularly limited as long as it is a solvent capable of dissolving or dispersing the base polymer, additives contained as desired, and the like.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include: monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents obtained by etherifying some of hydroxy groups of the polyhydric alcohol-based solvent.

In the present embodiment, alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate are also included in the alcohol-based solvent.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents obtained by etherifying a hydroxy group of the polyhydric alcohol-based solvent.

Examples of the ketone-based solvent include chain ketone-based solvents, such as acetone, butanone, and methyl-iso-butyl ketone;
cyclic ketone-based solvents, such as cyclopentanone, cyclohexanone, and methylcyclohexanone; and 2,4-pentanedione, acetonylacetone, and acetophenone.

Examples of the amide-based solvent include cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include:
monocarboxylic acid ester-based solvents, such as n-butyl acetate;
partially etherized polyhydric alcohol acetate-based solvents, such as diethylene glycol mono-n-butyl ether acetate, propylene glycol monomethyl ether acetate, and dipropylene glycol monomethyl ether acetate;
lactone-based solvents, such as γ-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxytriglycol acetate, diethyl oxalate, ethyl acetoacetate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, an ester-based solvent, an ether-based solvent, and an alcohol-based solvent are preferable, a partially etherized polyhydric alcohol acetate-based solvent, a partially etherized polyhydric alcohol-based solvent, a lactone-based solvent, a monoalcohol-based solvent, and an alcohol acid ester-based solvent are more preferable, and propylene glycol monomethyl ether acetate, propylene glycol monomethyl ether, γ-butyrolactone, diacetone alcohol, ethyl lactate, and methyl 2-hydroxyisobutyrate are still more preferable. The radiation-sensitive composition may contain one solvent, or two or more solvents.

### <Other Optional Components>

The radiation-sensitive composition may contain, in addition to the components, other optional components. Examples of other optional components may include a cross-linking agent, a localization enhancing agent, a surfactant, an alicyclic backbone-containing compound, and a sensitizer. These other optional components may be used singly, or two or more thereof may be used in combination.

### <Method for Preparing Radiation-Sensitive Composition>

The radiation-sensitive composition can be prepared, for example, by mixing the base polymer and the solvent, and if necessary, the optional component at a prescribed ratio. The radiation-sensitive composition is, after the mixing, preferably filtered through, for example, a filter having a pore size of approximately 0.05 μm to 0.4 μm. The solid matter concentration of the radiation-sensitive composition is usually 0.1% by mass to 50% by mass, preferably 0.5% by mass to 30% by mass, more preferably 1% by mass to 20% by mass.

### <Pattern Forming Method>

A pattern forming method according to the embodiment of the present invention includes:
a step (1) of applying the radiation-sensitive composition directly or indirectly on a substrate to form a resist film (hereinafter also referred to as “resist film forming step”);
a step (2) of exposing the resist film to light (hereinafter also referred to as “exposure step”); and
a step (3) of developing the exposed resist film with a developer (hereinafter also referred to as “development step”).

According to the pattern forming method, the radiation-sensitive composition capable of exerting LWR performance and an over exposure margin equal to or higher than those of the related art together with excellent sensitivity in pattern formation is used, so that a high-quality resist pattern can be formed. Hereinbelow, each of the steps will be described.

### [Resist Film Forming Step]

In this step (the step (1)), a resist film is formed from the radiation-sensitive composition. Examples of the substrate on which the resist film is formed may include those traditionally known in the art, including a silicon wafer, silicon dioxide, and a wafer coated with aluminum. An organic or inorganic antireflective film disclosed in, for example, JP-B-6-12452 or JP-A-59-93448 may be formed on the substrate. Examples of an applicating method may include a rotary coating (spin coating), flow casting, and roll coating. After the application, prebaking (PB) may be performed to volatilize the solvent in the coating film, as necessary. The temperature of PB is usually from 60° C. to 160° C., preferably from 80° C. to 140° C. The duration of PB is usually from 5 seconds to 600 seconds, preferably from 10 seconds to 300 seconds. The thickness of the resist film formed is preferably from 10 nm to 1,000 nm, more preferably from 10 nm to 500 nm.

### [Exposure Step]

In this step (the step (2)), the resist film formed in the resist film forming step as the step (1) is exposed by irradiating with radiation through a photomask. Examples of the radiation to be used for the exposure may include an electromagnetic wave including visible ray, ultraviolet ray, far ultraviolet ray, extreme ultraviolet ray (EUV), X ray, and γ ray; and charged particle radiation such as an electron beam and α ray. Among them, far ultraviolet ray, an electron beam, or EUV is preferable. ArF excimer laser light (wavelength is 193 nm), KrF excimer laser light (wavelength is 248 nm), an electron beam, or EUV is more preferable. An electron beam having a wavelength of 50 nm or less, which is identified as the next generation exposing technology, or EUV is further preferable.

After the exposure, post exposure bake (PEB) is preferably performed to promote the dissociation of the acid-dissociable group of the polymer by an acid generated from the radiation-sensitive acid generator or the structural unit (IV) through exposure to light in the exposed part of the resist film. As a result of the PEB, there is generated a difference in solubility into a developer between the exposed area and the unexposed area. The temperature of PEB is usually from 50° C. to 180° C., preferably from 80° C. to 150° C. The duration of PEB is usually from 5 seconds to 600 seconds, preferably from 10 seconds to 300 seconds.

### [Development Step]

In this step (the step (3)), the resist film exposed in the exposure step as the step (2) is developed with a developer. By this step, the predetermined resist pattern can be formed. After the development, the resist pattern is generally washed with a rinse solution such as water or alcohol, and then dried.

Examples of the developer used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferable, and a 2.38% by mass aqueous TMAH solution is more preferable.

In the case of organic solvent development, examples of the solvent may include organic solvents such as hydrocarbon-based solvents, ether-based solvents, ester-based solvents, ketone-based solvents, and alcohol-based solvents, and solvents containing an organic solvent. Examples of the organic solvent may include one, two or more solvents listed as the solvent for the radiation-sensitive composition. Among them, ester-based solvents and ketone-based solvents are preferable. As the ester-based solvents, acetate-based solvents are preferable, and n-butyl acetate and amyl acetate are more preferable. As the ketone-based solvents, chain ketones are preferable, and 2-heptanone is more preferable. The content of the organic solvent in a developer is preferably 80% by mass or more, more preferably 90% by mass or more, still more preferably 95% by mass or more, particularly preferably 99% by mass or more. Examples of the component other than the organic solvent in the developer may include water and silicone oil.

Examples of the developing method may include a method including dipping a substrate in a tank filled with a developer for a given time (dipping method); a developing method including raising a developer on the surface of a substrate due to surface tension and leaving the raised developer for a given time (paddling method); a method including spraying a developer on the surface of a substrate (spraying method); and a method including injecting a developer on a substrate rolling at a constant rate while scanning a developer injection nozzle at a constant rate (dynamic dispensing method).

### EXAMPLES

Hereinafter, the present invention will be specifically described with reference to Examples, but the present invention is not limited to these Examples. Physical property values in the Examples were measured as follows.

### [Synthesis Examples] Synthesis of Base Polymer

Monomers represented by the following formulas were combined in the composition shown in the following Table 1, and then subjected to a copolymerization reaction in a tetrahydrofuran (THF) solvent, followed by crystallization in methanol. Furthermore, washing was repeated with hexane, and then isolation and drying were performed to yield A-1 to A-40 as base polymers having the composition shown below. In Table 1, “-” indicates that the corresponding component was not used. The same applies to the following tables.

The Mw and the dispersion degree (Mw/Mn) of polymers were measured by gel permeation chromatography (GPC) using GPC columns manufactured by Tosoh Corporation (“G2000HXL”×2, “G3000HXL”×1, “G4000HXL”×1) under the following conditions.

### (Measurement Conditions)

Eluant: tetrahydrofuran (manufactured by Wako Pure Chemical Industries, Ltd.)
Flow rate: 1.0 mL/min
Sample concentration: 1.0% by mass
Sample injection amount: 100 μL
Column temperature: 40° C.
Detector: differential refractometer
Reference material: monodisperse polystyrene

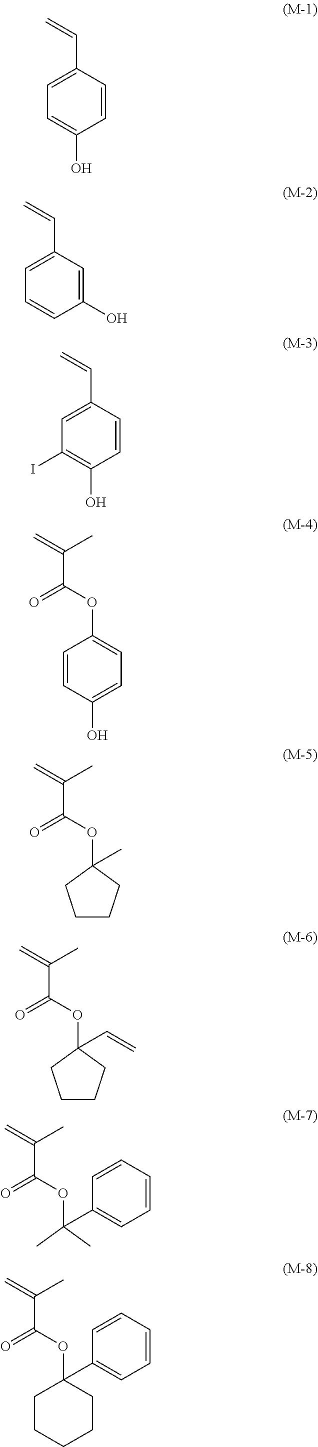

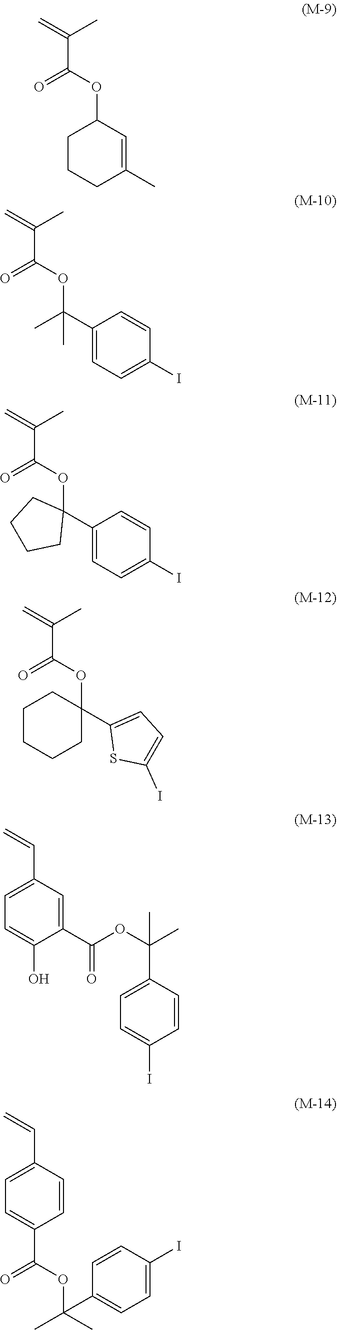

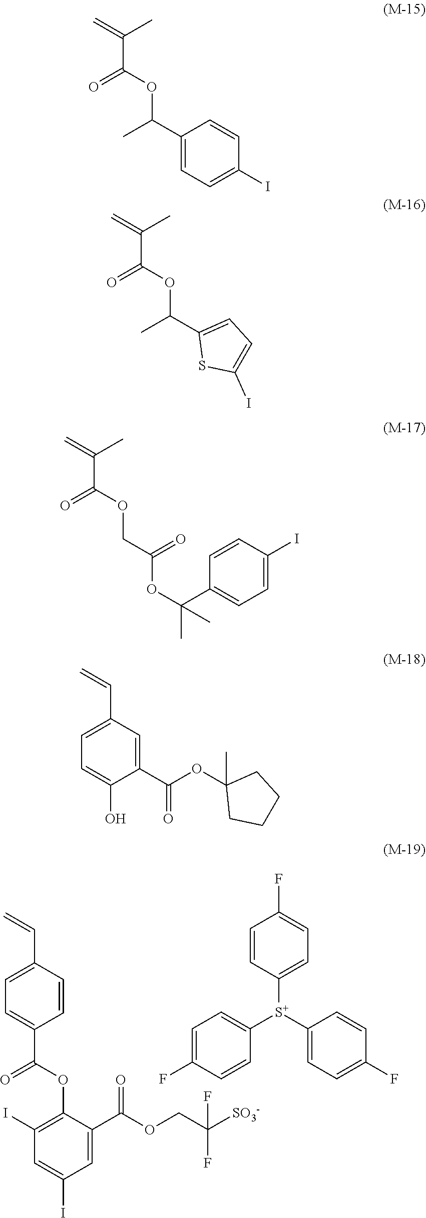

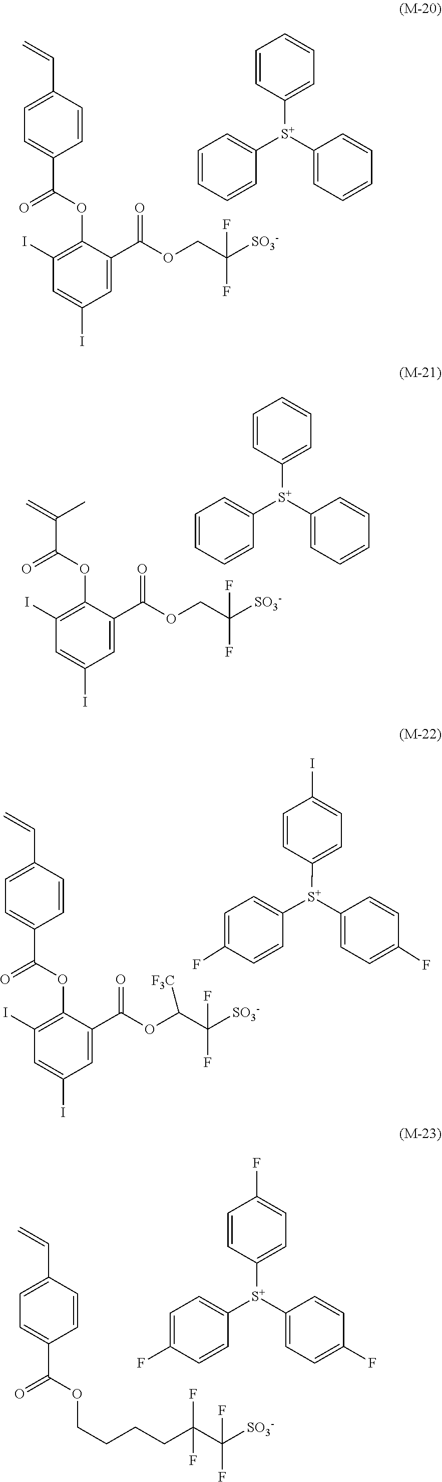

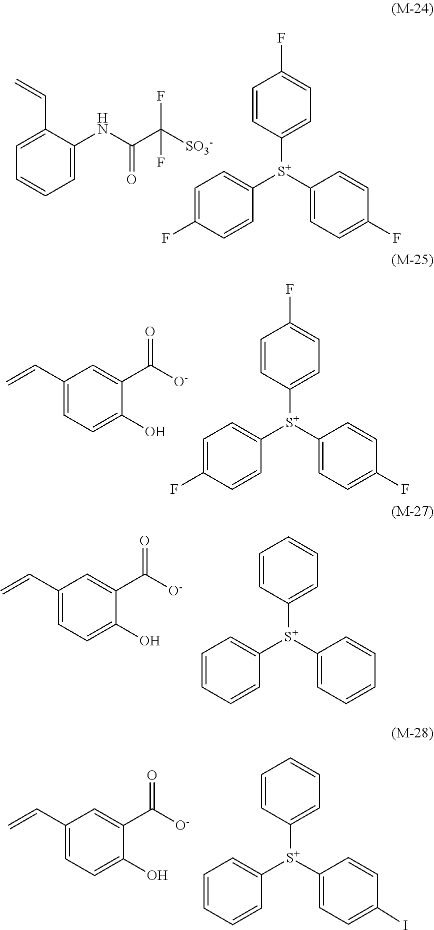

TABLE 1

| | Monomer that affords | | Monomer that affords | | Monomer that affords | | Monomer that affords | | Monomer that affords | | | |
|---|---|---|---|---|---|---|---|---|---|---|---|---|
| | structural unit (III) | | structural unit (I) | | structural unit (II) | | structural unit (IV) | | structural unit (V) | | | |
| | | Used | | Used | | Used | | Used | | Used | | |
| First | | amount | | amount | | amount | | amount | | amount | | |
| polymer | Type | (mol %) | Type | (mol %) | Type | (mol %) | Type | (mol %) | Type | (mol %) | Mw | Mw/Mn |
| A-1 | M-1 | 50 | — | — | M-5 | 50 | — | — | — | — | 6500 | 1.4 |
| A-2 | M-1 | 50 | — | — | M-6 | 50 | — | — | — | — | 6600 | 1.4 |
| A-3 | M-1 | 50 | — | — | M-7 | 50 | — | — | — | — | 6300 | 1.3 |
| A-4 | M-1 | 50 | — | — | M-8 | 50 | — | — | — | — | 6400 | 1.5 |
| A-5 | M-1 | 50 | — | — | M-9 | 50 | — | — | — | — | 6400 | 1.4 |
| A-6 | M-1 | 50 | M-10 | 50 | — | — | — | — | — | — | 6500 | 1.4 |
| A-7 | M-1 | 50 | M-11 | 50 | — | — | — | — | — | — | 6500 | 1.4 |
| A-8 | M-1 | 50 | M-12 | 50 | — | — | — | — | — | — | 6600 | 1.5 |
| A-9 | M-1 | 50 | M-13 | 50 | — | — | — | — | — | — | 6200 | 1.4 |
| A-10 | M-1 | 50 | M-14 | 50 | — | — | — | — | — | — | 6300 | 1.3 |
| A-11 | M-1 | 50 | M-15 | 50 | — | — | — | — | — | — | 6600 | 1.4 |
| A-12 | M-1 | 50 | M-16 | 50 | — | — | — | — | — | — | 6500 | 1.3 |
| A-13 | M-1 | 50 | M-17 | 50 | — | — | — | — | — | — | 6500 | 1.4 |
| A-14 | M-1/M-18 | 50/50 | — | — | — | — | — | — | — | — | 6800 | 1.4 |
| A-15 | M-2 | 50 | — | — | M-5 | 50 | — | — | — | — | 6500 | 1.3 |
| A-16 | M-2 | 50 | — | — | M-9 | 50 | — | — | — | — | 6300 | 1.5 |
| A-17 | M-2 | 50 | M-10 | 50 | — | — | — | — | — | — | 6700 | 1.3 |
| A-18 | M-3 | 50 | M-10 | 50 | — | — | — | — | — | — | 6400 | 1.3 |
| A-19 | M-4 | 50 | M-10 | 50 | — | — | — | — | — | — | 6400 | 1.4 |
| A-20 | M-1/M-2 | 25/25 | — | — | M-5 | 50 | — | — | — | — | 6500 | 1.4 |
| A-21 | M-1/M-2 | 25/25 | M-10 | 50 | — | — | — | — | — | — | 6400 | 1.4 |
| A-22 | M-1 | 30 | M-10/M-16 | 55/15 | — | — | — | — | — | — | 12200 | 1.4 |
| A-23 | M-1 | 30 | M-10/M-17 | 55/15 | — | — | — | — | — | — | 12100 | 1.4 |
| A-24 | M-1/M-18 | 30/15 | M-10 | 55 | — | — | — | — | — | — | 12100 | 1.4 |
| A-25 | M-1 | 30 | M-10 | 55 | — | — | M-19 | 15 | — | — | 12000 | 1.3 |
| A-26 | M-1 | 30 | M-10 | 55 | — | — | M-20 | 15 | — | — | 12200 | 1.4 |
| A-27 | M-1 | 30 | M-10 | 55 | — | — | M-21 | 15 | — | — | 12000 | 1.5 |
| A-28 | M-1 | 30 | M-10 | 55 | — | — | M-22 | 15 | — | — | 12100 | 1.3 |
| A-29 | M-1 | 30 | M-10 | 55 | — | — | M-23 | 15 | — | — | 7300 | 1.3 |
| A-30 | M-1 | 30 | M-10 | 55 | — | — | M-24 | 15 | — | — | 7200 | 1.5 |
| A-31 | M-1 | 30 | M-15 | 15 | M-5 | 55 | — | — | — | — | 12200 | 1.4 |
| A-32 | M-1 | 45 | M-10 | 50 | — | — | — | — | M-25 | 5 | 7300 | 1.4 |
| A-33 | M-1 | 45 | M-10 | 50 | — | — | — | — | M-26 | 5 | 7100 | 1.5 |
| A-34 | M-1 | 45 | M-10 | 50 | — | — | — | — | M-27 | 5 | 7200 | 1.4 |
| A-35 | M-1 | 45 | — | — | M-5 | 50 | — | — | M-27 | 5 | 7200 | 1.4 |
| A-36 | M-2 | 30 | M-10/M-16 | 30/15 | M-8 | 25 | — | — | — | — | 13300 | 1.4 |
| A-37 | M-3/M-18 | 30/25 | M-10/M-17 | 30/15 | — | — | — | — | — | — | 13500 | 1.3 |
| A-38 | M-3/M-18 | 30/5 | M-10/M-17 | 50/15 | — | — | — | — | — | — | 13300 | 1.4 |
| A-39 | M-3/M-18 | 30/5 | M-10/M-17 | 50/15 | M-8 | 25 | — | — | — | — | 13200 | 1.5 |
| A-40 | M-3/M-18 | 30/5 | M-17 | 15 | M-5 | 50 | — | — | — | — | 13300 | 1.4 |

### [Synthesis Examples] Synthesis of Second Polymer

Monomers represented by the following formulas were combined in the composition shown in the following Table 2, and then subjected to a copolymerization reaction in a tetrahydrofuran (THF) solvent. After the polymerization, the solvent was substituted with acetonitrile, followed by washing with hexane. Thereafter, the solvent was substituted with propylene glycol monomethyl ether acetate to yield FP-1 to FP-21 as second polymers.

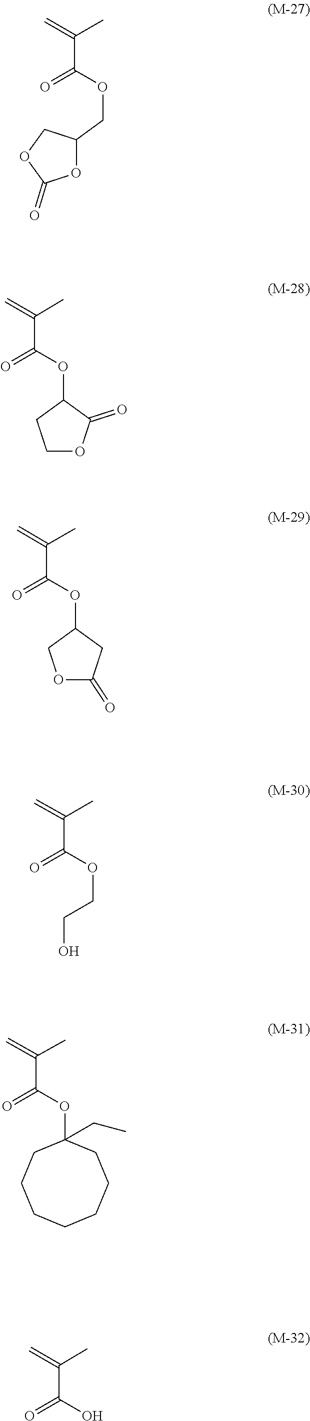

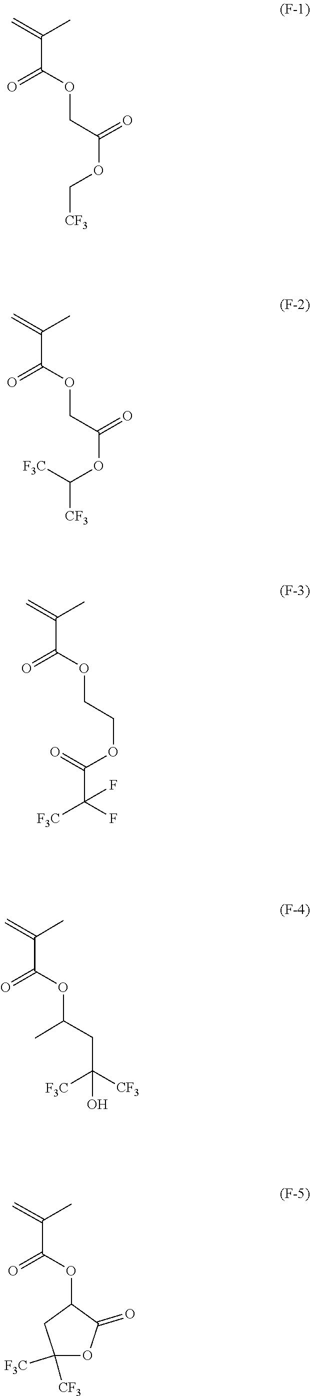 [SMILES: C=C(C)C(=O)OCC(=O)OCC(F)(F)F ; C=C(C)C(=O)OCC(=O)OC(C(F)(F)F)C(F)(F)F ; C=C(C)C(=O)OCCOC(=O)C(F)(F)C(F)(F)F ; C=C(C)C(=O)OC(C)CC(O)(C(F)(F)F)C(F)(F)F ; C=C(C)C(=O)OC1CC(C(F)(F)F)(C(F)(F)F)OC1=O]

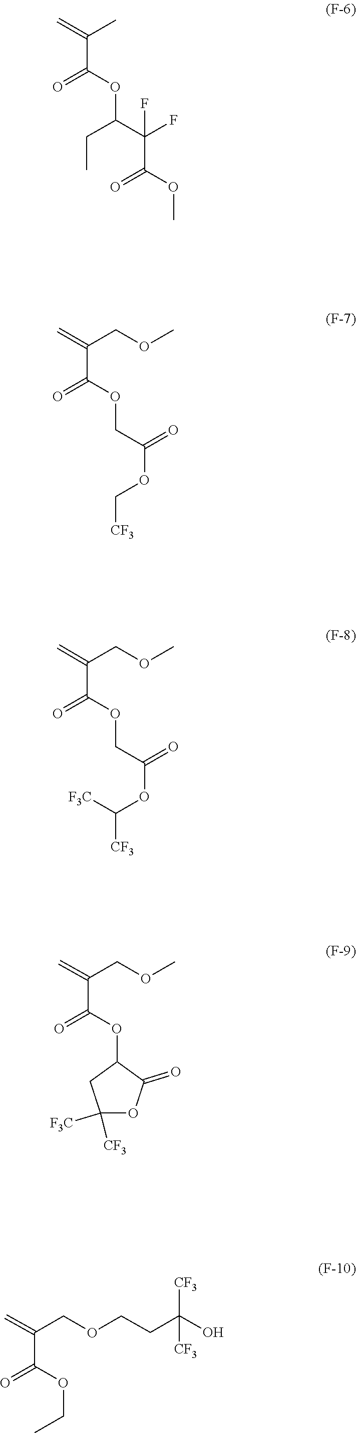 [SMILES: C=C(C)C(=O)OC(CC)C(F)(F)C(=O)OC ; C=C(COC)C(=O)OCC(=O)OCC(F)(F)F ; C=C(COC)C(=O)OCC(=O)OC(C(F)(F)F)C(F)(F)F ; C=C(COC)C(=O)OC1CC(C(F)(F)F)(C(F)(F)F)OC1=O ; C=C(COCCC(O)(C(F)(F)F)C(F)(F)F)C(=O)OCC]

TABLE 2

| | Monomer that affords | | Monomer that affords | | Monomer that affords | | | |
|---|---|---|---|---|---|---|---|---|
| | structural unit (II) | | structural unit (i) | | structural unit (ii) or (iii) | | | |
| Second | | Used amount | | Used amount | | Used amount | | |
| polymer | Type | (mol %) | Type | (mol %) | Type | (mol %) | Mw | Mw/Mn |
| FP-1 | M-31 | 30 | F-1 | 70 | — | — | 20000 | 1.5 |
| FP-2 | M-31 | 30 | F-2 | 70 | — | — | 22000 | 1.5 |
| FP-3 | M-31 | 30 | F-3 | 70 | — | — | 19000 | 1.5 |
| FP-4 | M-31 | 30 | F-5 | 70 | — | — | 20000 | 1.5 |
| FP-5 | M-31 | 30 | F-6 | 70 | — | — | 21000 | 1.5 |
| FP-6 | M-31 | 30 | F-7 | 70 | — | — | 21000 | 1.5 |
| FP-7 | M-31 | 30 | F-8 | 70 | — | — | 21000 | 1.5 |
| FP-8 | M-31 | 30 | F-9 | 70 | — | — | 20000 | 1.5 |
| FP-9 | M-7 | 30 | F-1 | 70 | — | — | 20000 | 1.5 |
| FP-10 | M-9 | 30 | F-1 | 70 | — | — | 21000 | 1.5 |
| FP-11 | — | — | F-4 | 100 | — | — | 21000 | 1.5 |
| FP-12 | — | — | F-10 | 100 | — | — | 21000 | 1.5 |
| FP-13 | M-31 | 30 | F-1 | 70 | — | — | 20000 | 1.5 |
| FP-14 | M-31 | 30 | F-1 | 70 | — | — | 22000 | 1.5 |
| FP-15 | M-31 | 30 | F-1 | 70 | — | — | 22000 | 1.5 |
| FP-16 | M-31 | 30 | F-1 | 50 | M-27 | 20 | 20000 | 1.5 |
| FP-17 | M-31 | 30 | F-1 | 50 | M-28 | 20 | 21000 | 1.5 |
| FP-18 | M-31 | 30 | F-7 | 50 | M-29 | 20 | 20000 | 1.5 |
| FP-19 | M-31 | 30 | F-7 | 50 | M-30 | 20 | 21000 | 1.5 |
| FP-20 | — | — | F-1 | 70 | M-32 | 30 | 20000 | 1.5 |
| FP-21 | — | — | F-7 | 80 | M-32 | 20 | 20000 | 1.5 |

In addition to the synthesized polymer, components for use in preparation of the radiation-sensitive composition are shown below.

### <[B] Radiation-Sensitive Acid Generator>

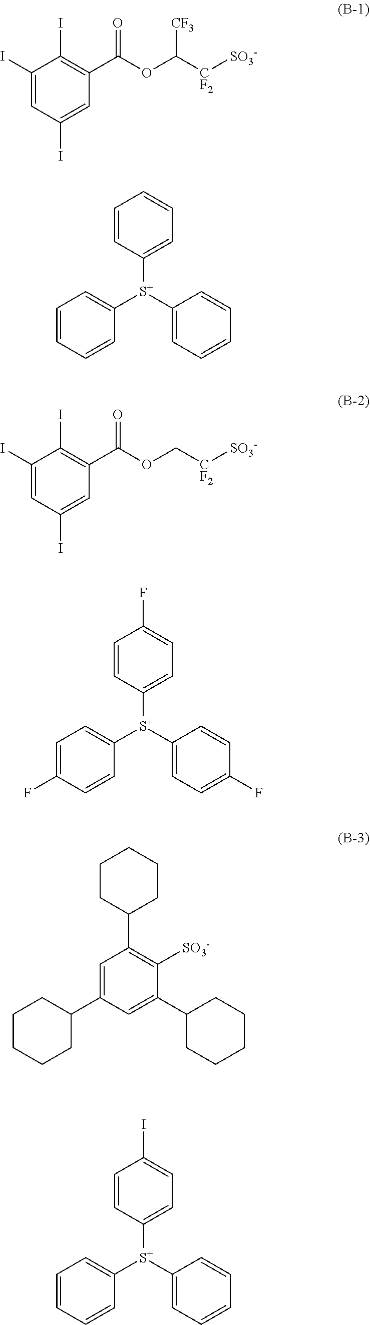

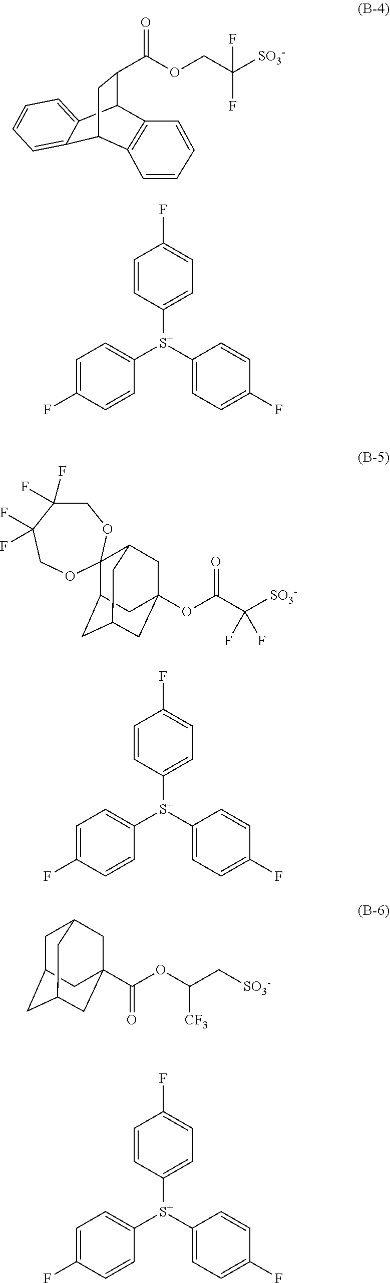

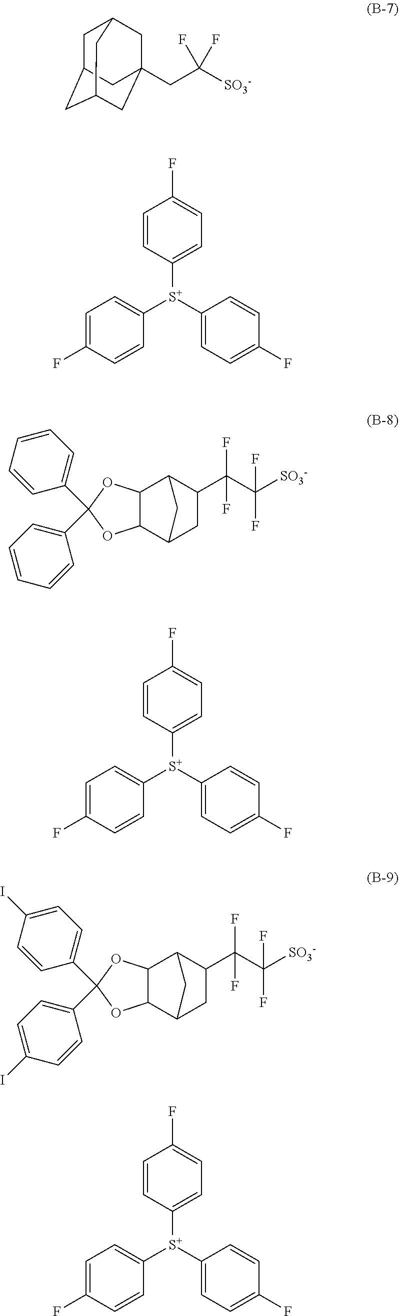

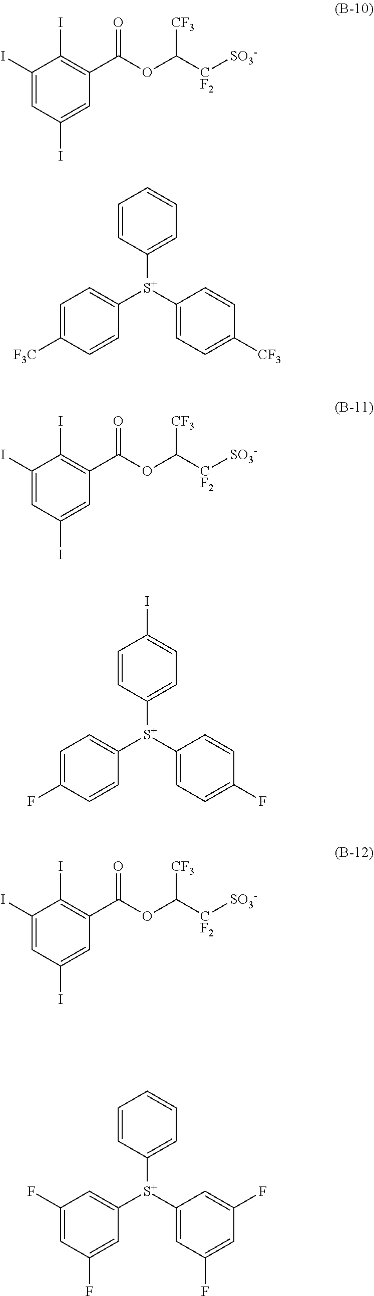

### <[C] Acid Diffusion Controlling Agent>

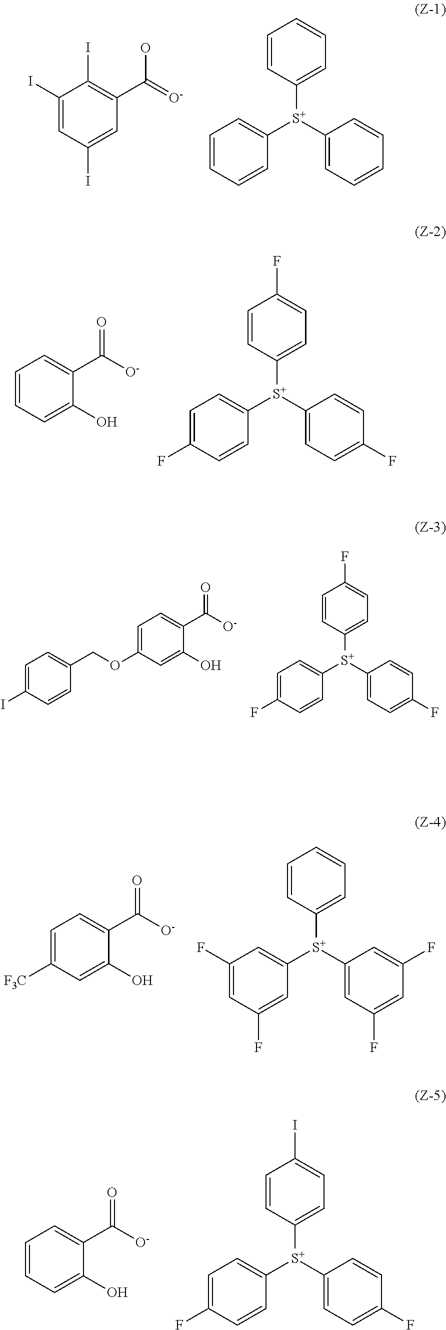

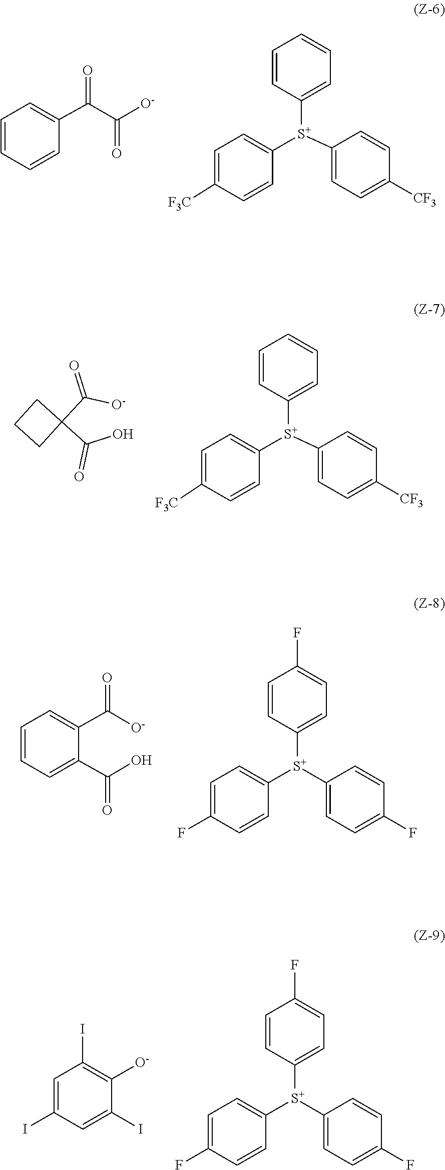

### <[D] Solvent>

D-1: Propylene glycol monomethyl ether acetate
D-2: Propylene glycol 1-monomethyl ether

### Example 1

A radiation-sensitive composition (R-1) was prepared by blending 100 parts by mass of the first polymer (A-6) [A], 20 parts by mass of (B-1) as the radiation-sensitive acid generator [B], 25 mol % of (Z-1) as the acid diffusion inhibitor [C] based on (B-1), 5 parts by mass of the second polymer (FP-1) [F], 2,000 parts by mass of (D-1) as the solvent [D], and 4,800 parts by mass of (D-2).

### Examples 2 to 64 and Comparative Examples 1 to 62

Radiation-sensitive compositions (R-2) to (R-64) and (cR-1) to (cR-62) were prepared in the same manner as in Example 1 except that the types and blending amounts of respective components shown in the following Table 3 and the following Table 4 were used.

TABLE 3

| | | | | | | Acid diffusion inhibitor [C] | | | | | |
|---|---|---|---|---|---|---|---|---|---|---|---|
| | | | | | | | Based on monomer | | | | |
| | | | | Radiation-sensitive | | | that affords | | | | |
| | Radiation- | First polymer [A] | | acid generator [B] | | | structural unit | Second polymer [F] | | | |
| | sensitive | | Parts by | | Parts by | | (IV) and [B] | | Parts by | | Parts by |
| | composition | Type | mass | Type | mass | Type | (mol %) | Type | mass | Solvent [D] | mass |
| Example 1 | R-1 | A-6 | 100 | B-1 | 20 | Z-1 | 25 | FP-1 | 5 | D-1/D-2 | 2000/4800 |
| Example 2 | R-2 | A-7 | 100 | B-1 | 20 | Z-1 | 25 | FP-1 | 5 | D-1/D-2 | 2000/4800 |
| Example 3 | R-3 | A-8 | 100 | B-1 | 20 | Z-1 | 25 | FP-1 | 5 | D-1/D-2 | 2000/4800 |
| Example 4 | R-4 | A-9 | 100 | B-1 | 20 | Z-1 | 25 | FP-1 | 5 | D-1/D-2 | 2000/4800 |
| Example 5 | R-5 | A-10 | 100 | B-1 | 20 | Z-1 | 25 | FP-1 | 5 | D-1/D-2 | 2000/4800 |
| Example 6 | R-6 | A-11 | 100 | B-1 | 20 | Z-1 | 25 | FP-1 | 5 | D-1/D-2 | 2000/4800 |
| Example 7 | R-7 | A-12 | 100 | B-1 | 20 | Z-1 | 25 | FP-1 | 5 | D-1/D-2 | 2000/4800 |
| Example 8 | R-8 | A-13 | 100 | B-1 | 20 | Z-1 | 25 | FP-1 | 5 | D-1/D-2 | 2000/4800 |
| Example 9 | R-9 | A-17 | 100 | B-1 | 20 | Z-1 | 25 | FP-1 | 5 | D-1/D-2 | 2000/4800 |
| Example 10 | R-10 | A-18 | 100 | B-1 | 20 | Z-1 | 25 | FP-1 | 5 | D-1/D-2 | 2000/4800 |
| Example 11 | R-11 | A-19 | 100 | B-1 | 20 | Z-1 | 25 | FP-1 | 5 | D-1/D-2 | 2000/4800 |
| Example 12 | R-12 | A-21 | 100 | B-1 | 20 | Z-1 | 25 | FP-1 | 5 | D-1/D-2 | 2000/4800 |
| Example 13 | R-13 | A-22 | 100 | — | — | Z-1 | 25 | FP-1 | 5 | D-1/D-2 | 2000/4800 |
| Example 14 | R-14 | A-23 | 100 | — | — | Z-1 | 25 | FP-1 | 5 | D-1/D-2 | 2000/4800 |
| Example 15 | R-15 | A-24 | 100 | — | — | Z-1 | 25 | FP-1 | 5 | D-1/D-2 | 2000/4800 |
| Example 16 | R-16 | A-25 | 100 | — | — | Z-1 | 25 | FP-1 | 5 | D-1/D-2 | 2000/4800 |
| Example 17 | R-17 | A-26 | 100 | — | — | Z-1 | 25 | FP-1 | 5 | D-1/D-2 | 2000/4800 |
| Example 18 | R-18 | A-27 | 100 | — | — | Z-1 | 25 | FP-1 | 5 | D-1/D-2 | 2000/4800 |
| Example 19 | R-19 | A-28 | 100 | — | — | Z-1 | 25 | FP-1 | 5 | D-1/D-2 | 2000/4800 |
| Example 20 | R-20 | A-29 | 100 | — | — | Z-1 | 25 | FP-1 | 5 | D-1/D-2 | 2000/4800 |
| Example 21 | R-21 | A-30 | 100 | — | — | Z-1 | 25 | FP-1 | 5 | D-1/D-2 | 2000/4800 |
| Example 22 | R-22 | A-31 | 100 | — | — | Z-1 | 25 | FP-1 | 5 | D-1/D-2 | 2000/4800 |
| Example 23 | R-23 | A-32 | 100 | B-1 | 20 | — | — | FP-1 | 5 | D-1/D-2 | 2000/4800 |
| Example 24 | R-24 | A-33 | 100 | B-1 | 20 | — | — | FP-1 | 5 | D-1/D-2 | 2000/4800 |
| Example 25 | R-25 | A-35 | 100 | B-1 | 20 | — | — | FP-1 | 5 | D-1/D-2 | 2000/4800 |
| Example 26 | R-26 | A-36 | 100 | — | — | Z-1 | 25 | FP-1 | 5 | D-1/D-2 | 2000/4800 |
| Example 27 | R-27 | A-37 | 100 | — | — | Z-1 | 25 | FP-1 | 5 | D-1/D-2 | 2000/4800 |
| Example 28 | R-28 | A-38 | 100 | — | — | — | — | FP-1 | 5 | D-1/D-2 | 2000/4800 |
| Example 29 | R-29 | A-39 | 100 | — | — | — | — | FP-1 | 5 | D-1/D-2 | 2000/4800 |
| Example 30 | R-30 | A-6 | 100 | B-1 | 20 | Z-1 | 25 | FP-2 | 5 | D-1/D-2 | 2000/4800 |
| Example 31 | R-31 | A-6 | 100 | B-1 | 20 | Z-1 | 25 | FP-3 | 5 | D-1/D-2 | 2000/4800 |
| Example 32 | R-32 | A-6 | 100 | B-1 | 20 | Z-1 | 25 | FP-5 | 5 | D-1/D-2 | 2000/4800 |
| Example 33 | R-33 | A-6 | 100 | B-1 | 20 | Z-1 | 25 | FP-6 | 5 | D-1/D-2 | 2000/4800 |
| Example 34 | R-34 | A-6 | 100 | B-1 | 20 | Z-1 | 25 | FP-7 | 5 | D-1/D-2 | 2000/4800 |
| Example 35 | R-35 | A-6 | 100 | B-1 | 20 | Z-1 | 25 | FP-9 | 5 | D-1/D-2 | 2000/4800 |
| Example 36 | R-36 | A-6 | 100 | B-1 | 20 | Z-1 | 25 | FP-10 | 5 | D-1/D-2 | 2000/4800 |
| Example 37 | R-37 | A-6 | 100 | B-1 | 20 | Z-1 | 25 | FP-13 | 5 | D-1/D-2 | 2000/4800 |
| Example 38 | R-38 | A-6 | 100 | B-1 | 20 | Z-1 | 25 | FP-14 | 5 | D-1/D-2 | 2000/4800 |
| Example 39 | R-39 | A-6 | 100 | B-1 | 20 | Z-1 | 25 | FP-15 | 5 | D-1/D-2 | 2000/4800 |
| Example 40 | R-40 | A-6 | 100 | B-1 | 20 | Z-1 | 25 | FP-16 | 5 | D-1/D-2 | 2000/4800 |
| Example 41 | R-41 | A-6 | 100 | B-1 | 20 | Z-1 | 25 | FP-17 | 5 | D-1/D-2 | 2000/4800 |
| Example 42 | R-42 | A-6 | 100 | B-1 | 20 | Z-1 | 25 | FP-18 | 5 | D-1/D-2 | 2000/4800 |
| Example 43 | R-43 | A-6 | 100 | B-1 | 20 | Z-1 | 25 | FP-19 | 5 | D-1/D-2 | 2000/4800 |
| Example 44 | R-44 | A-6 | 100 | B-2 | 20 | Z-1 | 25 | FP-1 | 5 | D-1/D-2 | 2000/4800 |
| Example 45 | R-45 | A-6 | 100 | B-3 | 20 | Z-1 | 25 | FP-1 | 5 | D-1/D-2 | 2000/4800 |
| Example 46 | R-46 | A-6 | 100 | B-4 | 20 | Z-1 | 25 | FP-1 | 5 | D-1/D-2 | 2000/4800 |
| Example 47 | R-47 | A-6 | 100 | B-5 | 20 | Z-1 | 25 | FP-1 | 5 | D-1/D-2 | 2000/4800 |
| Example 48 | R-48 | A-6 | 100 | B-6 | 20 | Z-1 | 25 | FP-1 | 5 | D-1/D-2 | 2000/4800 |
| Example 49 | R-49 | A-6 | 100 | B-7 | 20 | Z-1 | 25 | FP-1 | 5 | D-1/D-2 | 2000/4800 |
| Example 50 | R-50 | A-6 | 100 | B-8 | 20 | Z-1 | 25 | FP-1 | 5 | D-1/D-2 | 2000/4800 |
| Example 51 | R-51 | A-6 | 100 | B-9 | 20 | Z-1 | 25 | FP-1 | 5 | D-1/D-2 | 2000/4800 |
| Example 52 | R-52 | A-6 | 100 | B-10 | 20 | Z-1 | 25 | FP-1 | 5 | D-1/D-2 | 2000/4800 |
| Example 53 | R-53 | A-6 | 100 | B-11 | 20 | Z-1 | 25 | FP-1 | 5 | D-1/D-2 | 2000/4800 |
| Example 54 | R-54 | A-6 | 100 | B-12 | 20 | Z-1 | 25 | FP-1 | 5 | D-1/D-2 | 2000/4800 |
| Example 55 | R-55 | A-6 | 100 | B-1 | 20 | Z-2 | 25 | FP-1 | 5 | D-1/D-2 | 2000/4800 |
| Example 56 | R-56 | A-6 | 100 | B-1 | 20 | Z-3 | 25 | FP-1 | 5 | D-1/D-2 | 2000/4800 |
| Example 57 | R-57 | A-6 | 100 | B-1 | 20 | Z-4 | 25 | FP-1 | 5 | D-1/D-2 | 2000/4800 |
| Example 58 | R-58 | A-6 | 100 | B-1 | 20 | Z-5 | 25 | FP-1 | 5 | D-1/D-2 | 2000/4800 |
| Example 59 | R-59 | A-6 | 100 | B-1 | 20 | Z-6 | 25 | FP-1 | 5 | D-1/D-2 | 2000/4800 |
| Example 60 | R-60 | A-6 | 100 | B-1 | 20 | Z-7 | 25 | FP-1 | 5 | D-1/D-2 | 2000/4800 |
| Example 61 | R-61 | A-6 | 100 | B-1 | 20 | Z-8 | 25 | FP-1 | 5 | D-1/D-2 | 2000/4800 |
| Example 62 | R-62 | A-6 | 100 | B-1 | 20 | Z-9 | 25 | FP-1 | 5 | D-1/D-2 | 2000/4800 |
| Example 63 | R-63 | A-6 | 100 | B-1 | 20 | Z-1 | 25 | FP-20 | 5 | D-1/D-2 | 2000/4800 |
| Example 64 | R-64 | A-6 | 100 | B-1 | 20 | Z-1 | 25 | FP-21 | 5 | D-1/D-2 | 2000/4800 |

TABLE 4

| | | | | | | Acid diffusion inhibitor [C] | | | | | |
|---|---|---|---|---|---|---|---|---|---|---|---|
| | | | | | | | Based on monomer | | | | |
| | | | | Radiation-sensitive | | | that affords | | | | |
| | Radiation- | First polymer [A] | | acid generator [B] | | | structural unit | Second polymer [F] | | | |
| | sensitive | | Parts by | | Parts by | | (IV) and [B] | | Parts by | | Parts by |
| | composition | Type | mass | Type | mass | Type | (mol %) | Type | mass | Solvent [D] | mass |
| Comparative | cR-1 | A-1 | 100 | B-1 | 20 | Z-1 | 25 | FP-1 | 5 | D-1/D-2 | 2000/4800 |
| Example 1 | | | | | | | | | | | |
| Comparative | cR-2 | A-2 | 100 | B-1 | 20 | Z-1 | 25 | FP-1 | 5 | D-1/D-2 | 2000/4800 |
| Example 2 | | | | | | | | | | | |
| Comparative | cR-3 | A-3 | 100 | B-1 | 20 | Z-1 | 25 | FP-1 | 5 | D-1/D-2 | 2000/4800 |
| Example 3 | | | | | | | | | | | |
| Comparative | cR-4 | A-4 | 100 | B-1 | 20 | Z-1 | 25 | FP-1 | 5 | D-1/D-2 | 2000/4800 |
| Example 4 | | | | | | | | | | | |
| Comparative | cR-5 | A-5 | 100 | B-1 | 20 | Z-1 | 25 | FP-1 | 5 | D-1/D-2 | 2000/4800 |
| Example 5 | | | | | | | | | | | |
| Comparative | cR-6 | A-14 | 100 | B-1 | 20 | Z-1 | 25 | FP-1 | 5 | D-1/D-2 | 2000/4800 |
| Example 6 | | | | | | | | | | | |
| Comparative | cR-7 | A-15 | 100 | B-1 | 20 | Z-1 | 25 | FP-1 | 5 | D-1/D-2 | 2000/4800 |
| Example 7 | | | | | | | | | | | |
| Comparative | cR-8 | A-16 | 100 | B-1 | 20 | Z-1 | 25 | FP-1 | 5 | D-1/D-2 | 2000/4800 |
| Example 8 | | | | | | | | | | | |
| Comparative | cR-9 | A-20 | 100 | B-1 | 20 | Z-1 | 25 | FP-1 | 5 | D-1/D-2 | 2000/4800 |
| Example 9 | | | | | | | | | | | |
| Comparative | cR-10 | A-31 | 100 | — | — | Z-1 | 25 | FP-1 | 5 | D-1/D-2 | 2000/4800 |
| Example 10 | | | | | | | | | | | |
| Comparative | cR-11 | A-35 | 100 | B-1 | 20 | — | — | FP-1 | 5 | D-1/D-2 | 2000/4800 |
| Example 11 | | | | | | | | | | | |
| Comparative | cR-12 | A-40 | 100 | — | — | — | — | FP-1 | 5 | D-1/D-2 | 2000/4800 |
| Example 12 | | | | | | | | | | | |
| Comparative | cR-13 | A-6 | 100 | B-1 | 20 | Z-1 | 25 | — | — | D-1/D-2 | 2000/4800 |
| Example 13 | | | | | | | | | | | |
| Comparative | cR-14 | A-7 | 100 | B-1 | 20 | Z-1 | 25 | — | — | D-1/D-2 | 2000/4800 |
| Example 14 | | | | | | | | | | | |
| Comparative | cR-15 | A-8 | 100 | B-1 | 20 | Z-1 | 25 | — | — | D-1/D-2 | 2000/4800 |
| Example 15 | | | | | | | | | | | |
| Comparative | cR-16 | A-9 | 100 | B-1 | 20 | Z-1 | 25 | — | — | D-1/D-2 | 2000/4800 |
| Example 16 | | | | | | | | | | | |
| Comparative | cR-17 | A-10 | 100 | B-1 | 20 | Z-1 | 25 | — | — | D-1/D-2 | 2000/4800 |
| Example 17 | | | | | | | | | | | |
| Comparative | cR-18 | A-11 | 100 | B-1 | 20 | Z-1 | 25 | — | — | D-1/D-2 | 2000/4800 |
| Example 18 | | | | | | | | | | | |
| Comparative | cR-19 | A-12 | 100 | B-1 | 20 | Z-1 | 25 | — | — | D-1/D-2 | 2000/4800 |
| Example 19 | | | | | | | | | | | |
| Comparative | cR-20 | A-13 | 100 | B-1 | 20 | Z-1 | 25 | — | — | D-1/D-2 | 2000/4800 |
| Example 20 | | | | | | | | | | | |
| Comparative | cR-21 | A-17 | 100 | B-1 | 20 | Z-1 | 25 | — | — | D-1/D-2 | 2000/4800 |
| Example 21 | | | | | | | | | | | |
| Comparative | cR-22 | A-18 | 100 | B-1 | 20 | Z-1 | 25 | — | — | D-1/D-2 | 2000/4800 |
| Example 22 | | | | | | | | | | | |
| Comparative | cR-23 | A-21 | 100 | B-1 | 20 | Z-1 | 25 | — | — | D-1/D-2 | 2000/4800 |
| Example 23 | | | | | | | | | | | |
| Comparative | cR-24 | A-22 | 100 | — | — | Z-1 | 25 | — | — | D-1/D-2 | 2000/4800 |
| Example 24 | | | | | | | | | | | |
| Comparative | cR-25 | A-23 | 100 | — | — | Z-1 | 25 | — | — | D-1/D-2 | 2000/4800 |
| Example 25 | | | | | | | | | | | |
| Comparative | cR-26 | A-24 | 100 | — | — | Z-1 | 25 | — | — | D-1/D-2 | 2000/4800 |
| Example 26 | | | | | | | | | | | |
| Comparative | cR-27 | A-25 | 100 | — | — | Z-1 | 25 | — | — | D-1/D-2 | 2000/4800 |
| Example 27 | | | | | | | | | | | |
| Comparative | cR-28 | A-26 | 100 | — | — | Z-1 | 25 | — | — | D-1/D-2 | 2000/4800 |
| Example 28 | | | | | | | | | | | |
| Comparative | cR-29 | A-27 | 100 | — | — | Z-1 | 25 | — | — | D-1/D-2 | 2000/4800 |
| Example 29 | | | | | | | | | | | |
| Comparative | cR-30 | A-28 | 100 | — | — | Z-1 | 25 | — | — | D-1/D-2 | 2000/4800 |
| Example 30 | | | | | | | | | | | |
| Comparative | cR-31 | A-29 | 100 | — | — | Z-1 | 25 | — | — | D-1/D-2 | 2000/4800 |
| Example 31 | | | | | | | | | | | |
| Comparative | cR-32 | A-30 | 100 | — | — | Z-1 | 25 | — | — | D-1/D-2 | 2000/4800 |
| Example 32 | | | | | | | | | | | |
| Comparative | cR-33 | A-32 | 100 | B-1 | 20 | — | — | — | — | D-1/D-2 | 2000/4800 |
| Example 33 | | | | | | | | | | | |
| Comparative | cR-34 | A-33 | 100 | B-1 | 20 | — | — | — | — | D-1/D-2 | 2000/4800 |
| Example 34 | | | | | | | | | | | |
| Comparative | cR-35 | A-34 | 100 | B-1 | 20 | — | — | — | — | D-1/D-2 | 2000/4800 |
| Example 35 | | | | | | | | | | | |
| Comparative | cR-36 | A-36 | 100 | — | — | Z-1 | 25 | — | — | D-1/D-2 | 2000/4800 |
| Example 36 | | | | | | | | | | | |
| Comparative | cR-37 | A-37 | 100 | — | — | Z-1 | 25 | — | — | D-1/D-2 | 2000/4800 |
| Example 37 | | | | | | | | | | | |
| Comparative | cR-38 | A-38 | 100 | — | — | — | — | — | — | D-1/D-2 | 2000/4800 |
| Example 38 | | | | | | | | | | | |
| Comparative | cR-39 | A-39 | 100 | — | — | — | — | — | — | D-1/D-2 | 2000/4800 |
| Example 39 | | | | | | | | | | | |
| Comparative | cR-40 | A-6 | 100 | B-2 | 20 | Z-1 | 25 | — | — | D-1/D-2 | 2000/4800 |
| Example 40 | | | | | | | | | | | |
| Comparative | cR-41 | A-6 | 100 | B-3 | 20 | Z-1 | 25 | — | — | D-1/D-2 | 2000/4800 |
| Example 41 | | | | | | | | | | | |
| Comparative | cR-42 | A-6 | 100 | B-4 | 20 | Z-1 | 25 | — | — | D-1/D-2 | 2000/4800 |
| Example 42 | | | | | | | | | | | |
| Comparative | cR-43 | A-6 | 100 | B-5 | 20 | Z-1 | 25 | — | — | D-1/D-2 | 2000/4800 |
| Example 43 | | | | | | | | | | | |
| Comparative | cR-44 | A-6 | 100 | B-6 | 20 | Z-1 | 25 | — | — | D-1/D-2 | 2000/4800 |
| Example 44 | | | | | | | | | | | |
| Comparative | cR-45 | A-6 | 100 | B-7 | 20 | Z-1 | 25 | — | — | D-1/D-2 | 2000/4800 |
| Example 45 | | | | | | | | | | | |
| Comparative | cR-46 | A-6 | 100 | B-8 | 20 | Z-1 | 25 | — | — | D-1/D-2 | 2000/4800 |
| Example 46 | | | | | | | | | | | |
| Comparative | cR-47 | A-6 | 100 | B-9 | 20 | Z-1 | 25 | — | — | D-1/D-2 | 2000/4800 |
| Example 47 | | | | | | | | | | | |
| Comparative | cR-48 | A-6 | 100 | B-10 | 20 | Z-1 | 25 | — | — | D-1/D-2 | 2000/4800 |
| Example 48 | | | | | | | | | | | |
| Comparative | cR-49 | A-6 | 100 | B-11 | 20 | Z-1 | 25 | — | — | D-1/D-2 | 2000/4800 |
| Example 49 | | | | | | | | | | | |
| Comparative | cR-50 | A-6 | 100 | B-12 | 20 | Z-1 | 25 | — | — | D-1/D-2 | 2000/4800 |
| Example 50 | | | | | | | | | | | |
| Comparative | cR-51 | A-6 | 100 | B-1 | 20 | Z-2 | 25 | — | — | D-1/D-2 | 2000/4800 |
| Example 51 | | | | | | | | | | | |
| Comparative | cR-52 | A-6 | 100 | B-1 | 20 | Z-3 | 25 | — | — | D-1/D-2 | 2000/4800 |
| Example 52 | | | | | | | | | | | |
| Comparative | cR-53 | A-6 | 100 | B-1 | 20 | Z-4 | 25 | — | — | D-1/D-2 | 2000/4800 |
| Example 53 | | | | | | | | | | | |
| Comparative | cR-54 | A-6 | 100 | B-1 | 20 | Z-5 | 25 | — | — | D-1/D-2 | 2000/4800 |
| Example 54 | | | | | | | | | | | |
| Comparative | cR-55 | A-6 | 100 | B-1 | 20 | Z-6 | 25 | — | — | D-1/D-2 | 2000/4800 |
| Example 55 | | | | | | | | | | | |
| Comparative | cR-56 | A-6 | 100 | B-1 | 20 | Z-7 | 25 | — | — | D-1/D-2 | 2000/4800 |
| Example 56 | | | | | | | | | | | |
| Comparative | cR-57 | A-6 | 100 | B-1 | 20 | Z-8 | 25 | — | — | D-1/D-2 | 2000/4800 |
| Example 57 | | | | | | | | | | | |
| Comparative | cR-58 | A-6 | 100 | B-1 | 20 | Z-9 | 25 | — | — | D-1/D-2 | 2000/4800 |
| Example 58 | | | | | | | | | | | |
| Comparative | cR-59 | A-6 | 100 | B-1 | 10 | Z-1 | 25 | FP-4 | 5 | D-1/D-2 | 2000/4800 |
| Example 59 | | | | | | | | | | | |
| Comparative | cR-60 | A-6 | 100 | B-1 | 10 | Z-1 | 25 | FP-8 | 5 | D-1/D-2 | 2000/4800 |
| Example 60 | | | | | | | | | | | |
| Comparative | cR-61 | A-6 | 100 | B-1 | 10 | Z-1 | 25 | FP-11 | 5 | D-1/D-2 | 2000/4800 |
| Example 61 | | | | | | | | | | | |
| Comparative | cR-62 | A-6 | 100 | B-1 | 10 | Z-1 | 25 | FP-12 | 5 | D-1/D-2 | 2000/4800 |
| Example 62 | | | | | | | | | | | |

### <Formation of Resist Pattern> (EUN Exposure, Alkaline Development)

Each of the radiation-sensitive compositions prepared above was applied using a spin coater (CLEAN TRACK ACT12 manufactured by Tokyo Electron Ltd.) onto the surface of a 12-inch silicon wafer on which a lower layer film (AL412 (manufactured by Brewer Science)) having a thickness of 50 nm had been formed. After PB was performed at 130° C. for 60 seconds, cooling was performed at 23° C. for 30 seconds to form a resist film having a thickness of 50 nm. Then, the resist film was irradiated with EUV light using an EUV scanner (type “NXE3300”, manufactured by ASML, NA=0.33, lighting condition: Conventional, s=0.89, Mask imecDEFECT32FFR02). The resist film was subjected to PEB at 110° C. for 60 seconds. Then, development was performed at 23° C. for 30 seconds using a 2.38 wt % aqueous TMAH solution to form a positive 32 nm line-and-space pattern.

### <Evaluation>

The sensitivity, LWR performance, and over-exposure margin of each of the radiation-sensitive compositions were evaluated by measuring each of the formed resist patterns according to the following method. A scanning electron microscope (“CG-4100” manufactured by Hitachi High-Technologies Corporation) was used for measuring the length of the resist pattern. The evaluation results are given in the following Tables 5 and 6.

### [Sensitivity]

An exposure amount at which a 32 nm line-and-space pattern was formed in the formation of the EUV resist pattern was defined as an optimum exposure amount, and the optimum exposure amount was defined as sensitivity (mJ/cm²). The sensitivity of less than 30 mJ/cm² was evaluated as A (excellent), the sensitivity of 30 mJ/cm² or more and less than 33 mJ/cm² was evaluated as B (good), and the sensitivity of 33 mJ/cm² or more was evaluated as C (defective).

### [Lwr Performance]

Using the scanning electron microscope, the resist pattern formed by the EUV was observed from above. Line widths were measured at a total of 50 optional points. A 3 sigma value was obtained from the distribution of the measurement values, and defined as LWR (unit: nm). The LWR of less than 2.8 nm was evaluated as A (excellent), the LWR of 2.8 nm or more and less than 3.2 nm was evaluated as B (good), and the LWR of 3.2 nm or more was evaluated as C (defective).

### [Overexposure Margin (Max CD)]

In the 32 nm line-and-space pattern, the maximum value of the width of the space pattern that was resolved without pattern collapse/line break was defined as Max CD (nm). The Max CD of 19 nm or more was evaluated as A (excellent), the Max CD of 16 nm or more and less than 19 nm was evaluated as B (good), and the Max CD of less than 16 nm was evaluated as C (defective).

TABLE 5

| | Radiation- | | | |
|---|---|---|---|---|
| | sensitive | Eop | LWR | Max CD |
| Example | composition | (mJ/cm²) | (nm) | (nm) |
| Example 1 | R-1 | B | B | A |
| Example 2 | R-2 | B | B | A |
| Example 3 | R-3 | B | B | A |
| Example 4 | R-4 | B | B | A |
| Example 5 | R-5 | B | B | A |
| Example 6 | R-6 | B | B | A |
| Example 7 | R-7 | B | B | A |
| Example 8 | R-8 | B | B | A |
| Example 9 | R-9 | B | B | A |
| Example 10 | R-10 | B | B | A |
| Example 11 | R-11 | A | B | A |
| Example 12 | R-12 | B | B | A |
| Example 13 | R-13 | A | A | B |
| Example 14 | R-14 | A | A | B |
| Example 15 | R-15 | A | A | B |
| Example 16 | R-16 | A | A | B |
| Example 17 | R-17 | A | A | B |
| Example 18 | R-18 | A | A | B |
| Example 19 | R-19 | A | A | B |
| Example 20 | R-20 | A | A | B |
| Example 21 | R-21 | A | A | B |
| Example 22 | R-22 | A | A | B |
| Example 23 | R-23 | A | A | B |
| Example 24 | R-24 | A | A | B |
| Example 25 | R-25 | A | A | B |
| Example 26 | R-26 | A | A | B |
| Example 27 | R-27 | A | A | B |
| Example 28 | R-28 | A | A | B |
| Example 29 | R-29 | A | A | B |
| Example 30 | R-30 | B | B | A |
| Example 31 | R-31 | B | B | A |
| Example 32 | R-32 | B | B | A |
| Example 33 | R-33 | B | B | A |
| Example 34 | R-34 | B | B | A |
| Example 35 | R-35 | B | B | A |
| Example 36 | R-36 | B | B | A |
| Example 37 | R-37 | B | B | A |
| Example 38 | R-38 | B | B | A |
| Example 39 | R-39 | B | B | A |
| Example 40 | R-40 | B | A | A |
| Example 41 | R-41 | B | A | A |
| Example 42 | R-42 | B | A | A |
| Example 43 | R-43 | B | A | A |
| Example 44 | R-44 | B | B | A |
| Example 45 | R-45 | B | B | A |
| Example 46 | R-46 | B | B | A |
| Example 47 | R-47 | B | B | A |
| Example 48 | R-48 | B | B | A |
| Example 49 | R-49 | B | B | A |
| Example 50 | R-50 | B | B | A |
| Example 51 | R-51 | B | B | A |
| Example 52 | R-52 | B | B | A |
| Example 53 | R-53 | B | B | A |
| Example 54 | R-54 | B | B | A |
| Example 55 | R-55 | B | B | A |
| Example 56 | R-56 | B | B | A |
| Example 57 | R-57 | B | B | A |
| Example 58 | R-58 | B | B | A |
| Example 59 | R-59 | B | B | A |
| Example 60 | R-60 | B | B | A |
| Example 61 | R-61 | B | B | A |
| Example 62 | R-62 | B | B | A |
| Example 63 | R-63 | B | B | A |
| Example 64 | R-64 | B | B | A |

TABLE 6

| | Radiation- | | | |
|---|---|---|---|---|
| Comparative | sensitive | Eop | LWR | Max CD |
| Example | composition | (mJ/cm²) | (nm) | (nm) |
| Comparative | cR-1 | C | C | B |
| Example 1 | | | | |
| Comparative | cR-2 | C | C | B |
| Example 2 | | | | |
| Comparative | cR-3 | C | C | B |
| Example 3 | | | | |
| Comparative | cR-4 | C | C | B |
| Example 4 | | | | |
| Comparative | cR-5 | C | C | B |
| Example 5 | | | | |
| Comparative | cR-6 | C | C | B |
| Example 6 | | | | |
| Comparative | cR-7 | C | C | B |
| Example 7 | | | | |
| Comparative | cR-8 | C | C | B |
| Example 8 | | | | |
| Comparative | cR-9 | C | C | B |
| Example 9 | | | | |
| Comparative | cR-10 | B | B | C |
| Example 10 | | | | |
| Comparative | cR-11 | B | B | C |
| Example 11 | | | | |
| Comparative | cR-12 | B | B | C |
| Example 12 | | | | |
| Comparative | cR-13 | C | C | C |
| Example 13 | | | | |
| Comparative | cR-14 | C | C | C |
| Example 14 | | | | |
| Comparative | cR-15 | C | C | C |
| Example 15 | | | | |
| Comparative | cR-16 | C | C | C |
| Example 16 | | | | |
| Comparative | cR-17 | C | C | C |
| Example 17 | | | | |
| Comparative | cR-18 | C | C | C |
| Example 18 | | | | |
| Comparative | cR-19 | C | C | C |
| Example 19 | | | | |
| Comparative | cR-20 | C | C | C |
| Example 20 | | | | |
| Comparative | cR-21 | C | C | B |
| Example 21 | | | | |
| Comparative | cR-22 | C | C | B |
| Example 22 | | | | |
| Comparative | cR-23 | C | C | B |
| Example 23 | | | | |
| Comparative | cR-24 | C | B | C |
| Example 24 | | | | |
| Comparative | cR-25 | C | B | C |
| Example 25 | | | | |
| Comparative | cR-26 | C | B | C |
| Example 26 | | | | |
| Comparative | cR-27 | C | B | C |
| Example 27 | | | | |
| Comparative | cR-28 | C | B | C |
| Example 28 | | | | |
| Comparative | cR-29 | C | B | C |
| Example 29 | | | | |
| Comparative | cR-30 | C | B | C |
| Example 30 | | | | |
| Comparative | cR-31 | C | B | C |
| Example 31 | | | | |
| Comparative | cR-32 | C | B | C |
| Example 32 | | | | |
| Comparative | cR-33 | C | B | C |
| Example 33 | | | | |
| Comparative | cR-34 | C | B | C |
| Example 34 | | | | |
| Comparative | cR-35 | C | B | C |
| Example 35 | | | | |
| Comparative | cR-36 | C | B | C |
| Example 36 | | | | |
| Comparative | cR-37 | C | B | C |
| Example 37 | | | | |
| Comparative | cR-38 | C | B | C |
| Example 38 | | | | |
| Comparative | cR-39 | C | B | C |
| Example 39 | | | | |
| Comparative | cR-40 | B | C | C |
| Example 40 | | | | |
| Comparative | cR-41 | B | C | C |
| Example 41 | | | | |
| Comparative | cR-42 | C | B | B |
| Example 42 | | | | |
| Comparative | cR-43 | C | B | B |
| Example 43 | | | | |
| Comparative | cR-44 | C | B | B |
| Example 44 | | | | |
| Comparative | cR-45 | C | B | B |
| Example 45 | | | | |
| Comparative | cR-46 | C | B | B |
| Example 46 | | | | |
| Comparative | cR-47 | C | B | B |
| Example 47 | | | | |
| Comparative | cR-48 | C | B | B |
| Example 48 | | | | |
| Comparative | cR-49 | C | B | B |
| Example 49 | | | | |
| Comparative | cR-50 | C | B | B |
| Example 50 | | | | |
| Comparative | cR-51 | C | B | B |
| Example 51 | | | | |
| Comparative | cR-52 | C | B | B |
| Example 52 | | | | |
| Comparative | cR-53 | C | B | B |
| Example 53 | | | | |
| Comparative | cR-54 | C | B | B |
| Example 54 | | | | |
| Comparative | cR-55 | C | B | B |
| Example 55 | | | | |
| Comparative | cR-56 | C | B | B |
| Example 56 | | | | |
| Comparative | cR-57 | C | B | B |
| Example 57 | | | | |
| Comparative | cR-58 | C | B | B |
| Example 58 | | | | |
| Comparative | cR-59 | C | C | C |
| Example 59 | | | | |
| Comparative | cR-60 | C | C | C |
| Example 60 | | | | |
| Comparative | cR-61 | C | C | C |
| Example 61 | | | | |
| Comparative | cR-62 | C | C | C |
| Example 62 | | | | |

As is apparent from the results of Tables 5 and 6, in all of the radiation-sensitive compositions of the Examples, the sensitivity, LWR, and Max CD were good as compared with those of the radiation-sensitive compositions of the Comparative Examples.

According to the radiation-sensitive composition and the pattern forming method of the embodiments of the present invention, the sensitivity, LWR, and over-exposure margin can be improved as compared with the conventional technology. Therefore, the radiation-sensitive composition and the pattern forming method can be suitably used for the formation of a fine resist pattern in a lithography process for various electronic devices such as semiconductor devices and liquid crystal devices.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition, comprising:
a first polymer comprising a structural unit (I) having an acid-dissociable group;
a second polymer comprising a structural unit (i) represented by formula (f1); and
a solvent,
wherein the acid-dissociable group has an iodo group: 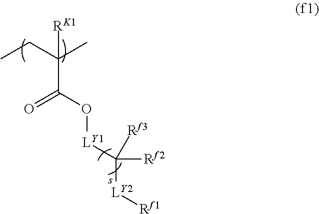
wherein in the formula (f1),
R^{K1} is a hydrogen atom, a fluorine atom, an alkyl group having 1 to 6 carbon atoms, a halogenated alkyl group having 1 to 6 carbon atoms, or a group represented by —R^{K2}—X—R^{K3}, in which R^{K2} is a single bond, an alkanediyl group having 1 to 6 carbon atoms, or a halogenated alkanediyl group having 1 to 6 carbon atoms, X is a divalent linking group having a hetero atom, and R^{K3} is an alkyl group having 1 to 6 carbon atoms or a halogenated alkyl group having 1 to 6 carbon atoms,
L^{Y1} is a divalent hydrocarbon group having 1 to 10 carbon atoms,
L^{Y2} is —COO—* or —OCO—*, *is a bond on an R^{f1} side,
R^{f1} is a monovalent hydrocarbon group having 1 to 10 carbon atoms or a monovalent fluorinated hydrocarbon group having 1 to 10 carbon atoms,
R^{f2} and R^{f3} are each independently a fluorine atom or a monovalent fluorinated hydrocarbon group having 1 to 10 carbon atoms, when there are a plurality of R^{f2} and R^{f3}, the plurality of R^{f2} are the same as or different from each other, and the plurality of R^{f3} are the same as or different from each other, and
s is an integer of 0 to 3, and when R^{f1} is the monovalent hydrocarbon group having 1 to 10 carbon atoms, s is an integer of 1 to 3.

2. The radiation-sensitive composition according to claim 1, wherein the acid-dissociable group comprises an iodo group-containing aromatic ring structure.

3. The radiation-sensitive composition according to claim 2, wherein an aromatic ring in the iodo group-containing aromatic ring structure is a benzene ring.

4. The radiation-sensitive composition according to claim 1, wherein a number of iodo groups in the acid-dissociable group is 1, 2, or 3.

5. The radiation-sensitive composition according to claim 1, wherein the structural unit (I) is represented by formula (1): 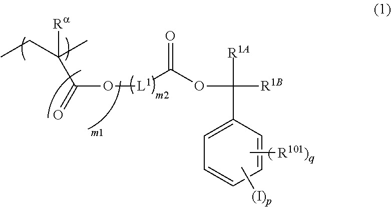
wherein in the formula (1),
R^{α} is a hydrogen atom, a fluorine atom, a methyl group, or a trifluoromethyl group,
L¹ is a divalent linking group,
R^{1A} and R^{1B} are each independently a hydrogen atom, a monovalent chain hydrocarbon group having 1 to 10 carbon atoms or a monovalent alicyclic hydrocarbon group having 3 to 20 carbon atoms, or taken together represent a divalent alicyclic group having 3 to 20 carbon atoms together with the carbon atom to which R^{1A} and R^{1B} are bonded, provided that both R^{1A} and
R^{1B} are not hydrogen atoms,
R¹⁰¹ is a nitro group, a cyano group, a hydroxy group, an alkoxy group, or an amino group, when there are a plurality of R¹⁰¹s, the plurality of R¹⁰¹s are the same as or different from each other,
m1 and m2 are each independently 0 or 1, provided that when m1 is 1, m2 is 1,
p is an integer of 1 to 3, and q is an integer of 0 to 3, provided that p+q is 5 or less.

6. The radiation-sensitive composition according to claim 1, wherein a content of the structural unit (I) in the first polymer with respect to all structural units composing the first polymer is 20 mol % or more and 70 mol % or less.

7. The radiation-sensitive composition according to claim 1, wherein the first polymer further comprises a structural unit having a phenolic hydroxyl group (III).

8. The radiation-sensitive composition according to claim 1, wherein in the formula (f1), L^{Y2} is —COO—*.

9. The radiation-sensitive composition according to claim 1, wherein in the formula (f1), R^{f1} is a monovalent fluorinated hydrocarbon group having 1 to 10 carbon atoms, and s is 0.

10. The radiation-sensitive composition according to claim 1, wherein a content of the structural unit (i) in the second polymer with respect to all structural units composing the second polymer is 30 mol % or more and 100 mol % or less.

11. The radiation-sensitive composition according to claim 1, wherein a content of the second polymer in the radiation-sensitive composition is 0.1 parts by mass or more and 20 parts by mass or less based on 100 parts by mass of the first polymer.

12. The radiation-sensitive composition according to claim 1, further comprising a radiation-sensitive acid generator.

13. The radiation-sensitive composition according to claim 12, wherein the radiation-sensitive acid generator has an iodo group.

14. The radiation-sensitive composition according to claim 1, further comprising an acid diffusion controlling agent.

15. The radiation-sensitive composition according to claim 14, wherein the acid diffusion controlling agent has an iodo group.

16. A pattern forming method, comprising:
directly or indirectly applying the radiation-sensitive composition according to claim 1 onto a substrate to form a resist film;
exposing the resist film to light; and
developing the exposed resist film with a developer.

17. The pattern forming method according to claim 16, wherein exposing comprises exposing the resist film to extreme ultraviolet ray or an electron beam.
